(19) United States
(12) Patent Application Publication
(10) Pub. No.: US 2025/0158361 A1
(43) Pub. Date: May 15, 2025

(54) SURFACE EMITTING LASER AND METHOD FOR MANUFACTURING SURFACE EMITTING LASER

(71) Applicant: Sony Group Corporation, Tokyo (JP)

(72) Inventors: Hiroshi NAKAJIMA, Tokyo (JP); Susumu SATO, Tokyo (JP); Mikihiro YOKOZEKI, Tokyo (JP)

(21) Appl. No.: 18/724,357

(22) PCT Filed: Oct. 13, 2022
(86) PCT No.: PCT/JP2022/038225

§ 371 Date: Jan. 9, 2025

(30) Foreign Application Priority Data
Jan. 28, 2022 (JP) 2022-011715

(51) Int. Cl. H01S 5/183; H01S 5/042; H01S 5/30; H01S 5/343

(52) U.S. Cl. CPC H01S 5/18377; H01S 5/04254; H01S 5/18369; H01S 5/3013; H01S 5/3095; H01S 5/343

(57) ABSTRACT

The present technology provides a surface emitting laser capable of compensating for disadvantages of a reflector due to a material system of a multilayer reflector in the entire reflector.

The surface emitting laser according to the present technology includes: a first structure that includes a first reflector; a second structure that includes a second reflector; and an active layer that is disposed between the first and second structures, the first reflector includes stacked a first multilayer reflector and a second multilayer reflector, the first multilayer reflector is made of a first material system, and the second multilayer reflector is made of a second material system that is different from the first material system. According to the present technology, it is possible to provide the surface emitting laser capable of compensating for disadvantages of the reflector due to a material system in the entire reflector.

### TECHNICAL FIELD

A technology according to the present disclosure (hereinafter, also referred to as a “present technology”) relates to a surface emitting laser and a method for manufacturing a surface emitting laser.

### BACKGROUND ART

In the related art, a surface emitting laser in which an intermediate structure including an active layer and a multilayer reflector (for example, a lower reflector) of a material system that is different from a material system of the intermediate structure are bonded to each other is known (see PTL 1 and NPL 1, for example).

### CITATION LIST

### Patent Literature

[PTL 1]
JP H11-186653A
[NPL 1]
8 mW fundamental mode output of waferfused VCSELs emitting in the 1550-nm band

### SUMMARY

### Technical Problem

A surface emitting laser in the related art has advantages and disadvantages due to a material system of a multilayer reflector.

Thus, a main object of the present technology is to provide a surface emitting laser capable of compensating for the disadvantages of the reflector due to the material system of the multilayer reflector in the entire reflector.

### Solution to Problem

The present technology provides a surface emitting laser including:
a first structure that includes a first reflector;
a second structure that includes a second reflector; and
an active layer that is disposed between the first structure and the second structure,
in which
the first reflector includes stacked a first multilayer reflector and a second multilayer reflector,
the first multilayer reflector is made of a first material system, and
the second multilayer reflector is made of a second material system that is different from the first material system.

Both the first multilayer reflector and the second multilayer reflector may be semiconductor multilayer reflectors.

The first material system may be a compound semiconductor that lattice-matches GaAs, and the second material system may be a compound semiconductor that lattice-matches InP.

A lattice constant of the first material system may fall within a range of ±0.2% of a lattice constant of GaAs, and a lattice constant of the second material system may fall within a range of ±0.2% of a lattice constant of InP.

The second multilayer reflector may be disposed between the first multilayer reflector and the active layer.

The active layer may be made of a GaAs-based compound semiconductor or a GaAsP-based compound semiconductor.

The active layer may have a quantum well structure made of AlGaInAs or GaInAsP.

A light emitting wavelength of the active layer may be equal to or greater than 1.2 μm and equal to or less than 2 μm.

The first structure may further include an intermediate layer disposed between the first multilayer reflector and the second multilayer reflector, and the intermediate layer may include a first layer that is disposed on the side of the first multilayer reflector and is made of a compound semiconductor that lattice-matches GaAs and a second layer that is disposed on the side of the second multilayer reflector and is made of a compound semiconductor that lattice-matches InP.

The first layer and the second layer may be bonded to each other.

The first structure may further include a substrate on the first reflector on the side opposite to a side of the active layer.

The first material system may be GaAs/AlₓGa_{1-X}As (0<X≤1).

The second material system may include AlGaInAs.

The second material system may be InP/AlGaInAs or AlInAs/AlGaInAs.

A thickness of the intermediate layer may be equal to or less than 300 nm.

The number of pairs in the second multilayer reflector may be equal to or greater than one and equal to or less than twenty.

The second reflector may be a dielectric multilayer reflector.

The second reflector may be made of a material containing at least one kind from SiO₂, TiO₂, Ta₂O₅, SiN, amorphous Si, MgF₂, and CaF₂.

The present technology also provides a method for manufacturing a surface emitting laser including:
laminating a first semiconductor structure including a first multilayer reflector that is a part of a first reflector on a first substrate;
bonding the first semiconductor structure to a second substrate;
forming a second semiconductor structure including a second multilayer reflector that is another portion of the first reflector and an active layer on the second substrate in this order from a side of the second substrate;
reducing a thickness of the second substrate; and forming a second reflector on the second semiconductor structure.

The reducing of the thickness may be performed between the bonding of the first semiconductor structure to the second substrate and the forming of the second semiconductor structure.

The present technology provides a surface emitting laser including:
a first structure that includes a first reflector;
a second structure that includes a second reflector; and
an active layer that is disposed between the first and second structures, in which
the second structure includes
a plurality of mesa-shaped tunnel junction layers that are provided between the active layer and the second reflector, and
a semiconductor layer that covers the plurality of tunnel junction layers, and
the plurality of tunnel junction layers are disposed to be spaced apart from each other in an in-plane direction to be optically separated.

The active layer may include a plurality of light emitting regions that individually correspond to the plurality of tunnel junction layers.

An interval between two adjacent tunnel junction layers from among the plurality of tunnel junction layers may be larger than a diameter of each of the plurality of tunnel junction layers.

The interval may be three times or more the diameter.

An alignment pitch of the plurality of tunnel junction layers may be equal to or greater than 40 μm and equal to or less than 100 μm.

The second structure ST2 may be provided with an electrode on the semiconductor layer on a side opposite to a side of the active layer.

The electrode may not overlap with any of the plurality of tunnel junction layers.

The electrode may overlap with at least one of the plurality of tunnel junction layers.

The electrode may include an electrode portion including a part that is present in the surroundings of each of the plurality of tunnel junction layers in a plan view.

At least a part of the part may be present between each of the corresponding tunnel junction layer and each of the tunnel junction layer that is adjacent to the corresponding tunnel junction layer in a plan view.

The part may surround each of the corresponding tunnel junction layer in a plan view.

The electrode may include an electrode portion that surrounds at least two tunnel junction layers together from among the plurality of tunnel junction layers in a plan view.

At least a part of the electrode may be disposed between the semiconductor layer and the second reflector.

The second reflector may cover the electrode and the semiconductor layer.

The electrode may be disposed on the second reflector on a side opposite to a side of the active layer.

A part of the second reflector may also function as the electrode.

The semiconductor layer may be made of InP.

A thickness of the semiconductor layer may be equal to or greater than 200 nm.

The second reflector may include a dielectric multilayer reflector.

The dielectric multilayer reflector may be made of a material containing at least one kind from SiO₂, TiO₂, Ta₂O₅, SiN, amorphous Si, MgF₂, and CaF₂.

The first reflector may include a dielectric multilayer reflector.

The dielectric multilayer reflector may be made of a material containing at least one kind from SiO₂, TiO₂, Ta₂O₅, SiN, amorphous Si, MgF₂, and CaF₂.

The active layer may have a quantum well structure made of AlGaInAs or GaInAsP.

A light emitting wavelength of the active layer may be equal to or greater than 1.2 μm and equal to or less than 2 μm.

A part of the first reflector may also function as another electrode.

### BRIEF DESCRIPTION OF DRAWINGS

FIG. 1 is a sectional view of a surface emitting laser according to a comparative example.

FIG. 2 is a sectional view of a surface emitting laser according to a first example to a first embodiment of the present technology.

FIG. 3 is a graph illustrating a relationship between deviation of an InP layer from a designed film thickness and an oscillation wavelength.

FIG. 4 is a graph illustrating a relationship between deviation of a GaAs layer from a designed film thickness and an oscillation wavelength.

FIG. 5 is a graph illustrating a relationship between a total film thickness of GaAs/AlAs·DBR and warpage of a wafer.

FIG. 6 is a graph illustrating a relationship between a position of the wafer in an in-plane direction and warpage.

FIG. 7 is a graph illustrating relationships between reflectance and the numbers of pairs of GaAs/AlAs·DBRs and InP/AlGaInAs·DBRs.

FIG. 8 is a flowchart for explaining a first example of a method for manufacturing the surface emitting laser in FIG. 2.

FIGS. 9A and 9B are sectional views for each process in the first example of the method for manufacturing the surface emitting laser in FIG. 2.

FIGS. 10A and 10B are sectional views for each process in the first example of the method for manufacturing the surface emitting laser in FIG. 2.

FIGS. 11A and 11B are sectional views for each process in the first example of the method for manufacturing the surface emitting laser in FIG. 2.

FIGS. 12A and 12B are sectional views for each process in the first example of the method for manufacturing the surface emitting laser in FIG. 2.

FIG. 13 is a sectional view for each process in the first example of the method for manufacturing the surface emitting laser in FIG. 2.

FIGS. 14A and 14B are sectional views for each process in the first example of the method for manufacturing the surface emitting laser in FIG. 2.

FIGS. 15A and 15B are sectional views for each process in the first example of the method for manufacturing the surface emitting laser in FIG. 2.

FIG. 16 is a flowchart for explaining a second example of a method for manufacturing the surface emitting laser in FIG. 2.

FIGS. 17A and 17B are sectional views for each process in the second example of the method for manufacturing the surface emitting laser in FIG. 2.

FIGS. 18A and 18B are sectional views for each process in the second example of the method for manufacturing the surface emitting laser in FIG. 2.

FIGS. 19A and 19B are sectional views for each process in the second example of the method for manufacturing the surface emitting laser in FIG. 2.

FIG. 20 is a sectional view for each process in the second example of the method for manufacturing the surface emitting laser in FIG. 2.

FIGS. 21A and 21B are sectional views for each process in the second example of the method for manufacturing the surface emitting laser in FIG. 2.

FIGS. 22A and 22B are sectional views for each process in the second example of the method for manufacturing the surface emitting laser in FIG. 2.

FIG. 23 is a sectional view for each process in the second example of the method for manufacturing the surface emitting laser in FIG. 2.

FIG. 24 is a sectional view for each process in the second example of the method for manufacturing the surface emitting laser in FIG. 2.

FIG. 25 is a sectional view for each process in the second example of the method for manufacturing the surface emitting laser in FIG. 2.

FIG. 26 is a sectional view for each process in the second example of the method for manufacturing the surface emitting laser in FIG. 2.

FIG. 27 is a sectional view of a surface emitting laser according to a second example to the first embodiment of the present technology.

FIG. 28 is a sectional view of a surface emitting laser according to a third example to the first embodiment of the present technology.

FIG. 29 is a sectional view of a surface emitting laser according to a fourth example to the first embodiment of the present technology.

FIG. 30 is a sectional view of a surface emitting laser according to a first modification of the first example to the first embodiment of the present technology.

FIG. 31 is a sectional view of a surface emitting laser according to a second modification of the first example to the first embodiment of the present technology.

FIG. 32 is a sectional view of a surface emitting laser according to a modification of the second example to the first embodiment of the present technology.

FIG. 33 is a sectional view of a surface emitting laser according to a modification of the third example to the first embodiment of the present technology.

FIG. 34 is a sectional view of a surface emitting laser according to a modification of the fourth example to the first embodiment of the present technology.

FIG. 35 is a sectional view of a surface emitting laser according to a modification of the first embodiment of the present technology.

FIG. 36 is a diagram illustrating the number of pairs in each DBR necessary to obtain a reflectance of equal to or greater than 99.9% in hybrid DBRs containing GaAs/AlAs·DBR and InP/AlGaInAs·DBR.

FIG. 37 is a sectional view of a surface emitting laser according to a first example of a second embodiment of the present technology.

FIG. 38 is a plan view of the surface emitting laser according to the first example of the second embodiment of the present technology.

FIG. 39 is a diagram for explaining a relationship between a diameter and a gap of tunnel junction layers in the surface emitting laser in FIG. 37.

FIG. 40 is a graph illustrating a relationship between an alignment pitch of the tunnel junction layers in FIG. 37 and a maximum temperature.

FIG. 41A is a diagram illustrating a first specific example of an alignment pitch of the tunnel junction layers and a maximum temperature. FIG. 41B is a diagram illustrating a second specific example of an alignment pitch of the tunnel junction layers and a maximum temperature.

FIG. 42A is a diagram illustrating a heat discharge route of the surface emitting laser in FIG. 37. FIG. 42B is a diagram illustrating a heat discharge route of a surface emitting laser in the related art.

FIG. 43 is a flowchart for explaining an example of a method for manufacturing the surface emitting laser in FIG. 37.

FIGS. 44A and 44B are sectional views for each process of an example of the method for manufacturing the surface emitting laser in FIG. 37.

FIGS. 45A and 45B are sectional views for each process of an example of the method for manufacturing the surface emitting laser in FIG. 37.

FIGS. 46A and 46B are sectional views for each process of an example of the method for manufacturing the surface emitting laser in FIG. 37.

FIGS. 47A and 47B are sectional views for each process of a first example of the method for manufacturing the surface emitting laser in FIG. 37.

FIG. 48A is a plan view of a surface emitting laser according to a second example of the second embodiment of the present technology. FIG. 48B is a sectional view of the surface emitting laser according to the second example of the second embodiment of the present technology.

FIG. 49A is a sectional view of a surface emitting laser according to a third example of the second embodiment of the present technology. FIG. 49B is a plan view of the surface emitting laser according to the third example of the second embodiment of the present technology.

FIG. 50A is a sectional view of a surface emitting laser according to a fourth example of the second embodiment of the present technology. FIG. 50B is a plan view of the surface emitting laser according to the fourth example of the second embodiment of the present technology.

FIG. 51A is a plan view of a surface emitting laser according to a fifth example of the second embodiment of the present technology. FIG. 51B is a sectional view of the surface emitting laser according to the fifth example of the second embodiment of the present technology.

FIG. 52A is a plan view of a surface emitting laser according to a sixth example of the second embodiment of the present technology. FIG. 52B is a sectional view of the surface emitting laser according to the sixth example of the second embodiment of the present technology.

FIG. 53A is a sectional view of a surface emitting laser according to a seventh example of the second embodiment of the present technology. FIG. 53B is a plan view of the surface emitting laser according to the seventh example of the second embodiment of the present technology.

FIG. 54A is a plan view of a surface emitting laser according to an eighth example of the second embodiment of the present technology. FIG. 54B is a sectional view of the surface emitting laser according to the eighth example of the second embodiment of the present technology.

FIG. 55A is a plan view of a surface emitting laser according to a ninth example of the second embodiment of the present technology. FIG. 55B is a sectional view of the surface emitting laser according to the ninth example of the second embodiment of the present technology.

FIG. 56A is a plan view of a surface emitting laser according to a tenth example of the second embodiment of the present technology. FIG. 56B is a sectional view of the surface emitting laser according to the tenth example of the second embodiment of the present technology.

FIG. 57A is a plan view of a surface emitting laser according to an eleventh example of the second embodiment of the present technology. FIG. 57B is a sectional view of the surface emitting laser according to the eleventh example of the second embodiment of the present technology.

FIG. 58A is a sectional view of a surface emitting laser according to a twelfth example of the second embodiment of the present technology. FIG. 58B is a plan view of the surface emitting laser according to the twelfth example of the second embodiment of the present technology.

FIG. 59A is a sectional view of a surface emitting laser according to a thirteenth example of the second embodiment of the present technology. FIG. 59B is a plan view of the surface emitting laser according to the thirteenth example of the second embodiment of the present technology.

FIG. 60A is a sectional view of a surface emitting laser according to a fourteenth example of the second embodiment of the present technology. FIG. 60B is a plan view of the surface emitting laser according to the fourteenth example of the second embodiment of the present technology.

FIG. 61A is a sectional view of a surface emitting laser according to a fifteenth example of the second embodiment of the present technology. FIG. 61B is a plan view of the surface emitting laser according to the fifteenth example of the second embodiment of the present technology.

FIG. 62A is a sectional view of a surface emitting laser according to a sixteenth example of the second embodiment of the present technology. FIG. 62B is a plan view of the surface emitting laser according to the sixteenth example of the second embodiment of the present technology.

FIG. 63A is a sectional view of a surface emitting laser according to a seventeenth example of the second embodiment of the present technology. FIG. 63B is a plan view of the surface emitting laser according to the seventeenth example of the second embodiment of the present technology.

FIG. 64A is a sectional view of a surface emitting laser according to an eighteenth example of the second embodiment of the present technology. FIG. 64B is a plan view of the surface emitting laser according to the eighteenth example of the second embodiment of the present technology.

FIG. 65 is a diagram illustrating an example of an application of the surface emitting laser according to the present technology to a distance measurement device.

FIG. 66 is a block diagram showing an example of a schematic configuration of a vehicle control system.

FIG. 67 is an explanatory diagram illustrating an example of an installation position of the distance measurement device.

### DESCRIPTION OF EMBODIMENTS

Preferred embodiments of the present technology will be described in detail with reference to the accompanying drawings below. In the present specification and the drawings, components having substantially the same functional configuration will be denoted by the same reference numerals, and thus repeated descriptions thereof will be omitted. The embodiments to be described below show a representative embodiment of the present technology, and the scope of the present technology should not be narrowly interpreted on the basis of this. Even in a case where the present specification describes that a surface emitting laser and a method for manufacturing a surface emitting laser according to the present technology exhibit a plurality of effects, it is only necessary for the surface emitting laser and the method for manufacturing a surface emitting laser according to the present technology to exhibit at least one effect. The advantageous effects described in the present specification are merely exemplary and are not limited, and other advantageous effects may be obtained.

The description will be made in the following order.
0. Introduction
1. Surface emitting laser according to first example of first embodiment of present technology
2. Surface emitting laser according to second example of first embodiment of present technology
3. Surface emitting laser according to third example of first embodiment of present technology
4. Surface emitting laser according to fourth example of first embodiment of present technology
5. Surface emitting laser according to first modification of first example of first embodiment of present technology
6. Surface emitting laser according to second modification of first example of first embodiment of present technology
7. Surface emitting laser according to modification of second example of first embodiment of present technology
8. Surface emitting laser according to modification of third example of first embodiment of present technology
9. Surface emitting laser according to modification of fourth example of first embodiment of present technology
10. Surface emitting laser according to modification of first embodiment of present technology
11. Surface emitting laser according to first example of second embodiment of present technology
12. Surface emitting laser according to second example of second embodiment of present technology
13. Surface emitting laser according to third example of second embodiment of present technology
14. Surface emitting laser according to fourth example of second embodiment of present technology
15. Surface emitting laser according to fifth example of second embodiment of present technology
16. Surface emitting laser according to sixth example of second embodiment of present technology
17. Surface emitting laser according to seventh example of second embodiment of present technology
18. Surface emitting laser according to eighth example of second embodiment of present technology
19. Surface emitting laser according to ninth example of second embodiment of present technology
20. Surface emitting laser according to tenth example of second embodiment of present technology
21. Surface emitting laser according to eleventh example of second embodiment of present technology
22. Surface emitting laser according to twelfth example of second embodiment of present technology
23. Surface emitting laser according to thirteenth example of second embodiment of present technology
24. Surface emitting laser according to fourteenth example of second embodiment of present technology
25. Surface emitting laser according to fifteenth example of second embodiment of present technology
26. Surface emitting laser according to sixteenth example of second embodiment of present technology
27. Surface emitting laser according to seventeenth example of second embodiment of present technology
28. Surface emitting laser according to eighteenth example of second embodiment of present technology
29. Other modifications of present technology
30. Examples of application to electronic devices
31. Examples in which surface emitting lasers are applied to distance measurement devices
32. Example in which distance measurement device is mounted in mobile object

### 0. Introduction

Incidentally, although raising an optical output of a laser light source is effective to enhance authentication accuracy in three-dimensional laser sensing such as face authentication, for example, laser light may damage eyes, and there is thus a restriction that the optical output cannot be raised to be equal to or greater than a prescribed value. The prescribed value is called a damage threshold value and increases as a wavelength of the laser light increases. The damage threshold value significantly increases from 1.4 μm or more, and a wavelength band of equal to or greater than 1.4 μm is thus called an eye safety zone. Therefore, a laser light source with a wavelength zone of equal to or greater than 1.4 μm is desired as a light source for next-generation sensing.

As a semiconductor laser which is a kind of a laser light source, there are roughly an edge emitting laser (LD) and a vertical cavity surface emitting laser (VCSEL). The VCSEL is less expensive, can more easily increase an output through alignment in an array, and is thus more suitable for an application to sensing or the like than the LD.

An InP substrate is suitable as a VCSEL substrate that oscillates with a wavelength of equal to or greater than 1.4 μm. However, there is a problem that there are no materials for the InP substrate that have a wide stop bandwidth and realize a distributed Bragg reflector (DBR) with high heat conductivity and satisfactory heat dissipation like a DBR that is used in a GaAs-based VCSEL and made of AlAs/GaAs, for example. Although DBRs that are made of AlGaInAs/InP and AlGaInAs/AlInAs, for example, are listed as semiconductor DBRs that lattice-match the InP substrate, both the semiconductor DBRs have problems of low refractive indexes, narrow stop bandwidths, low heat conductivity, and poor heat dissipation.

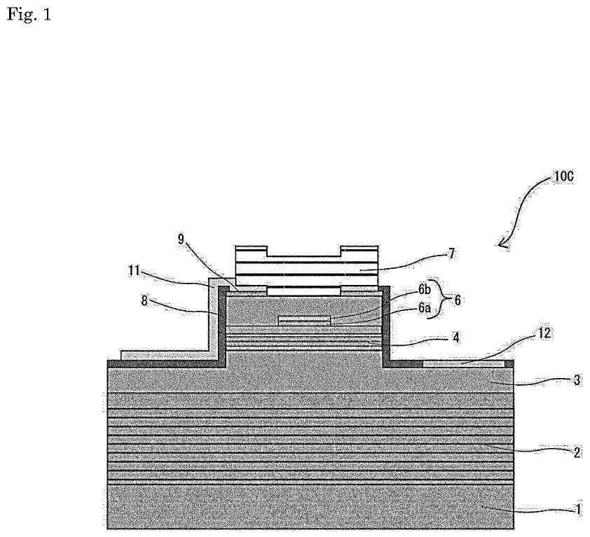

As a technology that solves this problem, the technology disclosed in PTL 1 and NPL 1 is listed. FIG. 1 is a sectional view of a surface emitting laser 10C according to a comparative example using the technology. In the surface emitting laser 10C, a GaAs substrate 1 in which a DBR 2 (lower DBR) made of AlAs/GaAs is formed and an InP substrate 3 in which crystals for a light emitting layer 4, a tunnel junction layer 6, and the like are made to grow are attached to each other. In this manner, it is possible to realize a surface emitting laser with a wider stop bandwidth of the lower DBR and high heat conductivity as compared with a case where a semiconductor DBR that lattice-matches the InP substrate 3 is used for the lower DBR. However, the surface emitting laser 10C has a problem that it is difficult to achieve the attachment due to warpage of the GaAs substrate 1 caused by distortion of the DBR 2 made of AlAs/GaAs and a yield is thus degraded. Furthermore, the problem has become further significant than before with an increase in diameter of the substrate with an intention to reduce costs in recent years. Note that in FIG. 1, the reference sign 7 denotes an upper DBR, the reference sign 8 denotes an insulating film, the reference sign 9 denotes a contact layer, the reference sign 11 denotes an anode wiring, and the reference sign 12 denotes a cathode electrode.

Also, the surface emitting laser 10C according to the comparative example has another problem. Although it is necessary to attach the substrates in which the crystals have been made to grow according to this technology, a large number of protrusions in μm order are typically generated on the surface of the substrates in which the crystals have been made to grow due to dust and the like generated in a crystallization furnace. The protrusions adversely affect the attachment, and it is thus necessary to flatten the surfaces through chemical mechanical polishing (CMP) or the like. However, since the resonator length of the VCSEL is as short as a few wavelengths or less, the resonator length significantly affects the oscillation wavelength. In other words, there is also a problem that the oscillation wavelength becomes non-uniform in a wafer surface if a film thickness of the outermost layer becomes uneven in the wafer plane through the polishing process.

Thus, the present inventors have focused particularly on the heat dissipation and the yield from among the above problems and have developed a surface emitting laser according to a first embodiment of the present technology as a surface emitting laser capable of curbing at least degradation of the heat dissipation and degradation of the yield.

Hereinafter, the surface emitting laser according to the first embodiment of the present technology will be described in detail by listing several examples.

### 1. Surface Emitting Laser According to First Example of First Embodiment of Present Technology

Hereinafter, a surface emitting laser 10 according to a first example of the first embodiment of the present technology will be described.

### <<Configuration of Surface Emitting Laser>>

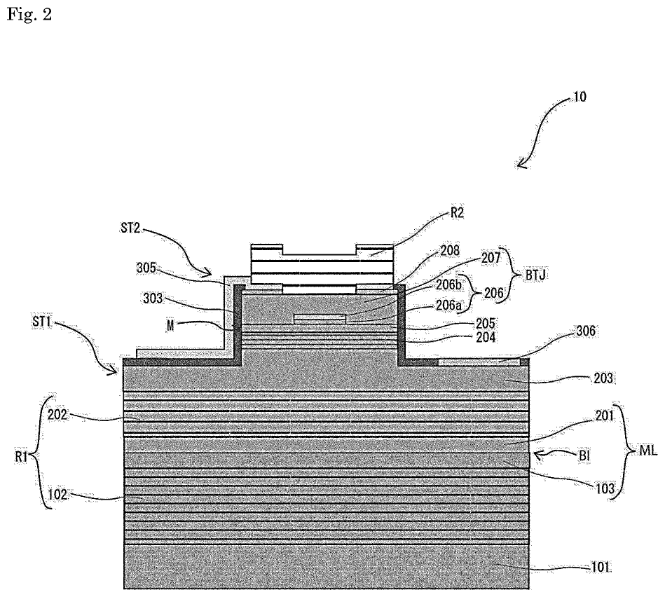

FIG. 2 is a sectional view of the surface emitting laser 10 according to the first example of the first embodiment of the present technology. The following description will be given on the assumption that the upper side and the lower side in the sectional views such as FIG. 2 are the upper and lower sides, respectively.

### (Overall Configuration)

The surface emitting laser 10 is a vertical cavity surface emitting laser (VCSEL). The surface emitting laser 10 is a VCSEL with an oscillation wavelength λ of equal to or greater than 900 nm, for example, or further with a long wavelength band of equal to or greater than 1.4 μm in an example. The oscillation wavelength λ is particularly preferably equal to or greater than 1.2 μm and equal to or less than 2 μm. The surface emitting laser 10 is driven by a laser driver in an example.

The surface emitting laser 10 includes a first structure ST1 that includes a first reflector R1, a second structure ST2 that includes a second reflector R2, and an active layer 204 that is disposed between the first and second structures ST1 and ST2 as illustrated in FIG. 2 in an example. In an example, the second reflector R2 is a reflector on an emission side. The first reflector R1 is also called a lower reflector. The second reflector R2 is also called an upper reflector.

The first structure ST1 further includes a substrate 101 that is disposed on the first reflector R1 on the side opposite to the side of the active layer 204 and a first cladding layer 203 that is disposed between the first reflector R1 and the active layer 204 in an example. A buffer layer is preferably disposed between the substrate 101 and the first reflector R1.

The first reflector R1 includes stacked first and second multilayer reflectors 102 and 202 in an example. In an example, the second multilayer reflector 202 is disposed between the first multilayer reflector 102 and the active layer 204.

The first structure ST1 further includes an intermediate layer ML that is disposed between the first and second multilayer reflectors 102 and 202 in an example.

The second structure ST2 further includes a buried tunnel junction (BTJ) disposed between the second reflector R2 and the active layer 204 in an example. Hereinafter, the buried tunnel junction BTJ will be appropriately abbreviated as a “BTJ”.

The second structure ST2 further includes a second cladding layer 205 disposed between the BTJ and the active layer 204 in an example.

In an example, a mesa M is configured to include a portion (upper portion) of the first cladding layer 203, the active layer 204, the second cladding layer 205, and the BTJ.

A contact layer 208 is provided on the top of the mesa M (specifically, on the BTJ) in an example. An insulating film 303 is provided along an upper surface of the first cladding layer 203 and a side surface of the mesa M in the surroundings of the mesa M. An anode wiring 305 that is partially in contact with the contact layer 208 is provided on the insulating film 303.

A part of the insulating film 303 on the first cladding layer 203 in the surroundings of the mesa M has been removed, and a cathode electrode 306 is provided at the removed location such that the cathode electrode 306 is in contact with the first cladding layer 203. In other words, the surface emitting laser 10 has an intra-cavity structure in which the anode wiring 305 and the cathode electrode 306 are disposed on the side of the same surface.

### (Substrate)

The substrate 101 is a GaAs substrate in an example. Although it is desirable that the GaAs substrate be an undoped substrate, the GaAs substrate may be an n-type substrate with a doping concentration of about 5×10¹⁷ to 1×10¹⁸ [cm⁻³]. The dopant in this case can be Si, for example.

### (Buffer Layer)

The buffer layer is a GaAs layer in an example. Although it is desirable that the GaAs layer be an undoped layer, the GaAs layer may be an n-type layer with a doping concentration of about 5×10¹⁷ to 1×10¹⁸ [cm⁻³]. The dopant in this case can be Si, for example.

### (First and Second Multilayer Reflectors)

The first multilayer reflector 102 is made of a first material system, and the second multilayer reflector 202 is made of a second material system that is different from the first material system. In other words, the first reflector R1 has a hybrid structure as a combination of multilayer reflectors of different material systems.

Both the first and second multilayer reflectors 102 and 202 are semiconductor multilayer reflectors (semiconductor DBRs) in an example. The semiconductor multilayer reflectors have a structure in which a plurality of kinds (two kinds, for example) of refractive index layers (semiconductor layers) with mutually different refractive indexes are alternately stacked to have an optical thickness that is ¼ (λ/4) the oscillation wavelength λ. Here, the number of pairs in the first multilayer reflector 102 is, for example, twenty five. The number of pairs in the second multilayer reflector 202 is preferably equal to or greater than one and equal to or less than twenty. Here, the number of pairs in the second multilayer reflector 202 is, for example, ten. Although it is desirable that each multilayer reflector be an undoped reflector, the multilayer reflector may be an n-type reflector with a doping concentration of about 5×10¹⁷ to 1×10¹⁸ [cm⁻³]. The dopant in this case can be Si, for example.

The first material system configuring the first multilayer reflector 102 is a compound semiconductor that lattice-matches GaAs in an example. A lattice constant of the first material system preferably falls within a range of ±0.2% of a lattice constant of GaAs in an example. Specifically, the first material system is preferably GaAs/AlₓGa_{1-X}As (0<X≤1). Note that the first material system may be, for example, GaInP/GaAs.

The second material system configuring the second multilayer reflector 202 is a compound semiconductor that lattice-matches InP. A lattice constant of the second material system preferably falls within a range of ±0.2% of a lattice constant of InP. Specifically, the second material system preferably includes AlGaInAs. More specifically, the second material system is preferably InP/AlGaInAs or AlInAs/AlGaInAs.

### (Intermediate Layer)

The intermediate layer ML includes a first layer 103 (a GaAs layer, for example) that is disposed on the side of the first multilayer reflector 102 and is made of a compound semiconductor that lattice-matches GaAs and a second layer 201 (an InP layer, for example) that is disposed on the side of the second multilayer reflector 202 and is made of a compound semiconductor that lattice-matches InP. The first and second layers 103 and 201 are bonded to each other. FIG. 2 illustrates a bonding interface BI between the first and second layers 103 and 201. The thickness (total thickness) of the intermediate layer ML is preferably equal to or less than 300 nm. Although the GaAs layer as the first layer 103 is preferably an undoped layer, the GaAs layer may be an n-type layer with a doping concentration of about 5×10¹⁷ to 1×10¹⁸ [cm⁻³]. The dopant in this case can be Si, for example. Although the InP layer as the second layer 201 is preferably an undoped layer, the InP layer may be an n-type layer with a doping concentration of about 5×10¹⁷ to 1×10¹⁸ [cm⁻³]. It is possible to use Si, for example, as a dopant in this case.

### (First Cladding Layer)

The first cladding layer 203 is made of an n-InP layer, for example. It is possible to use Si, for example, as a dopant for the n-InP layer, and the dopant concentration can be 5×10¹⁷ to 1×10¹⁸ [cm⁻³], for example.

### (Active Layer)

The active layer 204 is made of a GaAs-based compound semiconductor or a GaAsP-based compound semiconductor in an example. Specifically, the active layer 204 includes a multiquantum well (MQW) structure made of AlGaInAs or GaInAsP in an example. Here, the active layer 204 is made of an AlGaInAs/AlGaInAs multiquantum well layer, for example. Although a composition and a film thickness of the AlGaInAs/AlGaInAs multiquantum well layer are designed such that a light emitting wavelength of 1450 nm, for example, is achieved, it is desirable to introduce opposing distortions into a well layer and a barrier layer. In this case, the magnitude of the distortions is about 0.5%, and the number of wells is six. A region in the active layer 204 corresponding to a tunnel junction layer 206, which will be described later, is a light emitting region. The light emitting region in the active layer 204 is also a heat generating portion.

### (Second Cladding Layer)

The second cladding layer 205 is made of a p-InP layer, for example. It is possible to use Mg, for example, as a dopant for the p-InP layer, and the dopant concentration can be 5×10¹⁷ to 1×10¹⁸ [cm⁻³], for example.

### (BTJ)

The BTJ includes the tunnel junction layer 206 and a buried layer 207. The BTJ is disposed on the active layer 204 on the side of the second reflector R2 as described above. In other words, the BTJ is positioned on the side upstream a current route from the anode wiring 305 to the cathode electrode 306 with respect to the active layer 204. Hereinafter, the tunnel junction layer 206 will be appropriately abbreviated as a “TJ layer”.

The buried layer 207 is made of an n-InP layer, for example. It is possible to use Si, for example, as a dopant for the n-InP layer, and the doping concentration can be 5×10¹⁷ to 1×10¹⁸ [cm⁻³], for example.

The tunnel junction layer 206 is provided in a mesa shape on the second cladding layer 205. The tunnel junction layer 206 has a considerably lower resistance than the buried layer 207 in the surroundings (carrier conductivity is significantly high) and serves as a current passing region. A region surrounding the TJ layer in the buried layer 207 serves as a current constriction region. The tunnel junction layer 206 also serves as a heat generating portion. The diameter of the mesa (TJ mesa) of the tunnel junction layer 206 is, for example, 10 μm.

The tunnel junction layer 206 includes stacked p-type semiconductor region 206a and n-type semiconductor region 206b. Here, the p-type semiconductor region 206a is disposed on the n-type semiconductor region 206b on the side of the active layer 204 (lower side). The p-type semiconductor region 206a is made of a p-type AlGaInAs-based compound semiconductor doped with carbon (C) at a high concentration (5×10¹⁹ [cm⁻³], for example). The n-type semiconductor region 206b is made of an n-type AlGaInAs-based compound semiconductor doped with Si or Te, for example, at a high concentration (5×10¹⁹ [cm⁻³], for example). The film thickness (total film thickness) of the tunnel junction layer 206 is about 10 to 70 nm in an example. Here, the film thicknesses of both the p-type semiconductor region 206a and the n-type semiconductor region 206b are 20 nm, for example.

### (Contact Layer)

The contact layer 208 is an n-InGaAs layer with a donut shape with an inner diameter of 16 μm and an outer diameter of 50 μm in an example. It is possible to use Si, for example, as a dopant for n-InGaAs, and the dopant concentration can be 2×10¹⁹ [cm⁻³], for example.

### (Second Reflector)

The second reflector R2 is a dielectric multilayer reflector (dielectric DBR) in an example. The dielectric multilayer reflector has a structure in which a plurality of kinds (two kinds, for example) of refractive index layers (dielectric layers) with mutually different refractive indexes are alternately stacked with an optical thickness of ¼ (λ/4) the oscillation wavelength λ. The reflectance of the second reflector R2 is set to be slightly lower than that of the first reflector R1. The second reflector R2 is preferably made of a material containing at least one kind from SiO₂, TiO₂, Ta₂O₅, SiN, amorphous Si, MgF₂, and CaF₂, for example. For example, the dielectric multilayer reflector as the second reflector R2 has a structure in which high refractive index layers (Ta₂O₅ layers, for example) and low refractive index layers (SiO₂ layers, for example) are alternately stacked. Here, the number of pairs is seven, for example.

### (Insulating Film 303)

The insulating film 303 is made of a dielectric element such as SiO₂, SiN, or SiON, for example.

### (Anode Wiring)

The anode wiring 305 includes a ring-shaped part that is in contact with the contact layer 208. The anode wiring 305 is made of Au/Ni/AuGe or Au/Pt/Ti, for example. The anode wiring 305 is electrically connected to a positive electrode (positive pole) of a laser driver, for example. Note that a ring-shaped anode electrode may be provided between the ring-shaped part of the anode wiring 305 and the contact layer 208.

### (Cathode Electrode)

The cathode electrode 306 is made of Au/Ni/AuGe or Au/Pt/Ti, for example. The cathode electrode 306 is electrically connected to a negative electrode (negative pole) of a laser driver, for example.

### (Concerning Influences on Oscillation Wavelength)

In principle, the oscillation wavelength of the VCSEL is determined by a resonator length and an equivalent refractive index of a material. Thus, since the substantial resonator length becomes the distance between an upper DBR and an InP-based DBR by employing, for a lower DBR, a hybrid structure of a GaAs-based DBR (for example, a DBR that lattice-matches GaAs such as GaAs/AlAs·DBR) and an InP-based DBR (for example, a DBR that lattice-matches InP such as InP/AlGaInAs·DBR, for example) disposed thereon, it is possible to accurately control the substantial resonator length through a crystal growth process. In other words, it is the second multilayer reflector 202 that substantially configures the resonator along with the second reflector R2, the active layer 204, and the like in the first reflector R1 in the surface emitting laser 10. In this case, the film thicknesses of the first layer 103 (the GaAs layer, for example) and the second layer 201 (the InP layer, for example) facing the bonding interface BI of the intermediate layer ML less affect the oscillation wavelength λ.

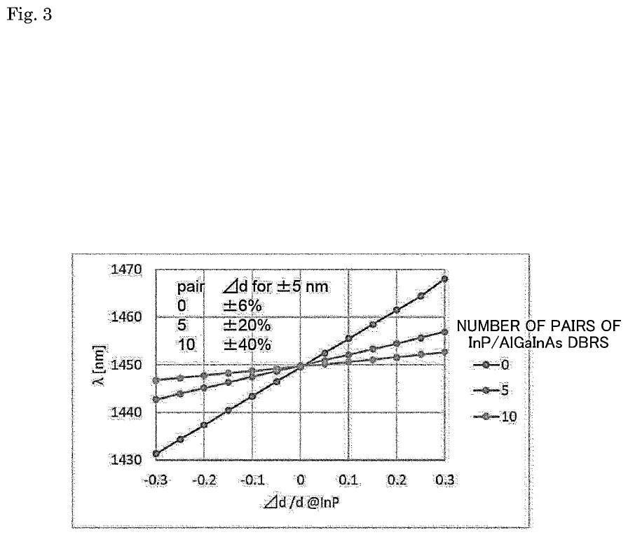

FIG. 3 is a graph illustrating a relationship between deviation of the InP layer used for the second layer 201 of the intermediate layer ML from a designed film thickness (Δd/d; where d is the designed film thickness, and Δd is the amount of deviation from the designed film thickness) and the oscillation wavelength λ. It is possible to know from FIG. 3 that variations in oscillation wavelength λ with respect to the deviation of the film thickness of the InP layer used for the second layer 201 decrease as the number of pairs in the second multilayer reflector 202 decreases. In a case where the number of pairs of InP/AlGaInAs·DBR is zero, for example, that is, in a case where there is only GaAs/AlAs·DBR, the oscillation wavelength changes by 5 nm if the film thickness of the InP layer deviates from the designed film thickness by 6% On the other hand, dependency of the oscillation wavelength on the deviation of the film thickness decreases by combining 5 pairs or 10 pairs of InP-based DBRs. Specifically, the oscillation wavelength changes by 5 nm if the film thickness of the InP layer deviates from the designed film thickness by 20% by combining 5 pairs of InP-based DBRs. The oscillation wavelength changes by 5 nm if the film thickness of the InP layer deviates from the designed film thickness by 40% by combining 10 pairs of InP-based DBRs. In other words, it is possible to very sufficiently curb variations in A if the number of pairs in the second multilayer reflector 202 is ten, for example, and there is still a sufficient effect of curbing variations in A even with five pairs. Note that although heat dissipation deteriorates if the number of pairs of InP/AlGaInAs·DBR is increased and the total film thickness of AlGaInAs is increased due to low heat conductivity of AlGaInAs, there are no significant influences if the number of pairs is about ten, and there is a larger advantage that a design margin for the film thickness of the InP layer increases.

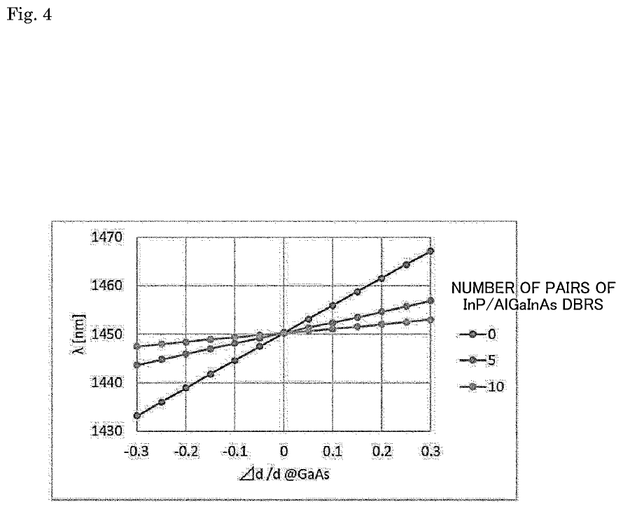

FIG. 4 is a graph illustrating a relationship between deviation (Δd/d; where d is a designed film thickness, and Δd is the amount of deviation from the designed film thickness) of the GaAs layer used for the first layer 103 of the intermediate layer ML from the designed film thickness and the oscillation wavelength λ. It is possible to know from FIG. 4 that variations in the oscillation wavelength λ with respect to the amount of deviation of the film thickness of the GaAs layer used for the first layer 103 also decreases as the number of pairs in the second multilayer reflector 202 increases. Specifically, it is possible to very sufficiently curb variations in λ if the number of pairs in the second multilayer reflector 202 is ten, for example, and there is still a sufficient effect of curbing variations in λ even with five pairs.

As described above, the number of pairs in the second multilayer reflector 202 is more preferably equal to or greater than five and further more preferably equal to or greater than ten from the viewpoint of curbing a change in oscillation wavelength. The number of pairs in the second multilayer reflector 202 is more preferably equal to or less than ten from the viewpoint of curbing degradation of heat dissipation.

### (Concerning Reduction of Bonding Failure)

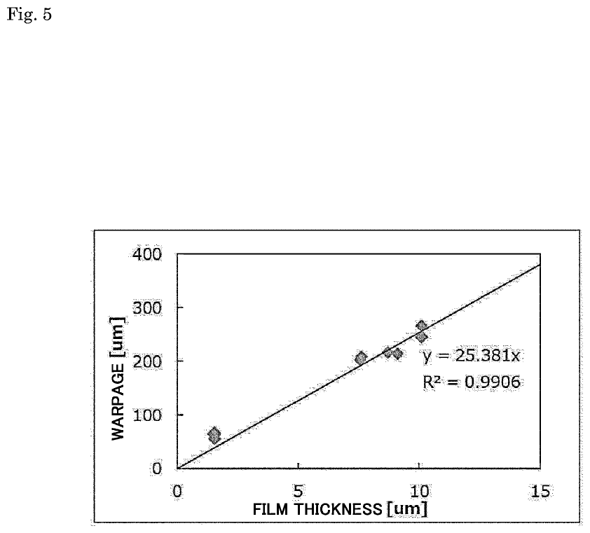

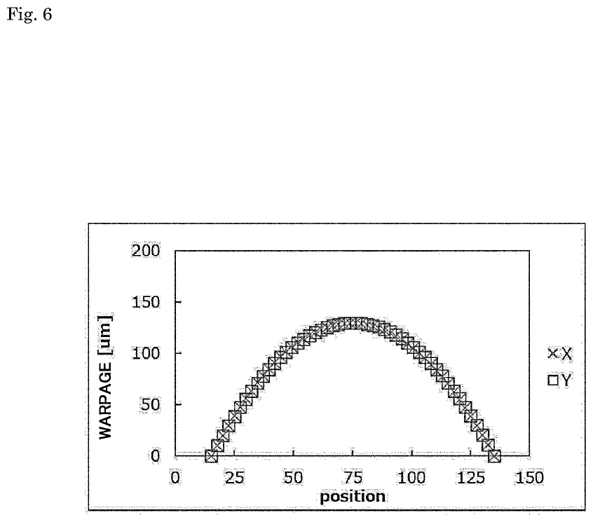

FIG. 5 is a graph illustrating a relationship between the total film thickness of GaAs/AlAs·DBR and warpage of the wafer. FIG. 6 is a graph illustrating a relationship between the position of GaAs/AlAs·DBR in the in-plane direction (in an XY plane) and warpage of the wafer. For example, the lattice constant of AlAs is larger than that of GaAs substrate (wafer) used as the substrate 101 by 0.12% in the GaAs-based DBR (GaAs/AlAs·DBR, for example) used as the first multilayer reflector 102, and warpage thus occurs in the GaAs substrate after crystal growth. As can be known from FIG. 5, the warpage increases as the number of pairs increases, that is, as the sum of the film thicknesses of AlAs increases, and this is thus disadvantageous for the attachment of the substrates. As can be known from FIG. 6, the warpage increases as it goes closer to the center of the wafer, and this is thus further disadvantageous for the attachment of the substrates.

On the other hand, the DBR (an InP/AlGaInAs·DBR, an AlInAs/AlGaInAs·DBR, or the like) used as the second multilayer reflector 202 is a lattice-matching system, and substantially no warpage thus occurs in the InP substrate (wafer).

Thus, it is possible to reduce the number of pairs in the GaAs-based DBR to obtain desired reflectance and to reduce warpage of the wafer by combining the GaAs-based DBR (the DBR that lattice-matches GaAs) and the InP-based DBR (the DBR that lattice-matches InP).

### (Concerning Number of Pairs in Each DBR in Hybrid DBR)

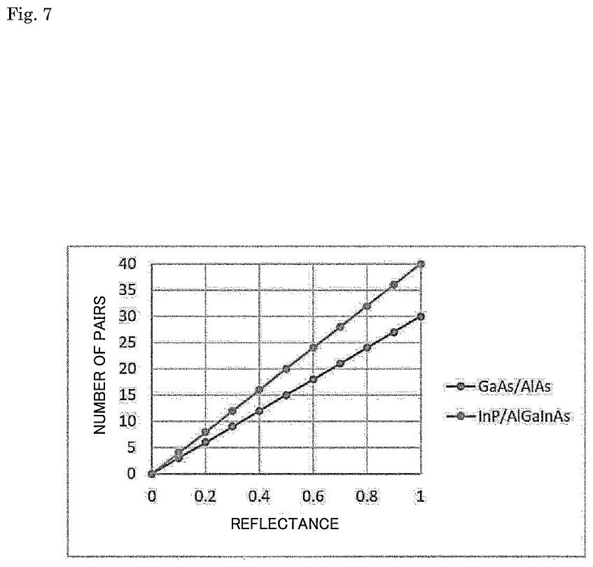

FIG. 7 is a graph illustrating relationships between reflectance and the number of pairs of the InP/AlGaInAs·DBRs and the GaAs/AlAs·DBRs. As can be known from FIG. 7, higher reflectance is obtained as the numbers of pairs increases in both the DBRs, reflectance that is close to one can be obtained with 30 pairs in the case of the GaAs/AlAs·DBR and with 40 pairs in the case of the InP/AlGaInAs·DBR.

### (Supplementary Explanation)

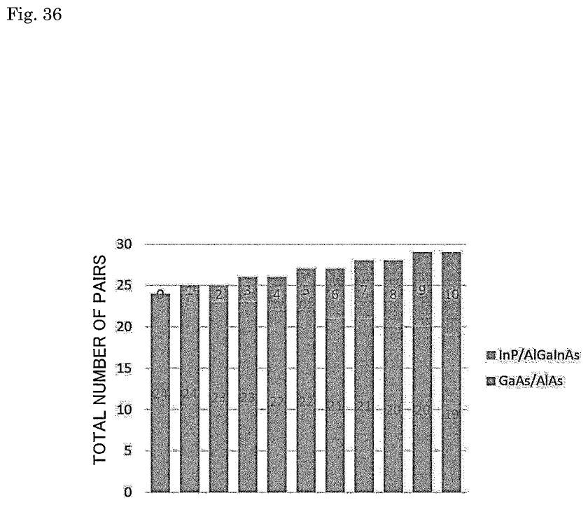

FIG. 36 is a diagram illustrating the number of pairs in each DBR necessary to obtain reflectance of equal to or greater than 99.9% in the hybrid DBR including the GaAs/AlAs·DBR and the InP/AlGaInAs·DBR. As can be known from FIG. 36, 19 or more pairs are needed in the GaAs/AlAs·DBR in a case where the number of pairs in the InP/AlGaInAs·DBR is ten, for example, in order to obtain the reflectance of equal to or greater than 99.9% in the hybrid DBR. Since 24 pairs are needed in the case where the GaAs/AlAs·DBR is used alone, the number of pairs decreases by five as compared with the case, and warpage of the wafer is thus reduced. Although heat dissipation deteriorates if the number of pairs in the InP/AlGaInAs·DBR is increased and the total film thickness of AlGaInAs is increased due to low heat conductivity of AlGaInAs, there are no large influences with about ten pairs, and there is a larger advantage of an improvement in productivity caused by reduction of a bonding failure inside of the wafer surface led by reduction of warpage achieved by reducing the film thickness of GaAs/AlAs·DBR.

### (Concerning Heat Dissipation)

The semiconductor DBR (for example, a DBR made of AlGaInAs/InP or AlGaInAs/AlInAs) that lattice-matches the InP substrate has lower heat conductivity and poorer heat dissipation than the semiconductor DBR (for example, GaAs/AlAs) made of a GaAs-based compound semiconductor. The surface emitting laser 10 can improve the heat dissipation as compared with the case where the lower reflector is configured only by the InP-based DBR since the first reflector R1 that is the lower reflector has a hybrid structure as a combination of the InP-based DBR and the GaAs-based DBR.

### (Concerning Stop Bandwidth)

The semiconductor DBR (for example, a DBR made of AlGaInAs/InP or AlGaInAs/AlInAs) that lattice-matches the InP substrate has a lower refractive index and a narrower stop bandwidth than the semiconductor DBR (for example, GaAs/AlAs) made of a GaAs-based semiconductor. According to the surface emitting laser 10, it is possible to widen the stop bandwidth as compared with a case where the lower reflector is configured only by the InP-based DBR since the first reflector R1 that is the lower reflector has a hybrid structure as a combination of the InP-based DBR and the GaAs-based DBR.

### <<Operations of Surface Emitting Laser>>

In the surface emitting laser 10, a current flowing in from the side of the positive electrode of the laser driver via the anode wiring 305 is constricted by the BTJ and is then injected to the active layer 204 via the second cladding layer 205. At this time, the active layer 204 emits light, the light reciprocates between the first and second reflectors R1 and R2 while being constricted by the BTJ and amplified by the active layer 204, and when an oscillation condition is satisfied, the light is emitted as laser light from the side of the second reflector R2. The current injected to the active layer 204 is caused to flow out to the side of the negative electrode of the laser driver via the first cladding layer 203 and the cathode electrode 306 in this order.

A part of heat generated by the tunnel junction layer 206 and the active layer 204 when the surface emitting laser 10 is driven is released from the side surface of the second multilayer reflector 202 to the outside via the first cladding layer 203, another portion is transmitted to the intermediate layer ML and the first multilayer reflector 102 via the first cladding layer 203 and the second multilayer reflector 202 and is then released to the outside view the side surface of the intermediate layer ML, the side surface of the first multilayer reflector 102, and the substrate 101. In this case, it is possible to improve heat dissipation as compared with a case where the first reflector R1 is configured only by a semiconductor multilayer reflector that lattice-matches InP, for example.

### First Example of Method for Manufacturing Surface Emitting Laser

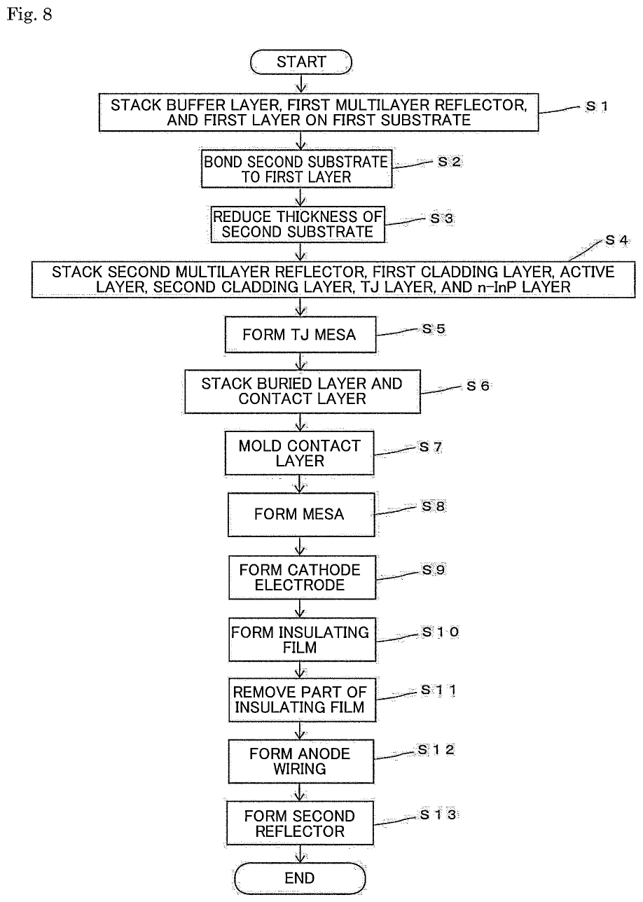

Hereinafter, a first example of a method for manufacturing the surface emitting laser 10 will be described with reference to the flowchart (Steps S1 to S13) in FIG. 8 and FIGS. 9A to 15B. Here, a plurality of surface emitting lasers 10 are simultaneously generated on a single wafer serving as a base material of the substrate 101 by a semiconductor manufacturing method using a semiconductor manufacturing device in an example. Then, the series of plurality of surface emitting lasers 10 integrated are separated to obtain a plurality of surface emitting lasers 10 with chip shapes (surface emitting laser chips).

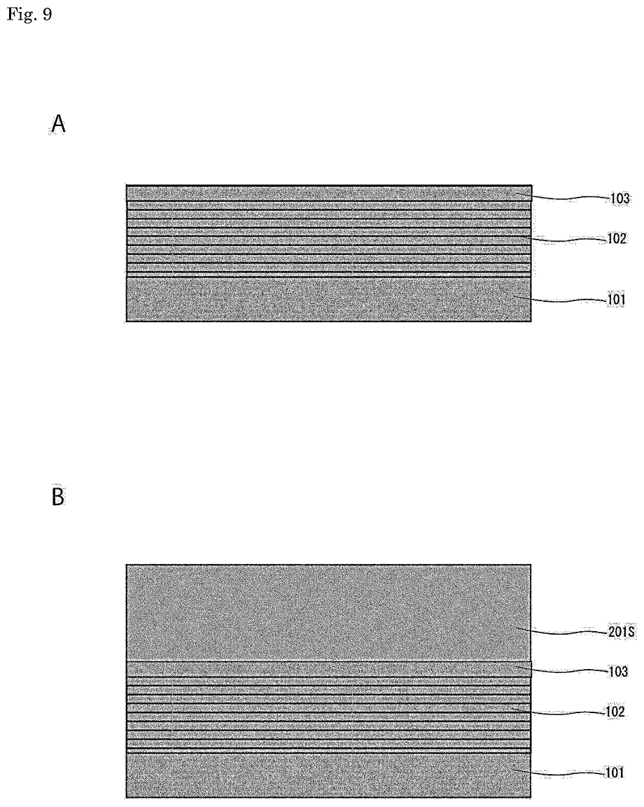

In first Step S1, the buffer layer, the first multilayer reflector 102, and the first layer 103 are stacked on a first substrate (see FIG. 9A). Specifically, the buffer layer, the first multilayer reflector 102 (for example, 25 pairs of GaAs/AlAs), and the first layer 103 (GaAs layer) are made to grow in this order on the substrate 101 (GaAs substrate) as the first substrate by a metal organic chemical vapor deposition (MOCVD) method in an example.

In next Step S2, a second substrate 201S is bonded to the first layer 103 (see FIG. 9B). Specifically, proton is injected to a depth of 100 nm, for example, into an n-InP substrate as the second substrate 201S from its surface, and the surface on the side on which the proton has been injected is bonded to the first layer 103. The bonding is preferably semiconductor direct bonding with no intervention of metal or the like. In a case where there is dust or the like generated during crystal growth on the surface on the side of the first layer 103, it is preferable to remove the dust or the like through wet etching, chemical mechanical polishing, or the like.

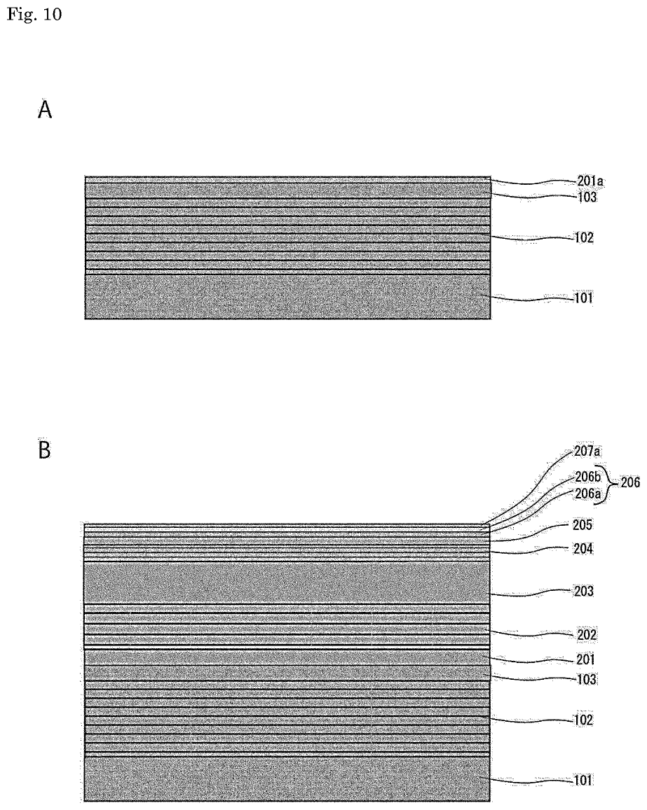

In next Step S3, the thickness of the second substrate 201S is reduced (see FIG. 10A). Specifically, the second substrate 201S is cut at the proton injection layer through thermal treatment. In this manner, a thin n-InP film 201a of 100 nm remains on the side of the first layer 103.

In next Step S4, the second multilayer reflector 202, the first cladding layer 203, the active layer 204, the second cladding layer 205, the tunnel junction layer 206, and the n-InP layer 207a are stacked (see FIG. 10B). Specifically, an n-InP layer as the second layer 201, the second multilayer reflector 202 (10 pairs of n-InP/n-AlGaInAs, for example), an n-InP layer as the first cladding layer 203, an AlGaInAs/AlGaInAs multiquantum well layer as the active layer 204, a p-InP layer as the second cladding layer 205, the tunnel junction layer 206, and the n-InP layer 207a are made to grow in this order on the thin n-InP film 201a (not shown in FIG. 10B) as the laminate generated in Step S3 by the MOCVD method.

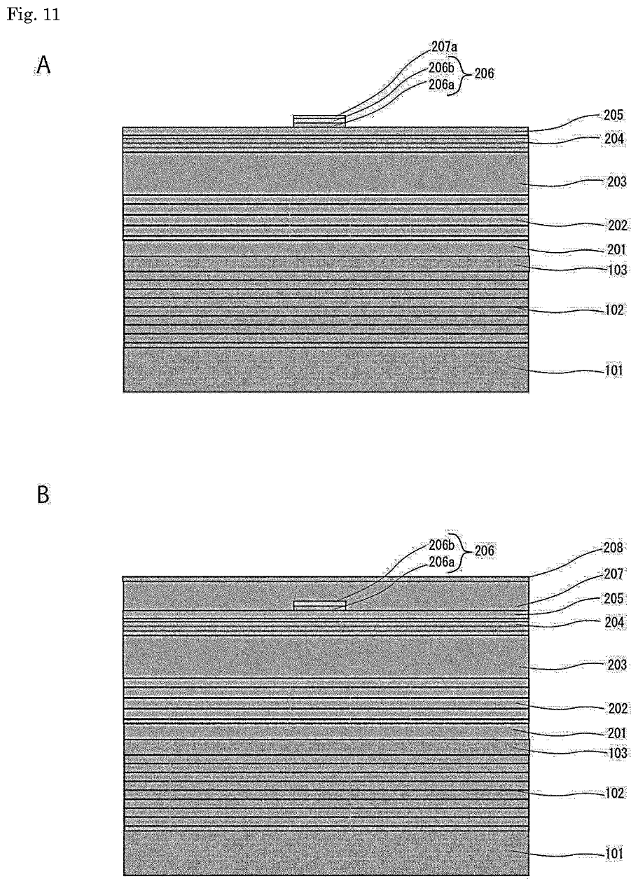

In next Step S5, a TJ mesa is formed (see FIG. 11A). Specifically, a TJ mesa (with a diameter of 10 μm, for example) including the tunnel junction layer 206 and the n-InP layer 207a is formed by photolithography. Wet etching is performed as etching, the n-InP layer 207a that is the topmost layer is etched with a mixture solution containing hydrogen bromide and hydrogen peroxide, and the tunnel junction layer 206 is etched with a mixture solution containing a sulfuric acid and hydrogen peroxide.

In next Step S6, the buried layer 207 and the contact layer 208 are stacked (see FIG. 11B). Specifically, an n-InP layer as the buried layer 207 and an n-InGaAs layer as the contact layer 208 are stacked in this order on the laminate generated in Step S5 by the MOCVD method. As a result, the TJ mesa is buried by the buried layer 207, and the contact layer 208 is formed on the buried layer 207.

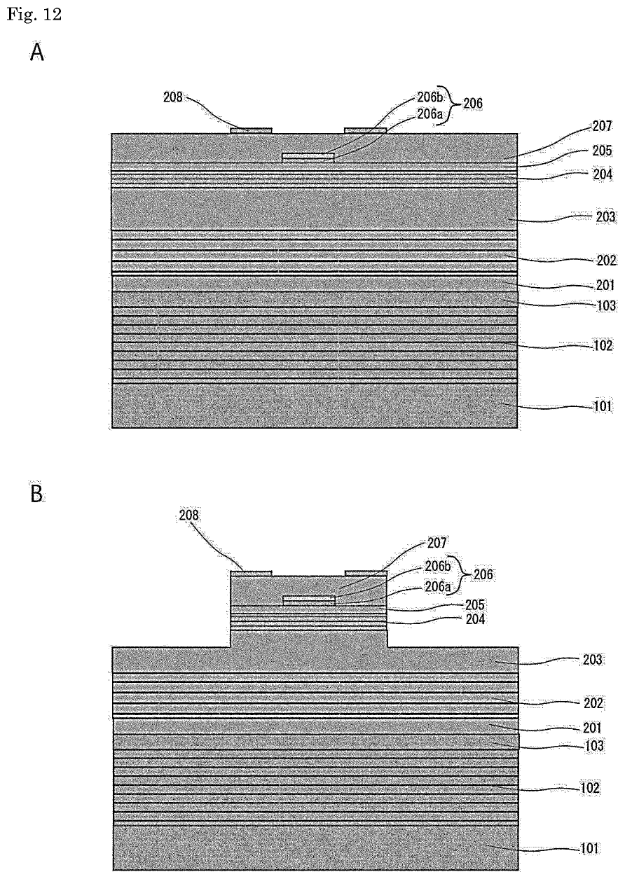

In next Step S7, the contact layer 208 is molded (see FIG. 12A). Specifically, the contact layer 208 is selectively etched and is molded into a donut shape with an inner diameter of 16 μm and an outer diameter of 50 μm, for example. Note that a ring-shaped anode electrode is formed on the donut-shaped contact layer 208 by a lift-off method, for example.

In next Step S8, a mesa is formed (see FIG. 12B). Specifically, a mesa adjusted to the outer diameter of the donut-shaped contact layer 208 is formed by photolithography. Dry etching is preferably performed as the etching at this time, and an etching bottom surface is positioned inside of the first cladding layer 203, for example.

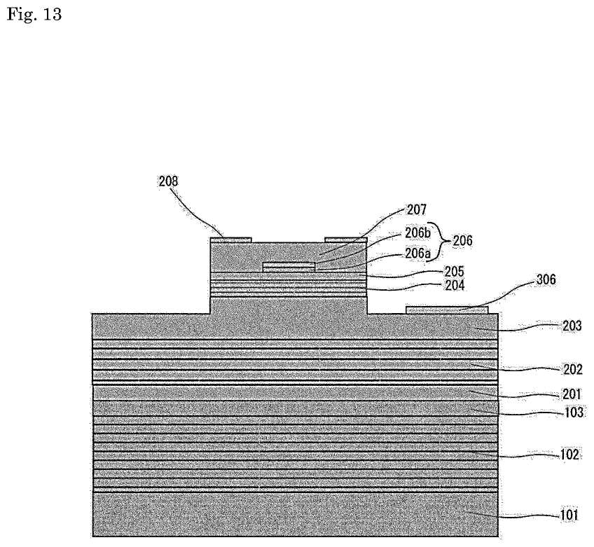

In next Step S9, the cathode electrode 306 is formed (see FIG. 13). Specifically, the cathode electrode 306 is formed on the first cladding layer 203 in the surroundings of the mesa by the lift-off method, for example. Film formation of an electrode material for the cathode electrode 306 at this time is performed by the sputtering method or the vapor deposition method.

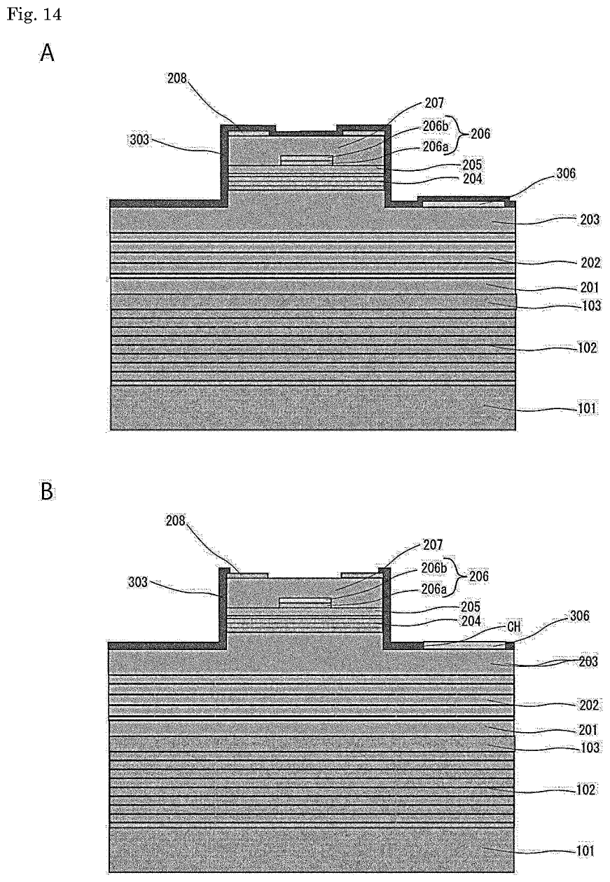

In next Step S10, the insulating film 303 is formed (see FIG. 14A). Specifically, the insulating film 303 is formed on the entire surface.

In next Step S11, a part of the insulating film 303 is removed (see FIG. 14B). Specifically, a part of the insulating film 303 covering the top portion of the mesa and a part covering the cathode electrode 306 are removed by dry etching, for example. As a result, the top portion of the mesa and the cathode electrode 306 are exposed.

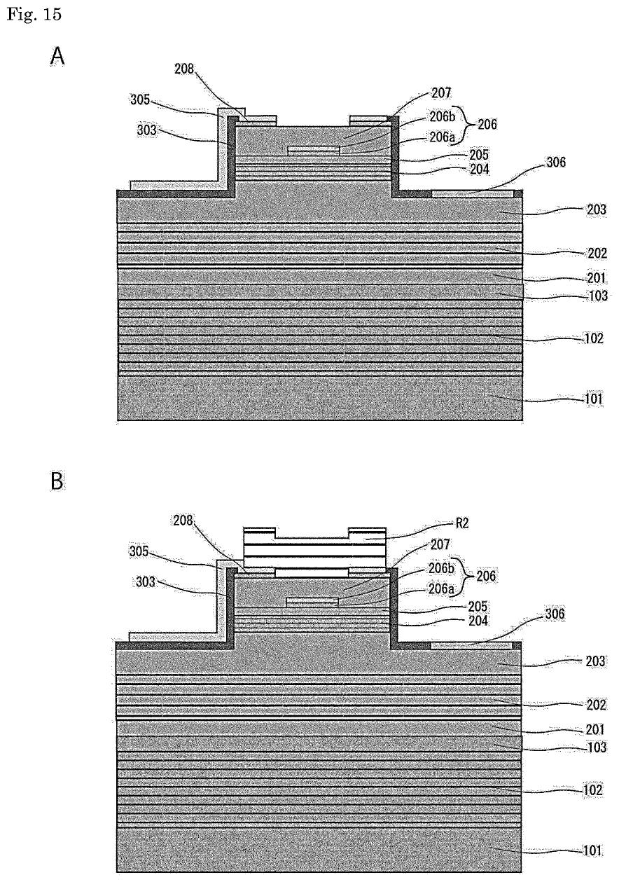

In next Step S12, the anode wiring 305 is formed (see FIG. 15A). Specifically, the anode wiring 305 that is partially (at the ring-shaped part) in contact with the contact layer 208 is formed along the insulating film 303 formed in the surroundings and on the side surface of the mesa by the lift off method, for example. Film formation of an electrode material for the anode wiring 305 at this time is performed by the sputtering method or the vapor deposition method.

In last Step S13, the second reflector R2 is formed (see FIG. 15B). Specifically, a dielectric multilayer (the number of pairs is seven) made of SiO₂/Ta₂O₅ is formed on the entire surface first. Then, the dielectric multilayer other than the dielectric multilayer formed on the top portion of the mesa is selectively removed by photolithography. As a result, the second reflector R2 is formed on the top portion of the mesa. Thereafter, the surface emitting laser 10 is split into each piece and is then mounted on a heat sink as needed, and the anode wiring 305 and the cathode electrode 306 are connected to corresponding terminals of the laser driver through wire bonding, for example.

### Second Example of Method for Manufacturing Surface Emitting Laser

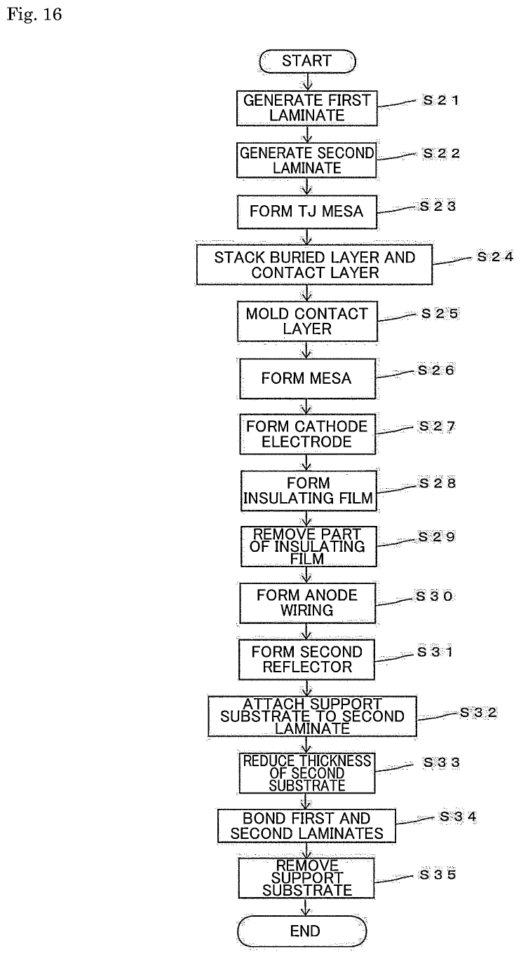

Hereinafter, a second example of the method for manufacturing the surface emitting laser 10 will be described with reference to the flowchart (Step S21 to S35) in FIG. 16, FIG. 9A and FIGS. 17A to 26. Here, a plurality of surface emitting lasers 10 are simultaneously generated on a single wafer serving as a base material of the substrate 101 by a semiconductor manufacturing method using a semiconductor manufacturing device in an example. Then, the series of plurality of surface emitting laser 10 integrated are separated to obtain a plurality of surface emitting lasers 10 with chip shapes (surface emitting laser chips).

In first Step S21, a first laminate is generated (see FIG. 9A). Specifically, the buffer layer, the first multilayer reflector 102 (25 pairs of GaAs/AlAs, for example), and the first layer 103 (GaAs layer) are made to grow in this order on the substrate 101 (GaAs substrate) as a first substrate by the metalorganic chemical vapor deposition method (MOCVD method) to thereby generate the first laminate in an example.

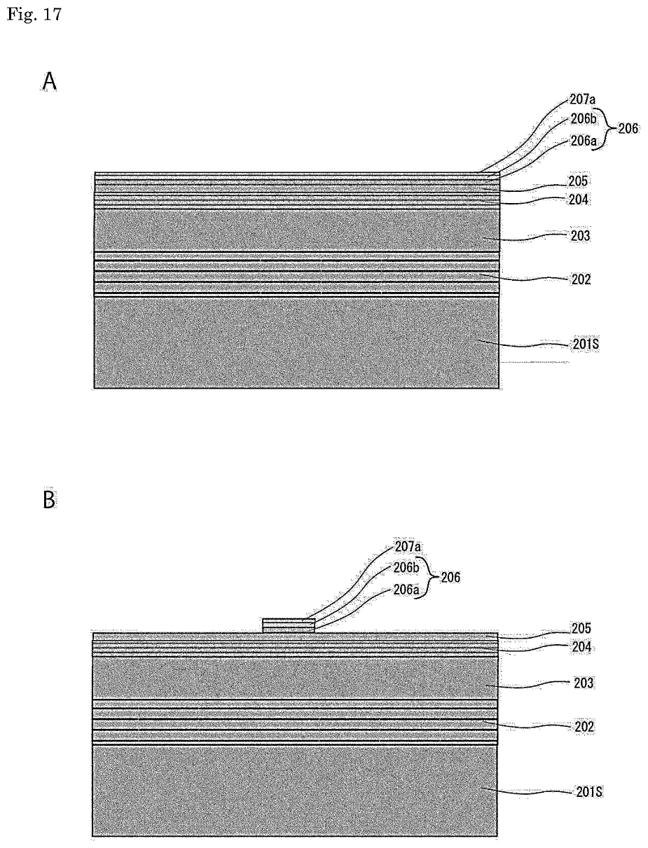

In next Step S22, a second laminate is generated (see FIG. 17A). Specifically, the second multilayer reflector 202 (10 pairs of n-InP/n-AlGaInAs, for example), an n-InP layer as the first cladding layer 203, an AlGaInAs/AlGaInAs multiquantum well layer as the active layer 204, a p-InP layer as the second cladding layer 205, the tunnel junction layer 206, and the n-InP layer 207a are made to grow in this order on an n-InP substrate as the second substrate 201S by the MOCVD method to thereby generate the second laminate.

In next Step S23, a TJ mesa is formed (see FIG. 17B). Specifically, a TJ mesa (with a diameter of 10 μm, for example) including the tunnel junction layer 206 and the n-InP layer 207a is formed in the second laminate by photolithography. Wet etching is performed as the etching at this time, the n-InP layer 207a as the topmost layer is etched with a mixture solution containing hydrogen bromide and hydrogen peroxide, and the tunnel junction layer 206 is etched with an aqueous mixture solution containing a sulfuric acid and hydrogen peroxide.

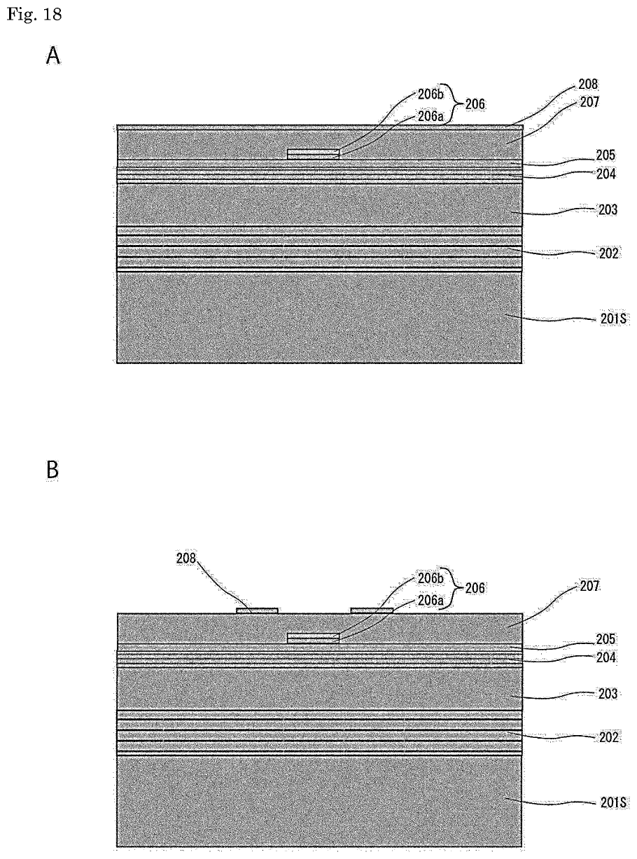

In next Step S24, the buried layer 207 and the contact layer 208 are stacked (see FIG. 18A). Specifically, an n-InP layer as the buried layer 207 and an n-InGaAs layer as the contact layer 208 are made to grow in this order on the second laminate by the MOCVD method. As a result, the TJ mesa is buried by the buried layer 207, and the contact layer 208 is formed on the buried layer 207.

In next Step S25, the contact layer 208 is molded (see FIG. 18B). Specifically, the contact layer 208 is selectively etched and is molded into a donut shape with an inner diameter of 16 μm and an outer diameter of 50 μm, for example. Note that a ring-shaped anode electrode is formed on the donut-shaped contact layer 208 by a lift-off method, for example.

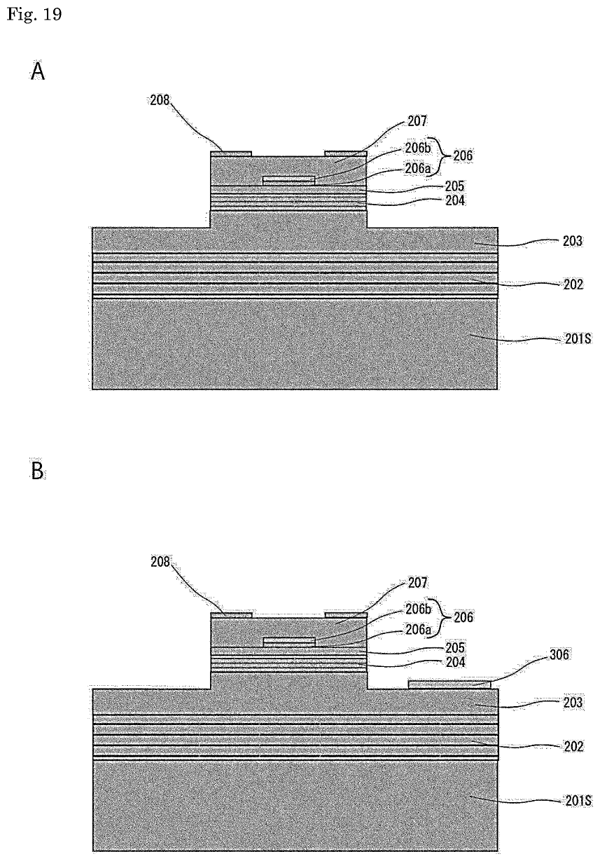

In next Step S26, a mesa is formed (see FIG. 19A). Specifically, the mesa adjusted in accordance with the outer diameter of the donut-shaped contact layer 208 is formed on the second laminate by photolithography. Dry etching is performed as the etching at this time, for example, and the etching bottom surface is positioned inside of the first cladding layer 203, for example.

In next Step S27, the cathode electrode 306 is formed (see FIG. 19B). Specifically, the cathode electrode 306 is formed on the first cladding layer 203 in the surroundings of the mesa of the second laminate by the lift-off method, for example. Film formation of an electrode material for the cathode electrode 306 at this time is performed by the sputtering method or the vapor deposition method.

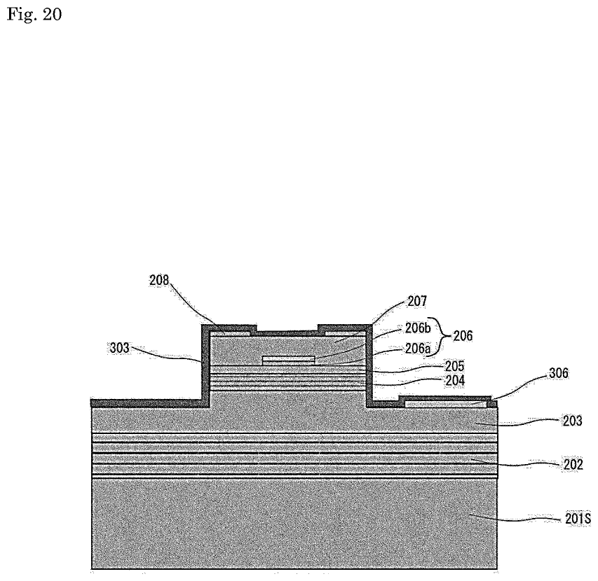

In next Step S28, the insulating film 303 is formed (see FIG. 20). Specifically, the insulating film 303 is formed on the entire surface of the second laminate.

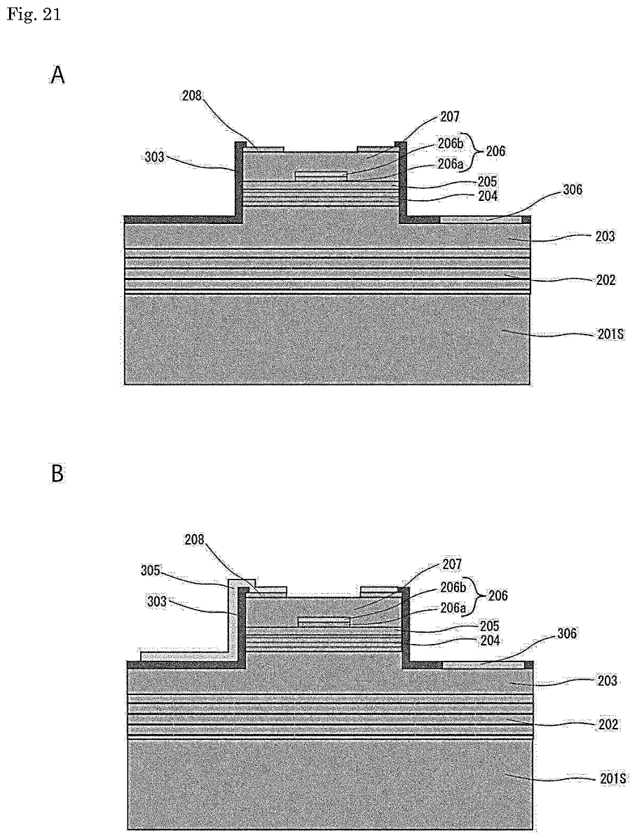

In next Step S29, a part of the insulating film 303 is removed (see FIG. 21A). Specifically, a part of the insulating film 303 covering the top portion of the mesa and a part covering the cathode electrode 306 are removed by dry etching, for example. As a result, the top portion of the mesa and the cathode electrode 306 are exposed.

In next Step S30, the anode wiring 305 is formed (see FIG. 21B). Specifically, the anode wiring 305 that is partially (at the ring-shaped part) in contact with the contact layer 208 is formed along the insulating film 303 formed in the surroundings and on the side surface of the mesa by the lift-off method, for example. Film formation of an electrode material for the anode wiring 305 at this time is performed by the sputtering method or the vapor deposition method.

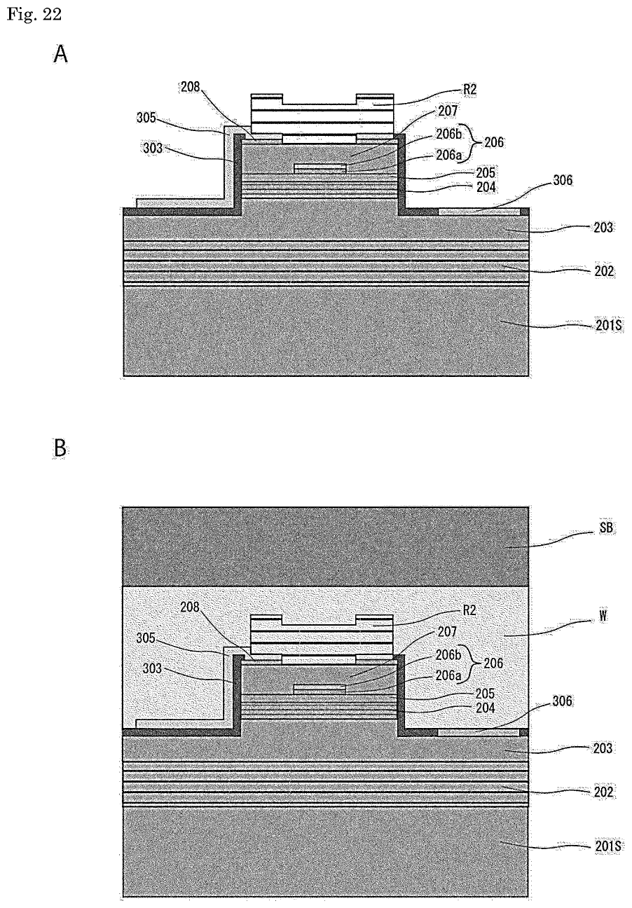

In next Step S31, the second reflector R2 is formed (see FIG. 22A). Specifically, a dielectric multilayer (the number of pairs is seven) made of SiO₂/Ta₂O₅ is formed on the entire surface of the second laminate first. Then, the dielectric multilayer other than the dielectric multilayer formed on the top portion of the mesa is selectively removed by photolithography. As a result, the second reflector R2 is formed on the top portion of the mesa.

In next Step S32, a support substrate SB is attached to the second laminate (see FIG. 22B). Specifically, the support substrate SB is attached to a surface of the second laminate on the side where the mesa is formed via a wax W, for example.

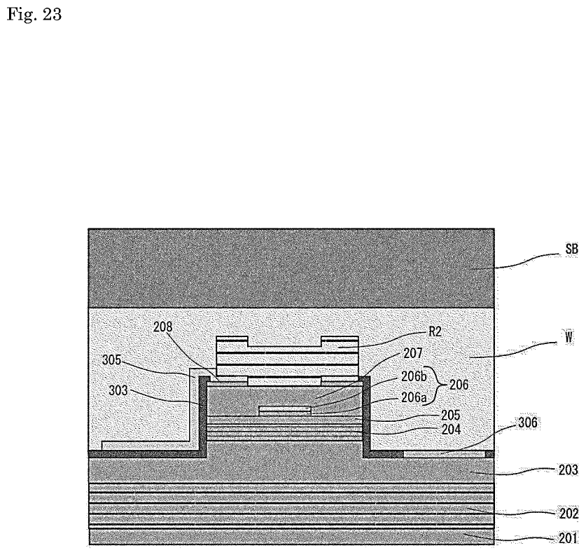

In next Step S33, the thickness of the second substrate 201S is reduced (see FIG. 23). Specifically, the rear surface (lower surface) of the second substrate 201S is polished by using a CMP device to thereby reduce the thickness. As a result, the n-InP layer as the second layer 201 remains.

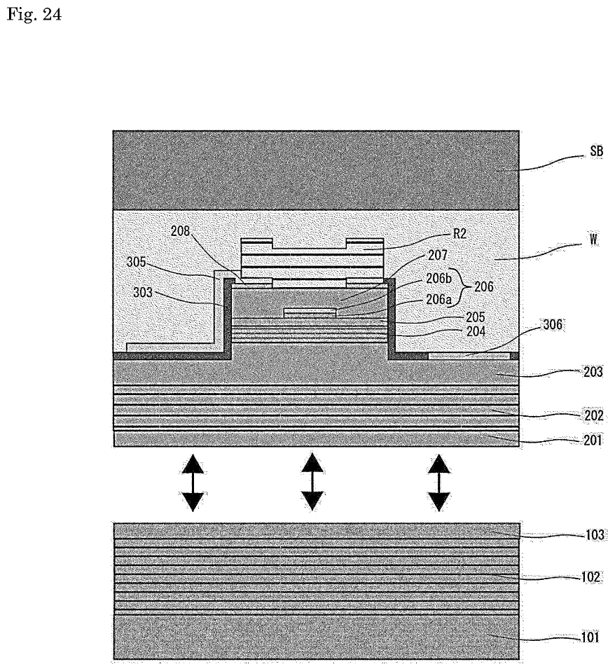

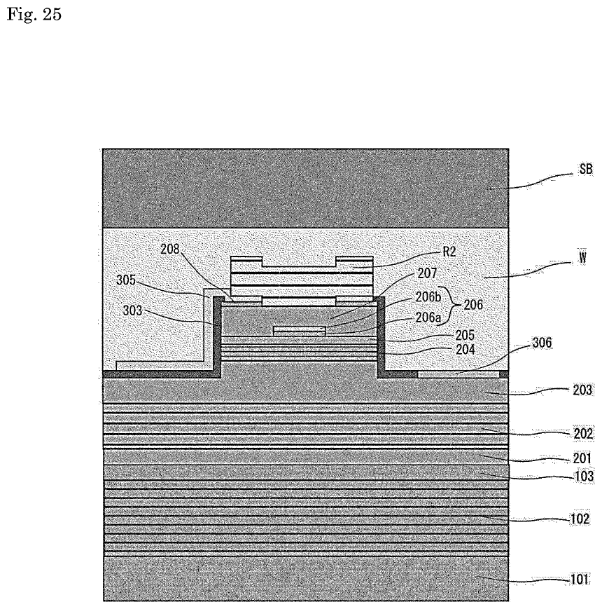

In next Step S34, the first and second laminates are bonded to each other (see FIGS. 24 and 25). Specifically, the GaAs layer as the first layer 103 in the first laminate and the n-InP layer as the second layer 201 in the second laminate are bonded to each other. The bonding is preferably semiconductor direct bonding with no intervention of metal or the like. In a case where there is dust or the like generated during crystal growth on the surface on the side of the first layer 103, it is preferable to remove the dust or the like through wet etching, chemical mechanical polishing, or the like.

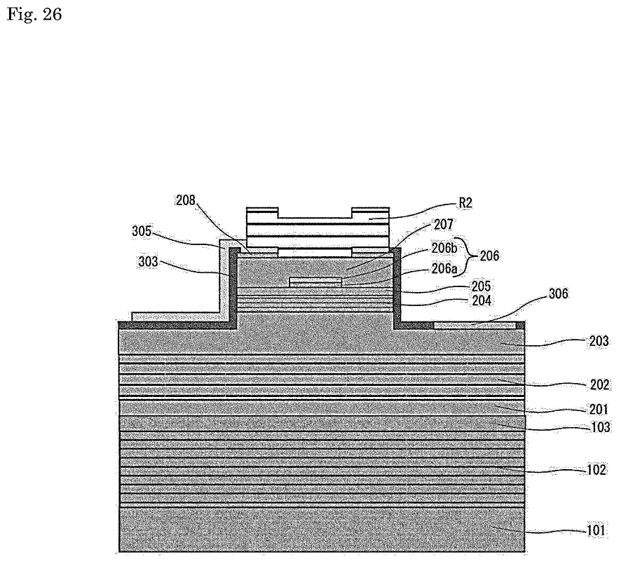

In final Step S35, the support substrate SB is removed (see FIG. 26). Specifically, the wax W is melted through heating, and the support substrate SB and the wax W are removed. Thereafter, the surface emitting laser 10 is split into each piece and is then mounted on a heat sink as needed, and the anode wiring 305 and the cathode electrode 306 are connected to corresponding terminals of the laser driver through wire bonding, for example.

### <<Effects of Surface Emitting Laser and Manufacturing Method Thereof>>

The surface emitting laser 10 according to the first example of the first embodiment of the present technology includes: the first structure ST1 that includes the first reflector R1; the second structure ST2 that includes the second reflector R2; and the active layer 204 that is disposed between the first and second structures ST1 and ST2, the first reflector R1 includes the stacked first and second multilayer reflectors 102 and 202, the first multilayer reflector 102 is made of the first material system, and the second multilayer reflector 202 is made of the second material system that is different from the first material system.

Since the first reflector R1 includes the first and second multilayer reflectors 102 and 202 made of the different material systems, the surface emitting laser 10 can compensate for disadvantages caused by one of the material systems (for example, poor heat dissipation and large warpage of the substrate) in the entire first reflector R1 by the other material system.

As a result, according to the surface emitting laser 10, it is possible to realize a surface emitting laser capable of compensating for the disadvantages of the material systems of the first and second multilayer reflectors 102 and 202 included in the first reflector R1 in the entire first reflector R1.

Both the first and second multilayer reflectors 102 and 202 are preferably semiconductor multilayer reflectors. In this manner, it is possible to secure high reflectance and conductivity in the entire first reflector R1. In this case, the degree of freedom in installing the cathode electrode 306, for example, is high.

The first material system is a compound semiconductor that lattice-matches GaAs, and the second material system is a compound semiconductor that lattice-matches InP. In this manner, it is possible to compensate for the disadvantage of large warpage of the substrate caused by the first material system by introducing the second material system and to compensate for the disadvantage of poor heat dissipation caused by the second material system by introducing the first material system in the first reflector R1. As a result, the surface emitting laser 10 can curb at least degradation of heat dissipation and degradation of a yield.

Additionally, since the first reflector R1 includes the first and second multilayer reflectors 102 and 202, the surface emitting laser 10 can curb warpage of the first multilayer reflector 102 and the first layer 103, can thereby curb a bonding failure, and can thus curb degradation of a yield as compared with a case where the first reflector R1 is configured only by a semiconductor multilayer reflector that lattice-matches GaAs, for example. Furthermore, since the first reflector R1 includes the first and second multilayer reflectors 102 and 202, the surface emitting laser 10 can curb degradation of heat dissipation as compared with the case where the first reflector R1 is configured only by the semiconductor multilayer reflector that lattice-matches InP, for example.

The lattice constant of the first material system preferably falls within a range of ±0.2% of the lattice constant of GaAs, and the lattice constant of the second material system preferably falls within a range of ±0.2% of the lattice constant of InP.

The second multilayer reflector 202 is disposed between the first multilayer reflector 102 and the active layer 204. In this manner, it is possible to cause the second multilayer reflector 202 to function as a substantial lower reflector of a resonator (a resonator of a long wavelength band) made of the second material system.

The active layer 204 is preferably made of a GaAs-based compound semiconductor (AlGaInAs, for example) or a GaAsP-based compound semiconductor (GaInAsP, for example). In this manner, it is possible to set the oscillation wavelength λ on the long wavelength side (the band of equal to or greater than 900 nm, for example).

The active layer 204 more preferably has a quantum well structure made of AlGaInAs or GaInAsP.

The light emitting wavelength of the active layer 204 is preferably equal to or greater than 1.2 μm and equal to or less than 2 μm.

The first structure ST1 further includes the intermediate layer ML disposed between the first and second multilayer reflectors 102 and 202, and the intermediate layer ML includes the first layer 103 that is disposed on the side of the first multilayer reflector 102 and is made of a compound semiconductor that lattice-matches GaAs and the second layer 201 that is disposed on the side of the second multilayer reflector 202 and is made of a compound semiconductor that lattice-matches InP. In this manner, it is possible to keep the surface of each multilayer reflector satisfactory since it is not necessary to use each of the surfaces of the first and second multilayer reflectors 102 and 202 as a bonding surface.

The first and second layers 103 and 201 are bonded to each other. In this manner, there is no need to cause the bonding interface to be present inside of a substantial resonator, and it is possible to curb degradation of in-plane uniformity of the oscillation wavelength λ.

The first structure ST1 further includes the first substrate 101 (a GaAs substrate, for example) that is disposed on the first reflector R1 on the side opposite to the side of the active layer 204. In this manner, it is possible to cause the first multilayer reflector 102 that is made of the compound semiconductor that lattice-matches GaAs to experience epitaxial growth on the first substrate 101.

The first material system is preferably GaAs/AlₓGa_{1-X}As (0<X≤1). In this manner, it is possible to cause the first multilayer reflector 102 to experience epitaxial growth on the GaAs substrate as the first substrate 101.

The second material system preferably includes AlGaInAs. In this manner, it is possible to cause the second multilayer reflector 202 to experience epitaxial growth on the second layer 201 (InP layer) or the second substrate 201S (InP substrate).

The second material system is preferably InP/AlGaInAs or AlInAs/AlGaInAs.

The thickness of the intermediate layer ML is preferably equal to or less than 300 nm. In this manner, it is possible to substantially curb an increase in thickness of the first reflector R1.

The number of pairs in the second multilayer reflector 202 is preferably equal to or greater than one and equal to or less than twenty. In this manner, it is possible to reduce warpage of the substrate and to curb deterioration of heat dissipation and narrowing of the stop bandwidth of the first reflector R1.

The second reflector R2 is a dielectric multilayer reflector. In this manner, it is possible to obtain high reflectance with a small number of pairs and to thereby achieve a thin thickness of the second reflector R2.

The second reflector R2 is preferably made of a material containing at least one kind from SiO₂, TiO₂, Ta₂O₅, SiN, amorphous Si, MgF₂, and CaF₂.

A first example of the method for manufacturing the surface emitting laser 10 includes: stacking a first semiconductor structure that includes the first multilayer reflector 102 and the first layer 103 as parts of the first reflector R1 on the first substrate 101; bonding the first semiconductor structure to the second substrate 201S; forming a second semiconductor structure that includes the second multilayer reflector 202 as another portion of the first reflector R1, the active layer 204, and the tunnel junction layer 206 in this order from the side of the second substrate 201S on the second substrate 201S; reducing the thickness of the second substrate 201S; and forming the second reflector R2 on the second semiconductor structure.

According to the first example of the method for manufacturing the surface emitting laser 10, it is possible to manufacture, through a small number of processes, the surface emitting laser 10 capable of compensating for the disadvantage caused by the material systems of the first and second multilayer reflectors included in the first reflector R1 in the entire first reflector R1.

The reducing of the thickness is preferably performed between the bonding of the first semiconductor structure to the second substrate 201S and the forming of the second semiconductor structure.

A second example of the method for manufacturing the surface emitting laser 10 includes: generating the first laminate including the first multilayer reflector 102 and the first layer 103 as parts of the first reflector R1 on the first substrate 101; generating the second laminate including the second multilayer reflector 202 that is another portion of the first reflector R2, the active layer 204, the tunnel junction layer 206, and the second reflector R2 in this order on the second substrate 201S; reducing the thickness of the second substrate 201S; and bonding the first and second laminates.

According to the second example of the method for manufacturing the surface emitting laser 10, it is possible to manufacture the surface emitting laser 10 capable of compensating for the disadvantage caused by the material systems of the first and second multilayer reflectors included in the first reflector R1 in the entire first reflector R1.

The reducing of the thickness is preferably performed between the generating of the second laminate and the bonding of the first and second laminates.

### 2. Surface Emitting Laser According to Second Example of First Embodiment of Present Technology

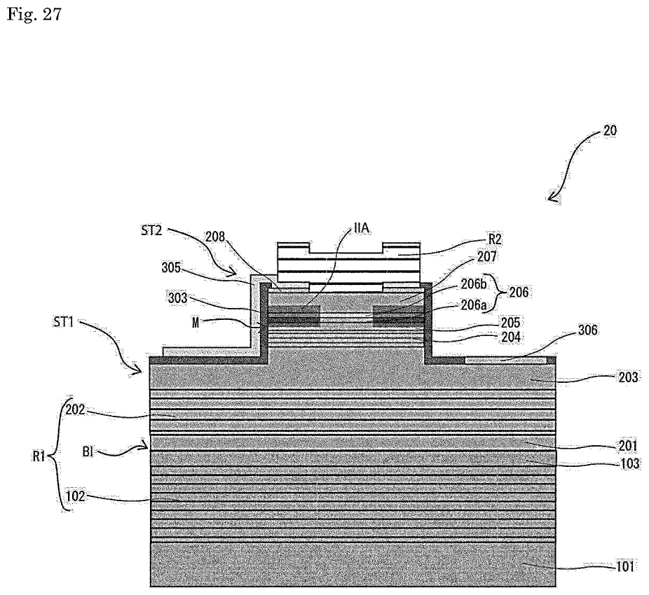

FIG. 27 is a sectional view of a surface emitting laser 20 according to a second example of the first embodiment of the present technology. The surface emitting laser 20 has a configuration similar to the surface emitting laser 10 according to the first example other than that the tunnel junction layer 206 is not of the buried type as illustrated in FIG. 27.

In the surface emitting laser 20, the tunnel junction layer 206 is a wide flat layer rather than a mesa-shaped layer. An ion injection region IIA with an annular shape, for example, is formed at a portion in the surroundings of the tunnel junction layer 206, and the surrounding portion is thereby caused to have a high resistance. In other words, the center portion of the tunnel junction layer 206 with a low resistance serves as a current passing region, and the surrounding portion with a high resistance serves as a current constriction region. The inner diameter (the current constriction diameter) of the ion injection region IIA is, for example, 10 μm. Proton (H⁺), for example, is used as the ion for the ion injection region IIA.

In the surface emitting laser 20, the number of pairs in the dielectric multilayer reflector as the second reflector R2 is, for example, eight.

The surface emitting laser 20 can be manufactured by a manufacturing method that is substantially similar to the method for manufacturing the surface emitting laser 10 according to the first example. However, a portion (lower portion) of the buried layer 207 is caused to grow on the tunnel junction layer 206, a protective film made of SiO₂, for example, is then formed by photolithography on a region corresponding to the current passing region of the portion, and ion injection is performed by using the protective film as a mask. Thereafter, another portion (upper portion) of the buried layer 207 is caused to grow again.

According to the surface emitting laser 20, it is possible to obtain effects that are similar to those of the surface emitting laser 10 according to the first example.

### 3. Surface Emitting Laser According to Third Example of First Embodiment of Present Technology

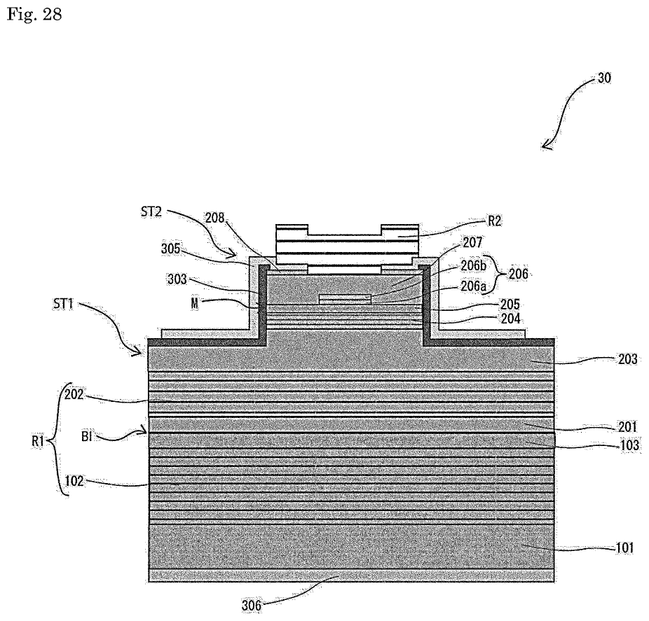

FIG. 28 is a sectional view of a surface emitting laser 30 according to a third example of the first embodiment of the present technology. The surface emitting laser 30 has a configuration that is similar to that of the surface emitting laser 10 according to the first example other than that the anode wiring 305 and the cathode electrode 306 are disposed on different surface sides as illustrated in FIG. 28.

In the surface emitting laser 30, a current injected into the active layer 204 via an anode wiring 305, the contact layer 208, the BTJ, and the second cladding layer 205 reaches a cathode electrode 306 via the first cladding layer 203, the second multilayer reflector 202, the intermediate layer ML, the first multilayer reflector 102, and the substrate 101.

The surface emitting laser 30 can be manufactured by a manufacturing method that is substantially similar to the method for manufacturing the surface emitting laser 10 according to the first example.

According to the surface emitting laser 30, it is possible to obtain effects that are similar to those of the surface emitting laser 10 according to the first example.

### 4. Surface Emitting Laser According to Fourth Example of First Embodiment of Present Technology

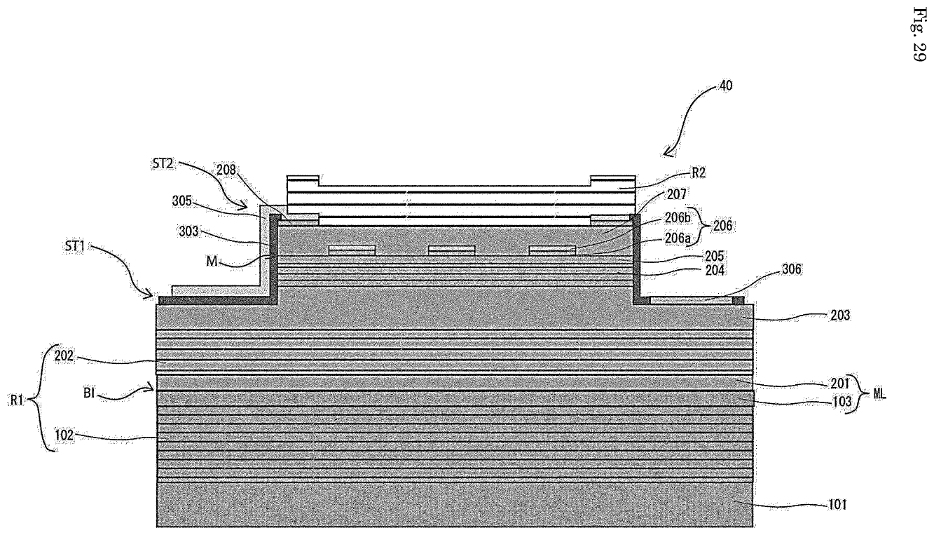

FIG. 29 is a sectional view of a surface emitting laser 40 according to a fourth example of the first embodiment of the present technology. The surface emitting laser 40 has a configuration that is similar to that of the surface emitting laser 10 according to the first example other than that the plurality of tunnel junction layers 206 are disposed in an array shape in the BTJ as illustrated in FIG. 29.

In the active layer 204, a plurality of regions corresponding to the plurality of tunnel junction layers 206 serve as light emitting regions. In other words, the surface emitting laser 40 substantially configures a surface emitting laser array. Here, the plurality of (3×3=9, for example) tunnel junction layers 206 are disposed in a two-dimensional array shape with a pitch of 50 μm, for example, in an in-plane direction (the directions that is parallel with and is perpendicular to the paper surface of FIG. 29, for example) in an example.

The surface emitting laser 40 can be manufactured by a manufacturing method that is substantially similar to the method for manufacturing the surface emitting laser 10 according to the first example.

According to the surface emitting laser 40, it is possible to obtain effects that are similar to those of the surface emitting laser 10 according to the first example and to emit a plurality of laser light beams through alignment in the arrays.

### 5. Surface Emitting Laser According to First Modification of First Example of First Embodiment of Present Technology

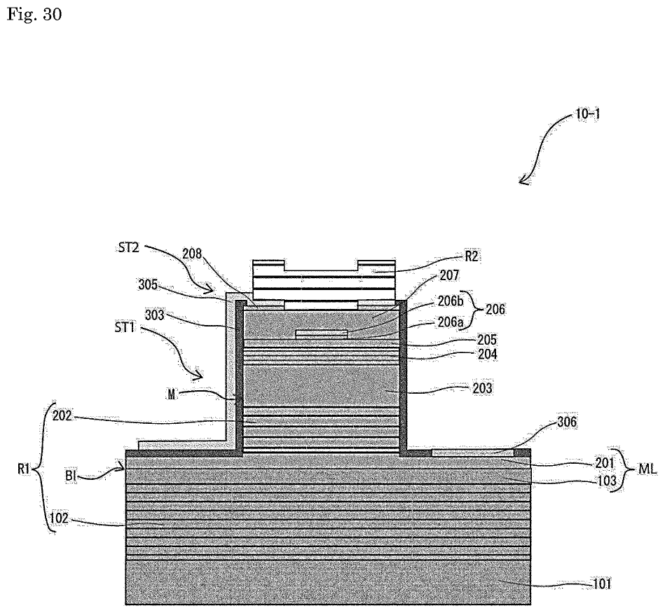

FIG. 30 is a sectional view of a surface emitting laser 10-1 according to a first modification of the first example of the first embodiment of the present technology. The surface emitting laser 10-1 has a configuration that is similar to that of the surface emitting laser 10 according to the first example other than that the bottom surface of the mesa M is positioned inside of the second layer 201 of the intermediate layer ML as illustrated in FIG. 30.

The surface emitting laser 10-1 can be manufactured by a manufacturing method that is substantially similar to the method for manufacturing the surface emitting laser 10 according to the first example.

According to the surface emitting laser 10-1, it is possible to obtain effects that are similar to those of the surface emitting laser 10 according to the first example.

### 6. Surface Emitting Laser According to Second Modification of First Example of First Embodiment of Present Technology

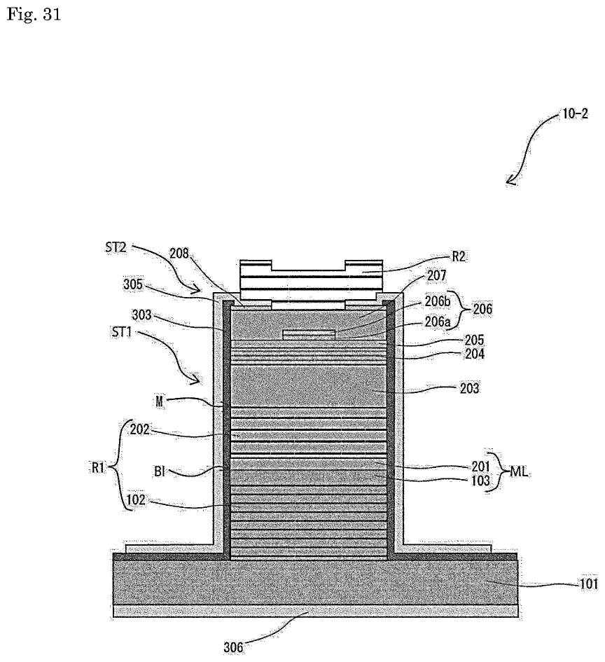

FIG. 31 is a sectional view of a surface emitting laser 10-2 according to a second modification of the first example of the first embodiment of the present technology. The surface emitting laser 10-2 has a configuration that is similar to the surface emitting laser 10 according to the first example other than that the bottom surface of the mesa M is the front surface (upper surface) of the substrate 101 and the cathode electrode 306 is provided on the rear surface (lower surface) of the substrate 101 as illustrated in FIG. 31.

The surface emitting laser 10-2 can be manufactured by a manufacturing method that is substantially similar to the method for manufacturing the surface emitting laser 10 according to the first example.

According to the surface emitting laser 10-2, it is possible to obtain effects that are similar to those of the surface emitting laser 10 according to the first example.

Note that as modifications of the surface emitting laser according to the first example, a modification in which the bottom surface of the mesa M is positioned inside of the second multilayer reflector 202, a modification in which the bottom surface of the mesa M is positioned inside of the first layer 103 of the intermediate layer ML, a modification in which the bottom surface of the mesa M is positioned inside of the first multilayer reflector 102, and a modification in which the bottom surface of the mesa M is positioned inside of the substrate 101 are also listed.

### 7. Surface Emitting Laser According to Modification of Second Example of First Embodiment of Present Technology

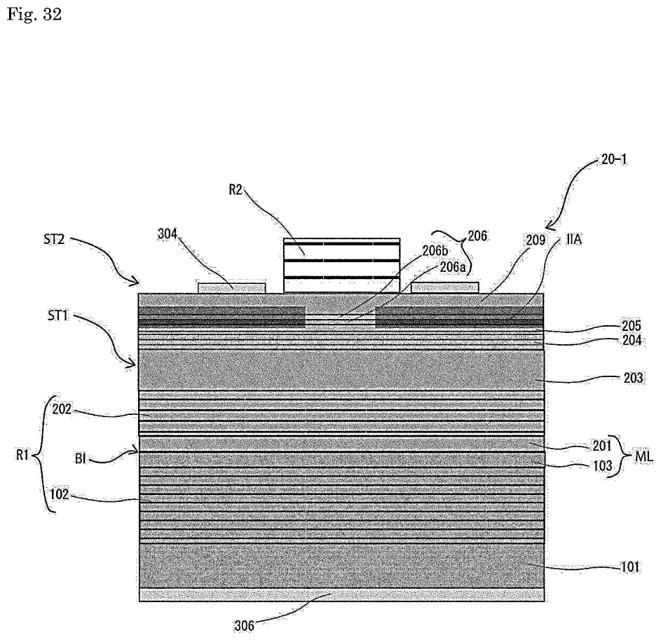

FIG. 32 is a sectional view of a surface emitting laser 20-1 according to a modification of the second example of the first embodiment of the present technology. The surface emitting laser 20-1 has a configuration that is substantially similar to that of the surface emitting laser 20 according to the second example other than that the mesa M is not formed.

In the surface emitting laser 20-1, a third cladding layer 209 (an n-InP layer, for example) is stacked on a solid tunnel junction layer 206 instead of the buried layer 207. The second reflector R2 is provided on a region of the third cladding layer 209 corresponding to the light emitting region. A ring-shaped anode electrode 304, for example, is provided on the region of the third cladding layer 209 in the surroundings of the second reflector R2 to surround the second reflector R2. The anode electrode 304 is made of a material that is similar to the material for the anode wiring 305, for example.

The surface emitting laser 20-1 can be manufactured by a manufacturing method that is substantially similar to the method for manufacturing the surface emitting laser 20 according to the second example.

According to the surface emitting laser 20-1, it is possible to simplify a manufacturing process in accordance with unnecessity of formation of the mesa M.

### 8. Surface Emitting Laser According to Modification of Third Example of First Embodiment of Present Technology

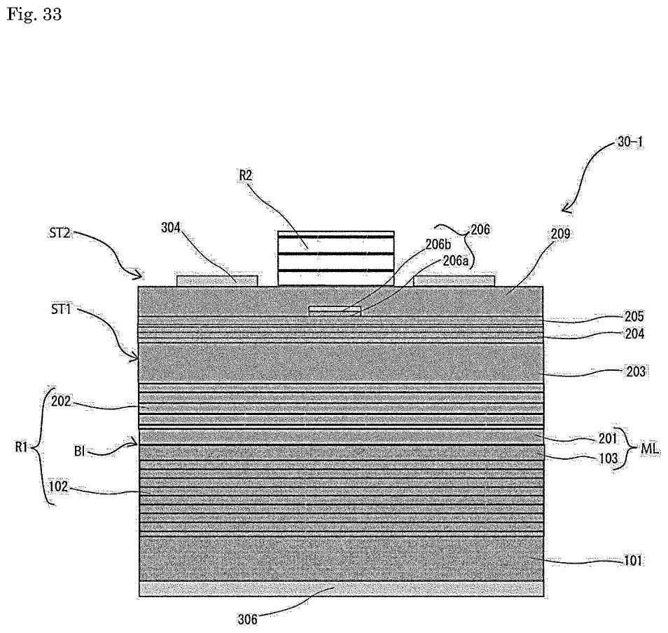

FIG. 33 is a sectional view of a surface emitting laser 30-1 according to a modification of the third example of the first embodiment of the present technology. The surface emitting laser 30-1 has a configuration that is substantially similar to the surface emitting laser 30 according to the third example other than that the mesa M is not formed.

In the surface emitting laser 30-1, the third cladding layer 209 (an n-InP layer, for example) is stacked on the solid tunnel junction layer 206 instead of the buried layer 207. The second reflector R2 is provided on the region of the third cladding layer 209 corresponding to the light emitting region. The ring-shaped anode electrode 304, for example, is provided on the region of the third cladding layer 209 in the surroundings of the second reflector R2 to surround the second reflector R2. The cathode electrode 306 is provided on the rear surface (lower surface) of the substrate 101.

The surface emitting laser 30-1 can be manufactured by a manufacturing method that is substantially similar to the method for manufacturing the surface emitting laser 30 according to the third example.

According to the surface emitting laser 30-1, it is possible to simplify a manufacturing process in accordance with unnecessity of formation of the mesa M.

### 9. Surface Emitting Laser According to Modification of Fourth Example of First Embodiment of Present Technology

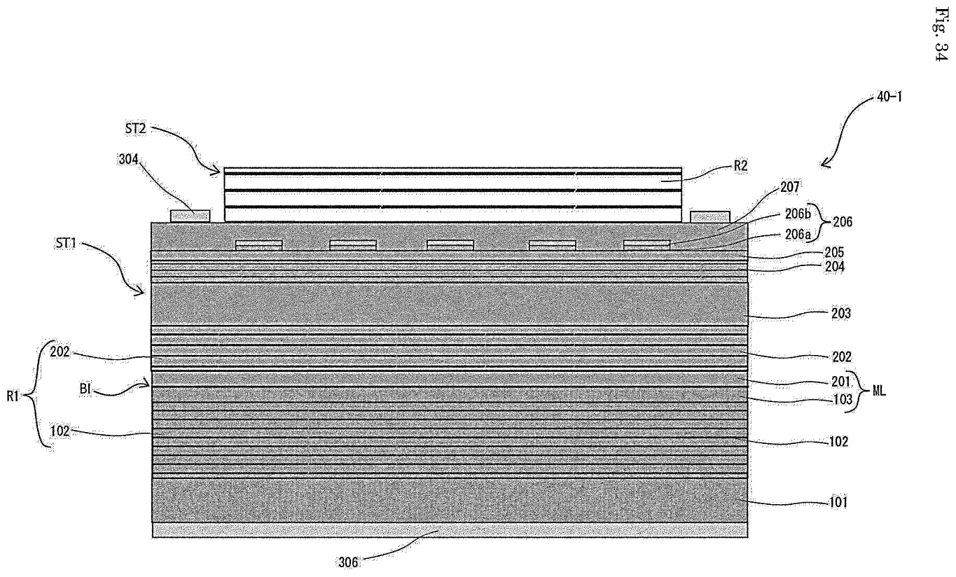

FIG. 34 is a sectional view of a surface emitting laser 40-1 according to a modification of the fourth example of the first embodiment of the present technology. The surface emitting laser 40-1 has a configuration that is substantially similar to that of the surface emitting laser 40 according to the fourth example other than that the mesa M is not formed as illustrated in FIG. 34.

In the surface emitting laser 40-1, the second reflector R2 is provided to straddle a plurality of regions of the buried layer 207 corresponding to a plurality of light emitting regions. The ring-shaped anode electrode 304, for example, is provided on the region of the buried layer 207 in the surroundings of the second reflector R2 to surround the second reflector R2. The cathode electrode 306 is provided on the rear surface (lower surface) of the substrate 101.

In the surface emitting laser 40-1, a plurality of (5×5=25, for example) of tunnel junction layers 206 that set the light emitting regions of the active layer 204 are disposed at a pitch of 50 μm, for example, in a two-dimensional array shape in the in-plane direction (the directions that is parallel with and is perpendicular to the paper surface of FIG. 34, for example).

The surface emitting laser 40-1 can be manufactured by a manufacturing method that is substantially similar to the method for manufacturing the surface emitting laser 40 according to the fourth example.

According to the surface emitting laser 40-1, it is possible to simplify a manufacturing process in accordance with unnecessity of formation of the mesa M.

### 10. Surface Emitting Laser According to Modification of First Embodiment of Present Technology

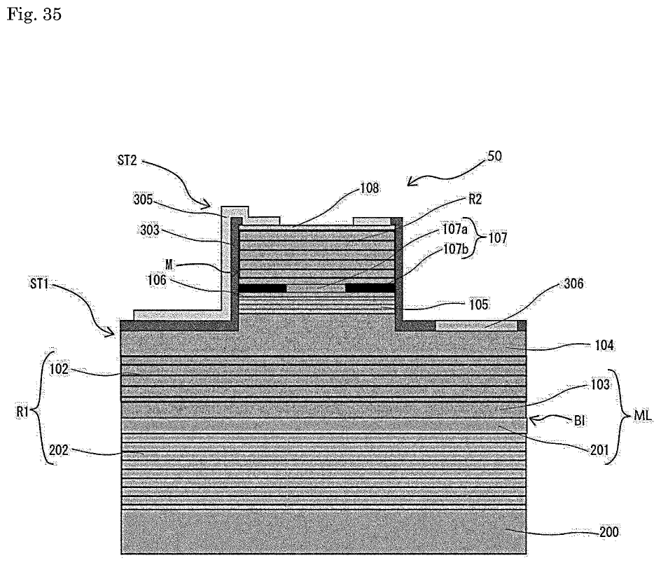

FIG. 35 is a sectional view of a surface emitting laser 50 according to a modification of the first embodiment of the present technology. In the surface emitting laser 50, a positional relationship between the first and second multilayer reflectors 102 and 202 is opposite to that in the surface emitting laser 10 according to the first example as illustrated in FIG. 35.

In the surface emitting laser 50, the second multilayer reflector 202, the second layer 201, the first layer 103, the first multilayer reflector 102, the first cladding layer 104, the active layer 105, the second cladding layer 106, the second reflector R2 including the oxidation constriction layer 107, and the contact layer 108 are stacked in this order on an InP substrate as a substrate 200 in an example.

In the surface emitting laser 50, a mesa M is configured to include a portion (upper portion) of the first cladding layer 104, the active layer 105, the second cladding layer 106, the second reflector R2 including the oxidation constriction layer 107, and the contact layer 108 in an example.

The first cladding layer 104 is made of an n-type GaAs-based compound semiconductor (n-AlGaAs, for example). The second cladding layer 106 is made of a p-type GaAs-based compound semiconductor (p-AlGaAs).

The active layer 105 has a quantum well structure including a barrier layer and a quantum well layer made of a GaAs-based compound semiconductor (AlGaAs, for example). The quantum well structure may be a single quantum well structure (QW structure) or may be a multiquantum well structure (MQW structure).

The oxidation constriction layer 107 includes a non-oxidation region 107a made of AlAs and an oxidation region 107b made of an oxide (Al₂O₃, for example) of AlAs surrounding the periphery thereof in an example. The oxidation constriction layer 107 has a current/light confinement function.

The second reflector R2 of the surface emitting laser 50 is a semiconductor multilayer reflector of a second conductive type (p-type, for example) and has a structure in which a plurality of kinds (two kinds, for example) of semiconductor layers (refractive index layers) with mutually different refractive indexes are alternately stacked with an optical thickness of a wavelength of ¼ the oscillation wavelength in an example. Each refractive index layer of the second reflector R2 is made of a GaAs-based compound semiconductor (p-AlGaAs, for example) of a second conductive type (p-type, for example).

The contact layer 108 is disposed on the second reflector R2. The contact layer 108 is made of a GaAs-based compound semiconductor of the second conductive type (p-type, for example), for example.

A method for manufacturing the surface emitting laser 50 is obtained by reversing the method for producing the stacked structure made of the compound semiconductor that lattice-matches the InP substrate and the stacked structure made of the GaAs-based compound semiconductor from those in the method for manufacturing the surface emitting laser 10 according to the first example.

According to the surface emitting laser 50, the first reflector R1 includes the first and second multilayer reflectors 102 and 202 made of the different material systems, and it is thus possible to compensate for a disadvantage (for example, poor heat dissipation or large warpage of the substrate) caused by one of the material systems by the other material system in the entire first reflector R1.

The first material system configuring the first multilayer reflector 102 is a compound semiconductor that lattice-matches GaAs, and the second material system that configures the second multilayer reflector 202 is a compound semiconductor that lattice-matches InP. In this manner, it is possible to compensate for the disadvantage of large warpage of the substrate caused by the first material system by introducing the second material system and to compensate for the disadvantage of poor heat dissipation caused by the second material system by introducing the first material system in the first reflector R1. As a result, the surface emitting laser 50 can curb at least degradation of heat dissipation and degradation of a yield.

Additionally, since the first reflector R1 includes the first and second multilayer reflectors 102 and 202, the surface emitting laser 50 can curb warpage of the first multilayer reflector 102 and the first layer 103, to thereby curb a bonding failure, and thus to curb degradation of a yield as compared with a case where the first reflector R1 is configured only by the semiconductor multilayer reflector that lattice-matches GaAs, for example. Furthermore, according to the surface emitting laser 50, the first reflector R1 includes the first and second multilayer reflectors 102 and 202, and it is thus possible to curb degradation of heat dissipation as compared with a case where the first reflector R1 is configured only by the semiconductor multilayer reflector that lattice-matches InP, for example.

Incidentally, the surface emitting laser array is a structure that is advantageous to obtain a high output. For example, JP H2017-168715A discloses an example of a typical surface emitting laser array. The surface emitting laser array includes a plurality of mesa-shaped light emitting portions that have oxidation constriction layers. The oxidation constriction layers are obtained by partially oxidizing an AlAs layer from a mesa side surface and are adapted to constrict a current. The oxidation constriction layers also have an effect of confining light in a lateral direction since the refractive index also decreases due to oxidation.

However, the surface emitting laser arrays have problems that a heat exhaust property is low, minute cracking is formed at a stepped portion, and a yield and reliability thus deteriorate since the light emitting portions have a mesa shape. Moreover, there is also a problem that a material that is easily oxidized like AlAs is not present in an InP-based VCSEL suitable for the 1.4 μm band and the surface emitting laser array cannot be produced by a similar method.

Thus, the present inventors have focused particularly on the heat exhaust property from among the above problems and have developed a surface emitting laser according to a second embodiment of the present technology as a high-output surface emitting laser capable of curbing at least degradation of the heat exhaust property.

Hereinafter, the surface emitting laser according to the second embodiment of the present technology will be described in detail by listing several examples.

### 11. Surface Emitting Laser According to First Example of Second Embodiment of Present Technology

Hereinafter, a surface emitting laser 51 according to a first example of the second embodiment of the present technology will be described.

### <<Configuration of Surface Emitting Laser>>

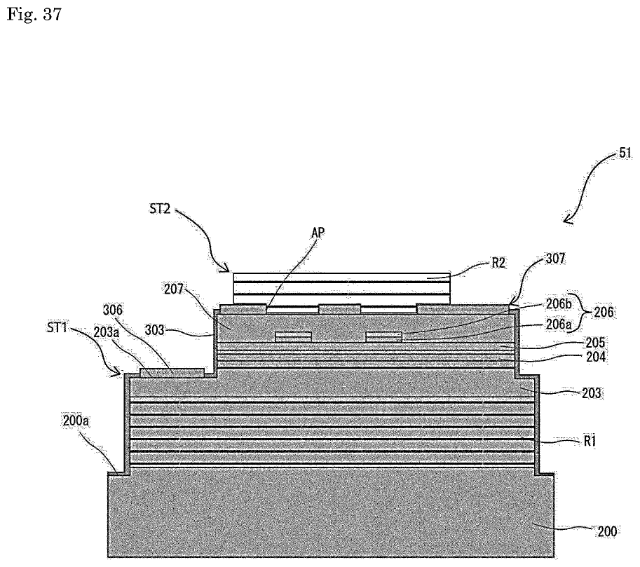

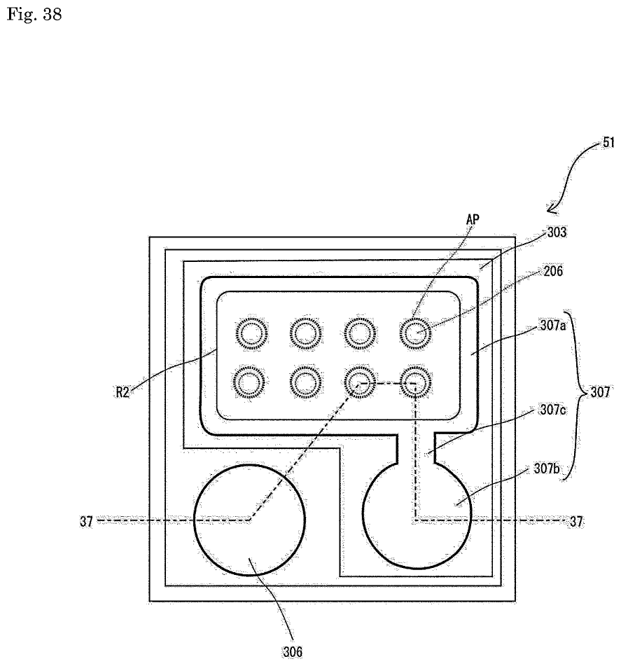

FIG. 37 is a sectional view of the surface emitting laser 51 according to the first example of the second embodiment of the present technology. FIG. 38 is a plan view of the surface emitting laser 51 according to the first example of the second embodiment of the present technology. FIG. 37 is a sectional view along the line 37-37 in FIG. 38.

The surface emitting laser 51 includes: a first structure ST1 that includes a first reflector R1; a second structure ST2 that includes a second reflector R2; and an active layer 204 that is disposed between the first and second structures ST1 and ST2 as illustrated in FIGS. 37 and 38. In other words, the surface emitting laser 51 is a VCSEL with a vertical cavity structure in which the active layer 204 is sandwiched by the first and second reflectors R1 and R2. The surface emitting laser 51 is made of an InP system (a material system that lattice-matches InP) except for the second reflector R2 in an example.

The active layer 204 has a quantum well structure made of AlGaInAs or GaInAsP in an example. The light emitting wavelength of the active layer 204 is equal to or greater than 1.2 μm and equal to or less than 2 μm, for example.

The first reflector R1 is an n-type semiconductor multilayer reflector in an example. Specifically, the first reflector R2 is an InP-based DBR, for example, and preferably includes AlGaInAs. More specifically, the first reflector R2 preferably includes a pair of InP/AlGaInAs or a pair of AlInAs/AlGaInAs.

The second reflector R2 is made of a dielectric multilayer reflector in an example. The second reflector R2 is preferably made of a material containing at least one kind from SiO₂, TiO₂, Ta₂O₅, SiN, amorphous Si, MgF₂, and CaF₂, for example.

Although the surface emitting laser 51 is a front surface emitting-type surface emitting laser in which reflectance of the first reflector R1 is set to be slightly higher than reflectance of the second reflector R2 in an example, the surface emitting laser 51 can also be a rear surface emitting-type surface emitting laser by setting the reflectance of the second reflector R2 to be slightly higher than the reflectance of the first reflector R1.

The second structure ST2 includes a plurality of (eight, for example) tunnel junction layers 206 (a plurality of TJ mesas) with mesa shapes and a buried layer 207 (an n-InP layer, for example) that is a semiconductor layer covering the plurality of tunnel junction layers 206 that are provided between the active layer 204 and the second reflector R2. Each tunnel junction layer 206 and the buried layer 207 configure a BTJ. The thickness of the buried layer 207 is preferably equal to or greater than 200 nm. The thickness of the buried layer 207 can be 300 nm, for example.

The first structure ST1 further includes a substrate 200 (an InP substrate, for example) disposed on the first reflector R1 on the side opposite to the side of the active layer 204 and a first cladding layer 203 (an n-InP layer, for example) disposed between the first reflector R1 and the active layer 204.

The second structure ST2 further includes a second cladding layer 205 (a p-InP layer, for example) that is disposed between the active layer 204 and the plurality of tunnel junction layers 206. The plurality of tunnel junction layers 206 are disposed in an array shape (in a matrix shape, for example) on the second cladding layer 205 in an example. Each tunnel junction layer 206 is covered with a buried layer 207 (an n-InP layer, for example) from a lateral side and an upper side.

The second structure ST2 further includes an anode electrode 307 (electrode) that is provided on the buried layer 207 on the side opposite to the side of the active layer 204. The anode electrode 307 is provided on a region of the buried layer 207 that does not overlap with any of the plurality of tunnel junction layers 206 in an example. The anode electrode 307 is made of a material that is similar to that of the anode wiring 305 as described above.

At least a part of the anode electrode 307 is disposed between the buried layer 207 and the second reflector R2. Specifically, the second reflector R2 seamlessly and continuously covers the anode electrode 307 and the buried layer 207.

The surface emitting laser 51 is provided with a stepped portion 203a for installing an electrode in an example. The stepped portion 203a includes a bottom surface inside of the first cladding layer 203, for example. A cathode electrode 306 is installed on the bottom surface. The cathode electrode 306 is electrically connected to a negative electrode of a laser driver.

The surface emitting laser 51 is provided with a stepped portion 200a for separating an element in an example. The stepped portion 200a has a bottom portion inside of the substrate 200.

The plurality of tunnel junction layers 206 (the plurality of TJ mesas) are disposed to be spaced apart from each other in the in-plane direction to be optically separated. The active layer 204 has a plurality of light emitting regions (current injection regions) that individually correspond to the plurality of tunnel junction layers 206. In other words, the surface emitting laser 51 substantially configures a surface emitting laser array including a plurality of independent light emitting portions. Therefore, laser light, a lateral mode of which is a basic mode or a high-order mode, is emitted from a plurality of (the same number as the number of the tunnel junction layers 206) locations from the surface emitting laser 51.

On the other hand, in a surface emitting laser (for example, JP 2014-203894A) in the related art having a BTJ structure in which a plurality of tunnel junction layers (TJ mesas) are buried in a buried layer, the plurality of tunnel junction layers are disposed to be adjacent such that the tunnel junction layers are optically coupled to each other, and an active layer substantially has a single light emitting region. In other words, the surface emitting laser substantially configures a surface emitting laser including a single light emitting portion. Therefore, laser light, a lateral mode of which is a basic mode, is emitted from a single location from the surface emitting laser.

In this manner, while the purpose of the surface emitting laser (for example, JP 2014-203894A) in the related art is to narrow down the intervals between adjacent TJ mesas and optically couple them, the surface emitting laser 51 is adapted to widen the intervals between the adjacent TJ mesas, optically separate them, and thereby isolate the lateral mode for each TJ mesa.

The surface emitting laser 51 can curb thermal interference between adjacent TJ mesas and achieve high-output laser oscillation that continues for a long period of time. Furthermore, a substantial optical loss hardly occurs, and there are substantially no influences on optical properties even if an electrode is disposed in a region corresponding to a portion between adjacent TJ mesas in the surface emitting laser 51. On the other hand, the surface emitting laser (for example, JP 2014-203894A) in the related art cannot curb thermal interference between adjacent TJ mesas and cannot allow an electrode which serves as an optical loss to be disposed in the region corresponding to the portion between the adjacent TJ mesas.

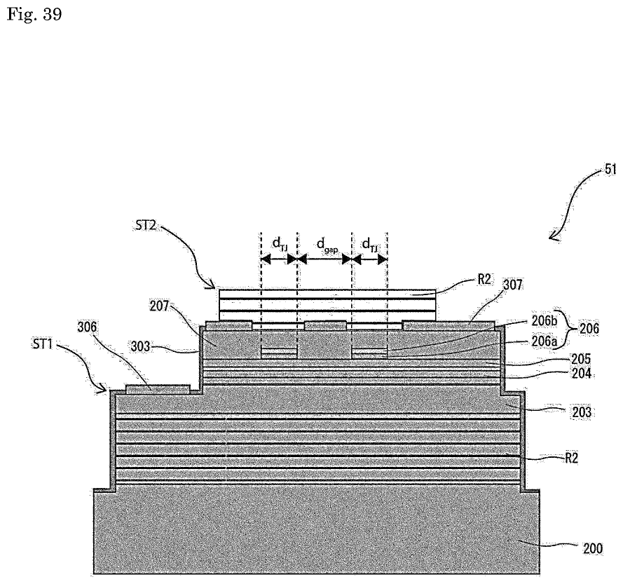

As illustrated in FIG. 39, an interval d_{gap} between two adjacent tunnel junction layers 206 from among the plurality of tunnel junction layers 206 is larger than a diameter d_{TJ} of each of the tunnel junction layers 206. In this manner, it is possible to optically separate the two adjacent tunnel junction layers 206, and thermal interference between the adjacent TJ mesas is curbed.

The interval d_{gap} between the two adjacent tunnel junction layers 206 is preferably three times or more, is more preferably four times or more, and is further preferably five times or more the diameter d_{TJ} of the plurality of tunnel junction layers 206. In this manner, it is possible to more reliably optically separate the adjacent TJ mesas. When d_{TJ} is 10 μm, for example, d_{gap} is preferably equal to or greater than 30 μm, is more preferably equal to or greater than 40 μm, and is further preferably equal to or greater than 50 μm.

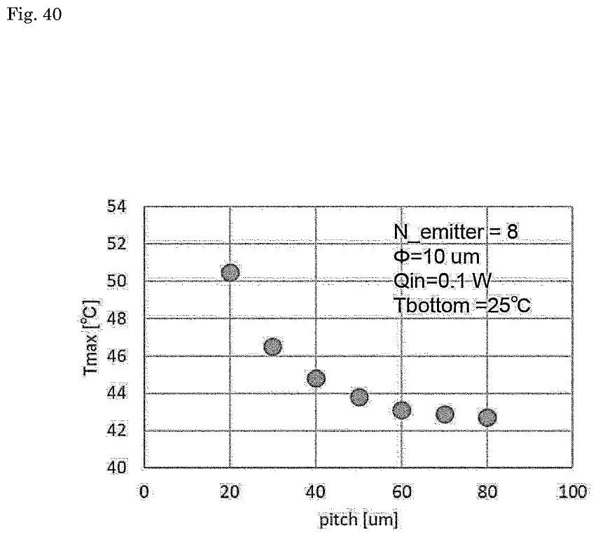

FIG. 40 is a graph illustrating a relationship between an alignment pitch (d_{gap}+d_{TJ}) of the tunnel junction layers 206 and the maximum temperature Tmax. Additionally, FIG. 40 illustrates a result of calculating, by a finite element method, the maximum temperature in a steady state in which the minimum temperature is 25° C. (Tbottom, environment temperature) when the number of tunnel junction layers 206 (N_emitter) is eight, d_{TJ}(Φ) is 10 μm, and heat (Qin) of 0.1 W has occurred in the tunnel junction layers 206. In FIG. 40, thermal interference between the adjacent TJ mesas is suddenly strengthened and the maximum temperature suddenly increases as the pitch decreases in a case where the pitch is less than 40 μm. On the contrary, it is possible to know that thermal interference between the adjacent TJ mesas is gradually weakened, and the maximum temperature asymptotically approaches the minimum value (42° C., for example) as the pitch increases in a case where the pitch is equal to or greater than 40 μm. Additionally, the maximum temperature is substantially a constant value (42° C., for example) when the pitch is equal to or greater than 100 μm.

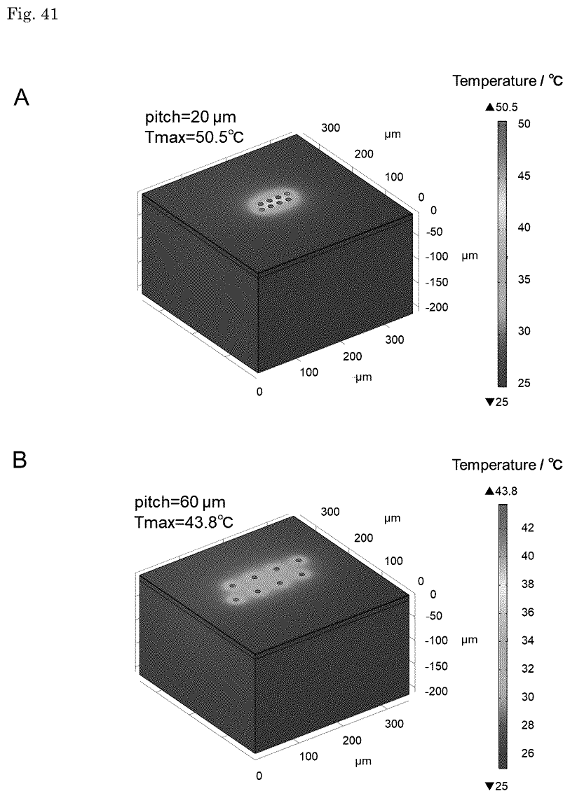

FIG. 41A is a diagram illustrating a first specific example of the alignment pitch of the tunnel junction layers 206 and the maximum temperature. FIG. 41B is a diagram illustrating a second specific example of the alignment pitch of the tunnel junction layers 206 and the maximum temperature. According to the surface emitting laser 51, the maximum temperature is 50.5° C. when the pitch is 20 μm as illustrated in FIG. 41A, and the maximum temperature is 43.8° C. when the pitch is 60 μm as illustrated in FIG. 41B.

As described above, the alignment pitch of the plurality of tunnel junction layers 206 is preferably equal to or greater than 40 μm and equal to or less than 100 μm, is more preferably equal to or greater than 50 μm and equal to or less than 90 μm, and is further preferably equal to or greater than 60 μm and equal to or less than 80 μm from the viewpoint of highly densely disposing the light emitting portions while effectively curbing thermal interference.

The anode electrode 307 includes an electrode portion 307a, a pad portion 307b, and a connecting portion 307c in an integrated manner in an example.

The electrode portion 307a is made of a layered portion including a plurality of (eight, for example) opening portions AP corresponding to the plurality of (eight, for example) tunnel junction layers 206. The electrode portion 307a includes a part that is present in the surroundings of each of the plurality of tunnel junction layers 206 in a plan view. At least a part (a part, for example) of the part is disposed between the corresponding tunnel junction layer 206 and the tunnel junction layer 206 that is adjacent to the corresponding tunnel junction layer 206 in a plan view. The part surrounds the corresponding tunnel junction layer 206 in a plan view.

As described above, the electrode portion 307a includes a part corresponding to each tunnel junction layer 206, and it is thus possible to uniformly inject a current to the plurality of corresponding light emitting regions via the plurality of tunnel junction layers 206 and to also curb a rise of an operation voltage even if the intervals between the adjacent TJ mesas is widened.

The pad portion 307b is connected to the electrode portion 307a via the connecting portion 307c. The pad portion 307b is electrically connected to the positive electrode of the laser driver.

### <<Operations of Surface Emitting Laser>>

Hereinafter, operations of the surface emitting laser 51 will be described. According to the surface emitting laser 51, a current that has flowed in from the side of the positive electrode of the laser driver via the anode electrode 307 is constricted by each BTJ and is then injected to the light emitting region corresponding to the BTJ of the active layer 204 via the second cladding layer 205. At this time, each light emitting region emits light, the light from the light emitting region reciprocates between the first and second reflectors R1 and R2 while being constricted by the corresponding BTJ and amplified in the light emitting region, and when an oscillation condition is satisfied, the light is emitted as laser light from the side of the second reflector R2. The current that has been injected to each light emitting region flows out to the side of the negative electrode of the laser driver via the first cladding layer 203 and the cathode electrode 306 in this order.

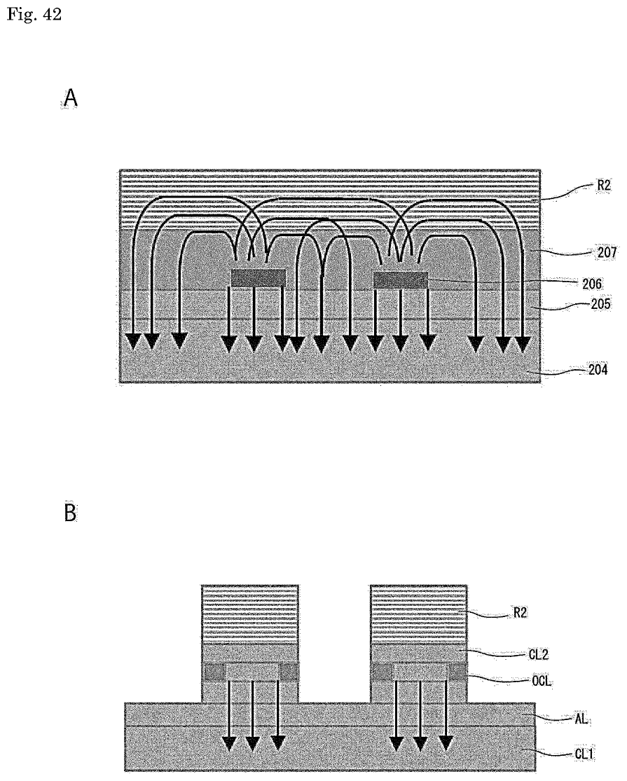

As illustrated in FIG. 42A, a part of heat generated in the tunnel junction layers 206 when the surface emitting laser 51 is driven is discharged to the side (lower side) of the substrate 200 via the second cladding layer 205 and the active layer 204 in this order, and the other part is discharged to the side (lower side) of the substrate 200 via the buried layer 207 and/or the second reflector R2, the second cladding layer 205, and the active layer 204 in this order. In this manner, since many heat exhaust routes for the heat generated in the vicinity of the tunnel junction layers 206 are present in the surface emitting laser 51, an excellent heat exhaust property is achieved, and it is possible to sufficiently curb a temperature rise when the element is driven.

On the other hand, according to the surface emitting laser in the related art illustrated in FIG. 42B, heat generated in the vicinity of the oxidation constriction layer OCL of each mesa at the time of driving is discharged to the side of the substrate via a part of the second cladding layer CL2, the active layer AL, and the first cladding layer CL1. In this manner, since the number of heat exhaust routes for the heat generated in the oxidation constriction layer OCL is small in the surface emitting laser in the related art, the heat exhaust property is inferior, and it is not possible to sufficiently curb a temperature rise when the element is driven.

### Example of Method for Manufacturing Surface Emitting Laser

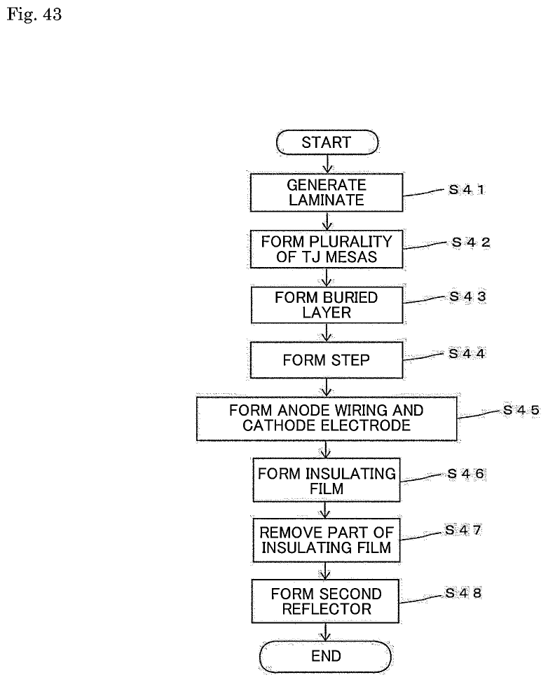

Hereinafter, an example of a method for manufacturing the surface emitting laser 51 will be described with reference to the flowchart in FIG. 43 and the like. Here, a plurality of surface emitting lasers 51 are simultaneously generated on a single wafer that serves as a base material of the substrate 200 by a semiconductor manufacturing method using a semiconductor manufacturing device in an example. Then, the series of plurality of surface emitting lasers 51 integrated are separated, and the plurality of surface emitting lasers 51 (surface emitting laser chips) with chip shapes are obtained.

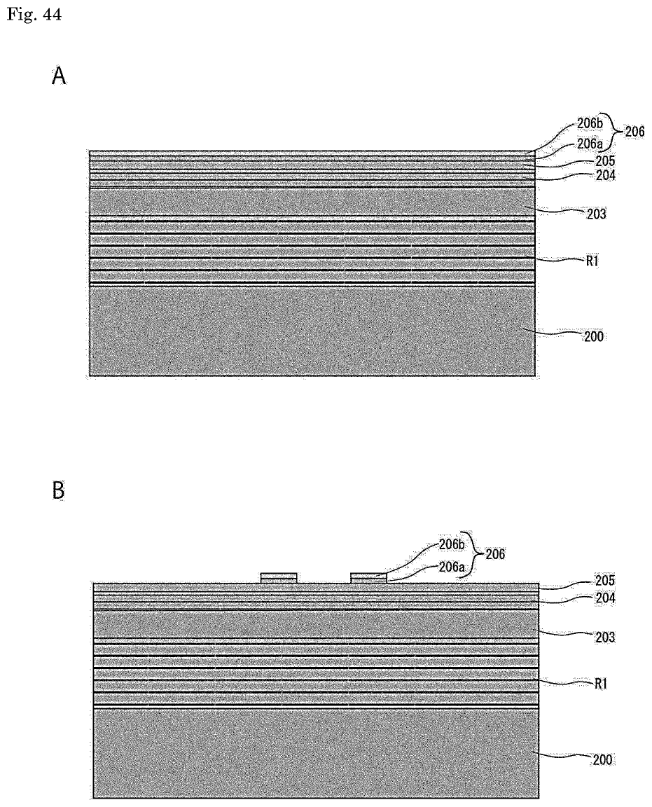

In first Step S41, a laminate is generated (see FIG. 44A). Specifically, the first reflector R1, the first cladding layer 203, the active layer 204, the second cladding layer 205, and the tunnel junction layers 206 are stacked in this order on the substrate 200 by the MOCVD method, for example, to thereby generate a laminate.

In next Step S42, a plurality of TJ mesas are formed (see FIG. 44B). Specifically, the plurality of tunnel junction layers 206 (with the diameter of 10 μm, for example, and a pitch of 50 μm, for example) are formed on the laminate by photolithography and etching.

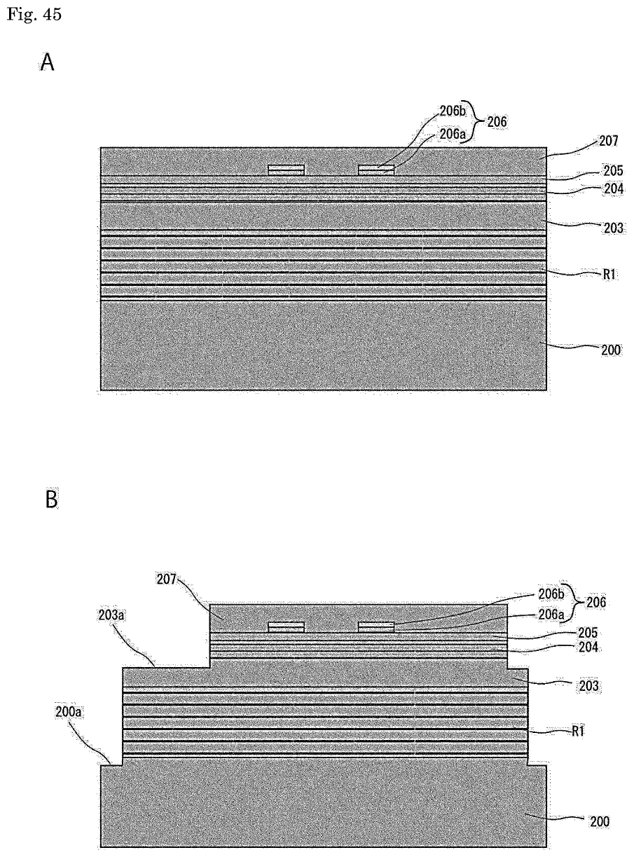

In next Step S43, the buried layer 207 is formed (see FIG. 45A). Specifically, an n-InP layer as the buried layer 207 is formed on the laminate on which the plurality of TJ mesas are formed by the MOCVD method, for example. As a result, the TJ mesas are buried by the buried layer 207.

In next Step S44, steps are formed (see FIG. 45B). Specifically, the stepped portion 203a for installing an electrode and the stepped portion 200a for separating elements are formed by photolithography and etching.

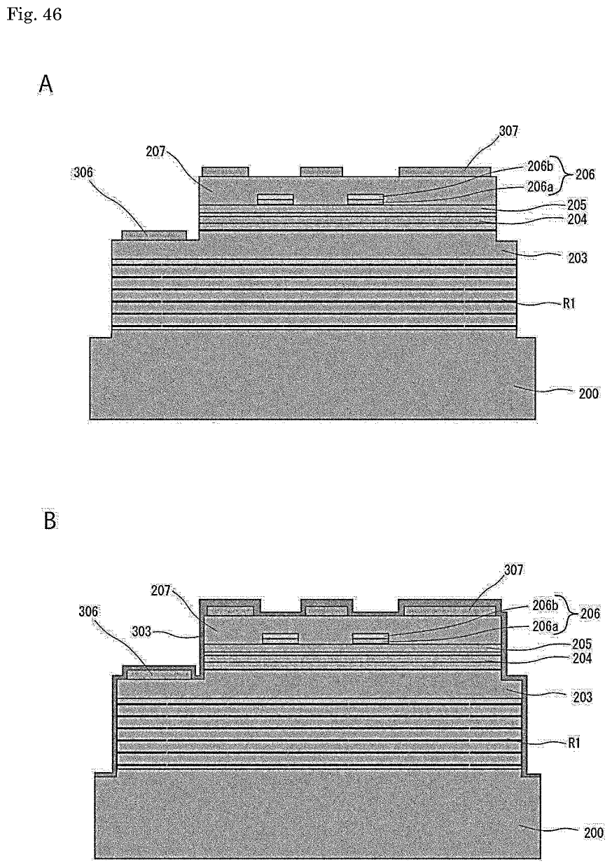

In next Step S45, the anode electrode 307 and the cathode electrode 306 are formed (see FIG. 46A). Specifically, the anode electrode 307 is formed on the buried layer 207, and the cathode electrode 306 is formed on the bottom surface of the stepped portion 203a by the lift-off method, for example. Film formation of the electrode material at this time is performed by the sputtering method or the vapor deposition method.

In next Step S46, the insulating film 303 is formed (see FIG. 46B). Specifically, the insulating film 303 is formed on the entire surface.

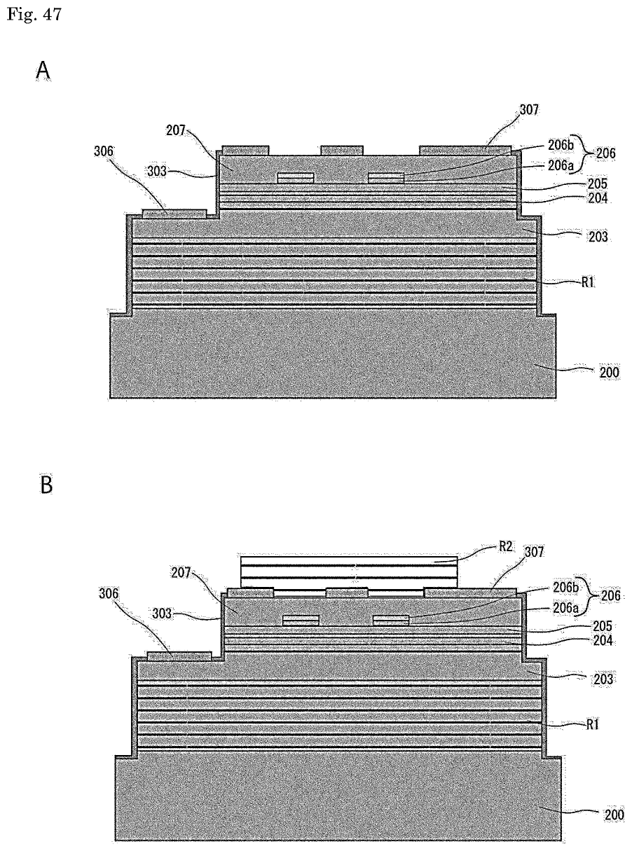

In next Step S47, a part of the insulating film 303 is removed (see FIG. 47A). Specifically, a part of the insulating film 303 covering the anode electrode 307 and a part covering the cathode electrode 306 are removed by dry etching, for example. As a result, the anode electrode 307 and the cathode electrode 306 are exposed.

In last Step S48, the second reflector R2 is formed (see FIG. 47B). Specifically, the dielectric multilayer is formed on the entire surface first. Then, the dielectric multilayer other than the dielectric multilayer formed on the anode electrode 307 and the buried layer 207 is selectively removed by photolithography. As a result, the second reflector R2 is formed. Thereafter, the surface emitting laser 51 is split into each piece and is mounted on a heat sink as needed, and the anode electrode 307 and the cathode electrode 306 are connected to corresponding terminals of the laser driver through wire bonding, for example.

### 12. Surface Emitting Laser According to Second Example of Second Embodiment of Present Technology

Hereinafter, a surface emitting laser 52 according to a second example of the second embodiment of the present technology will be described.

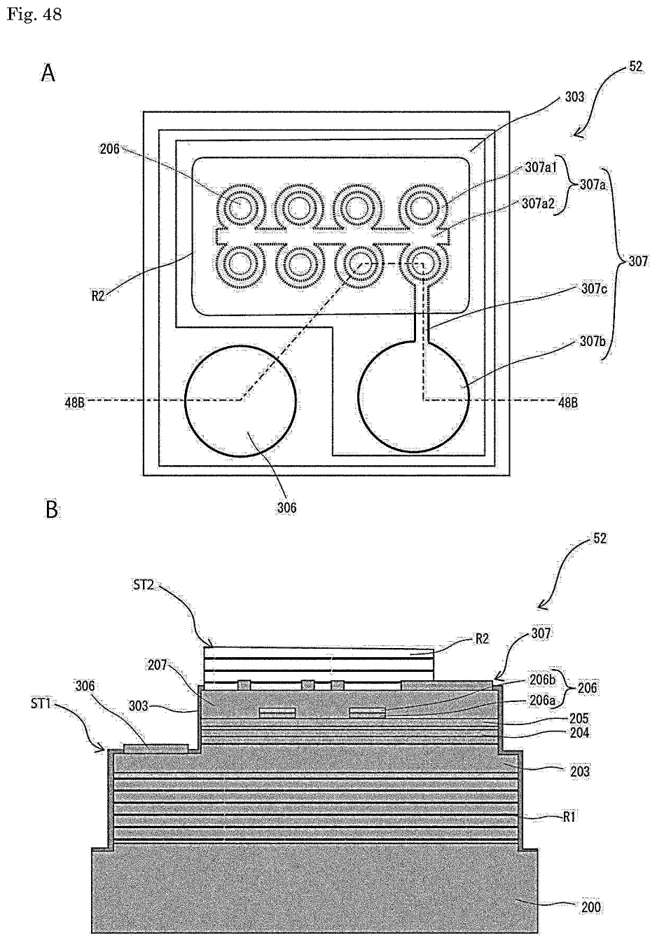

FIG. 48A is a plan view of the surface emitting laser 52 according to the second example of the second embodiment of the present technology. FIG. 48B is a sectional view of the surface emitting laser 52 according to the second example of the second embodiment of the present technology. FIG. 48B is a sectional view along the line 48B-48B in FIG. 48A.

The surface emitting laser 52 has a configuration that is substantially similar to that of the surface emitting laser 51 according to the first example other than that parts that are present in the surroundings of the plurality of tunnel junction layers 206, which are parts 307al with substantially annular shapes surrounding the corresponding tunnel junction layers 206, are coupled via a linear coupling portion 307a2, for example, in a plan view in the electrode portion 307a of the anode electrode 307 as illustrated in FIGS. 48A and 48B.

The surface emitting laser 52 can be applied to both a front surface emitting type and a rear surface emitting type.

According to the surface emitting laser 52, effects that are similar to those of the surface emitting laser 51 according to the first example are achieved.

### 13. Surface Emitting Laser According to Third Example of Second Embodiment of Present Technology

Hereinafter, a surface emitting laser 53 according to a third example of the second embodiment of the present technology will be described.

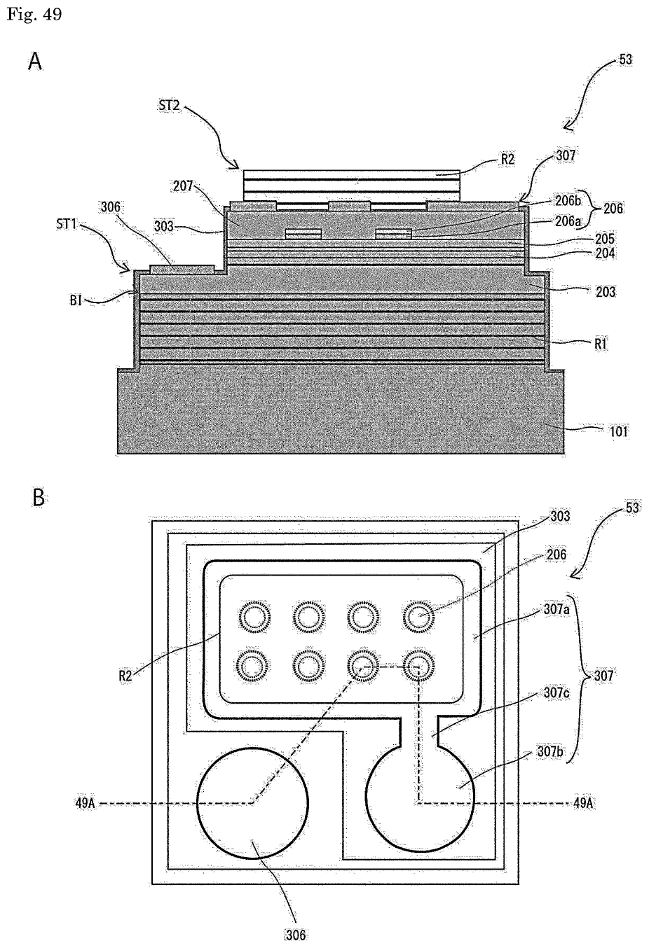

FIG. 49A is a sectional view of the surface emitting laser 53 according to the third example of the second embodiment of the present technology. FIG. 49B is a plan view of the surface emitting laser 53 according to the third example of the second embodiment of the present technology. FIG. 49A is a sectional view along the line 49A-49A in FIG. 49B.

The surface emitting laser 53 has a configuration that is similar to that of the surface emitting laser 51 according to the first example other than that the substrate 101 of the first structure ST1 is a GaAs substrate, the first reflector R1 is a GaAs-based semiconductor DBR, the first cladding layer 203 of the first structure ST1, the active layer 204, the second cladding layer 205, the tunnel junction layer 206, and the buried layer 207 of the second structure ST2 are made of InP-based compound semiconductors as illustrated in FIGS. 49A and 49B.

The surface emitting laser 53 includes a bonding interface BI between the first reflector R1 and the first cladding layer 203.

The surface emitting laser 53 can be applied to both a front surface emitting type and a rear surface emitting type.

According to the surface emitting laser 53, effects that are similar to those of the surface emitting laser 51 are achieved, GaAs-based materials that are more advantageous for heat dissipation than InP-based materials are used for the substrate 101 and the first reflector R1, and it is thus possible to curb a temperature rise of the element at the time of driving.

### 14. Surface Emitting Laser According to Fourth Example of Second Embodiment of Present Technology

Hereinafter, a surface emitting laser 54 according to a fourth example of the second embodiment of the present technology will be described.

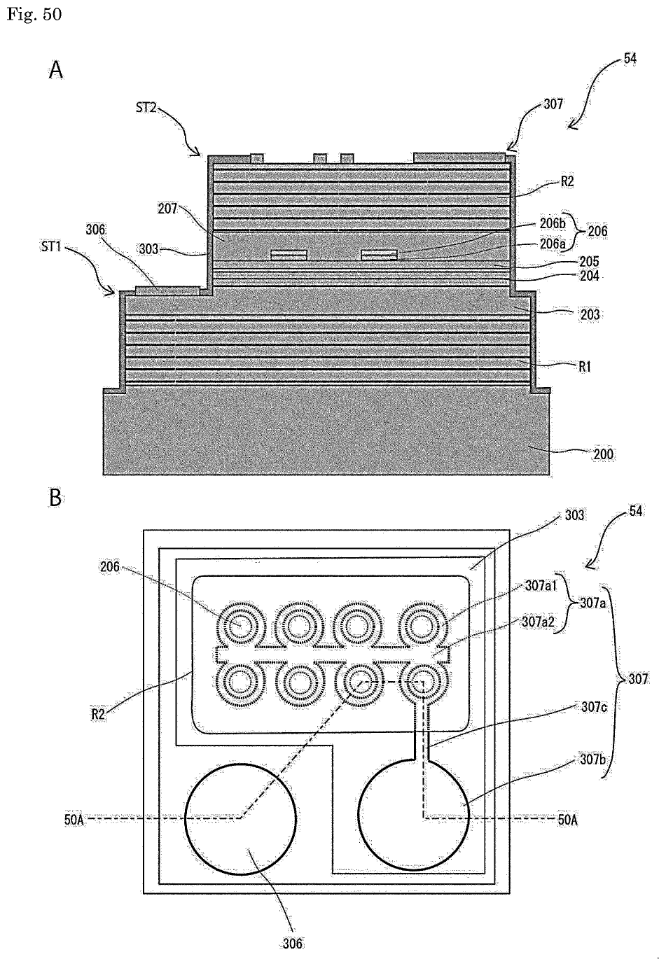

FIG. 50A is a sectional view of the surface emitting laser 54 according to the fourth example of the second embodiment of the present technology. FIG. 50B is a plan view of the surface emitting laser 54 according to the fourth example of the second embodiment of the present technology. FIG. 50A is a sectional view along the line 50A-50A in FIG. 50B.

The surface emitting laser 54 has a configuration that is substantially similar to that of the surface emitting laser 52 according to the second example other than that the second reflector R2 is an n-type semiconductor multilayer reflector as illustrated in FIGS. 50A and 50B.

Here, the second reflector R2 is an InP-based semiconductor DBR, for example, and preferably includes AlGaInAs. More specifically, the first reflector R2 preferably includes a pair of InP/AlGaInAs or a pair of AlInAs/AlGaInAs.

In the surface emitting laser 54, the anode electrode 307 is provided on the surface (upper surface) of the second reflector R2 on the side opposite to the side of the active layer 204.

The surface emitting laser 54 can be applied to both a front surface emitting type and a rear surface emitting type.

According to the surface emitting laser 54, effects that are similar to those of the surface emitting laser 51 according to the first example are achieved.

### 15. Surface Emitting Laser According to Fifth Example of Second Embodiment of Present Technology

Hereinafter, a surface emitting laser 55 according to a fifth example of the second embodiment of the present technology will be described.

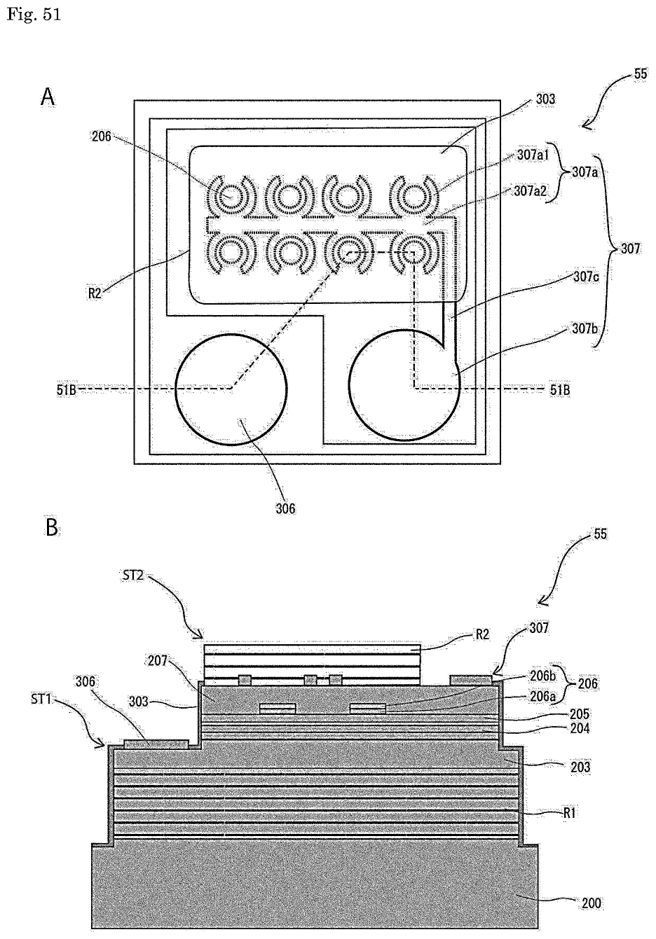

FIG. 51A is a plan view of the surface emitting laser 55 according to the fifth example of the second embodiment of the present technology. FIG. 51B is a sectional view of the surface emitting laser 55 according to the fifth example of the second embodiment of the present technology. FIG. 51B is a sectional view along the line 51B-51B in FIG. 51A.

The surface emitting laser 55 has a configuration that is substantially similar to that of the surface emitting laser 52 according to the second example other than that the part 307a1 of the electrode portion 307a that is present in the surroundings of each tunnel junction layer 206 has a split ring shape (substantially C shape) in a plan view as illustrated in FIGS. 51A and 51B.

The surface emitting laser 55 can be applied to both a front surface emitting type and a rear surface emitting type.

According to the surface emitting laser 55, effects that are similar to those of the surface emitting laser 52 according to the second example are achieved, the electrode portion 307a can be relatively easily produced, and it is possible to expect an improvement in yield.

### 16. Surface Emitting Laser According to Sixth Example of Second Embodiment of Present Technology

Hereinafter, a surface emitting laser 56 according to a sixth example of the second embodiment of the present technology will be described.

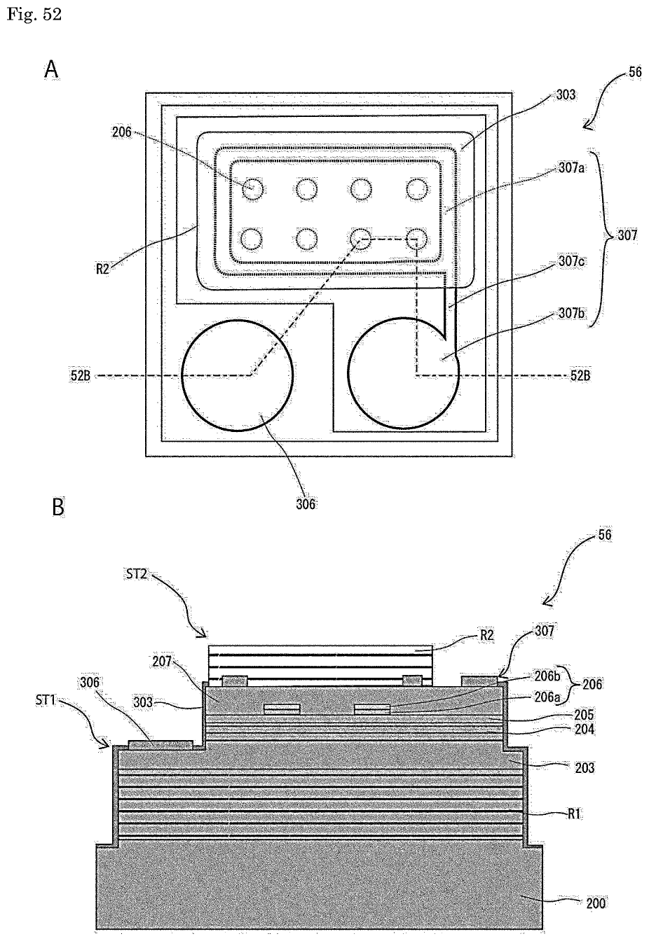

FIG. 52A is a plan view of the surface emitting laser 56 according to the sixth example of the second embodiment of the present technology. FIG. 52B is a sectional view of the surface emitting laser 56 according to the sixth example of the second embodiment of the present technology. FIG. 52B is a sectional view along the line 52B-52B in FIG. 52A.

The surface emitting laser 56 has a configuration that is substantially similar to that of the surface emitting laser 51 according to the first example other than that the electrode portion 307a surrounds at least two tunnel junction layers 206 (for example, all of the tunnel junction layers 206) together from among the plurality of tunnel junction layers 206 in a plan view as illustrated in FIGS. 52A and 52B.

Here, the electrode portion 307a has a frame shape collectively surrounding all of the tunnel junction layers 206.

The surface emitting laser 56 can be applied to both a front surface emitting type and a rear surface emitting type.

According to the surface emitting laser 56, effects that are substantially similar to those of the surface emitting laser 51 according to the first example are achieved, the electrode portion 307a can be significantly easily produced, and it is possible to expect an improvement in a yield.

### 17. Surface Emitting Laser According to Seventh Example of Second Embodiment of Present Technology

Hereinafter, a surface emitting laser 57 according to a seventh example of the second embodiment of the present technology will be described.

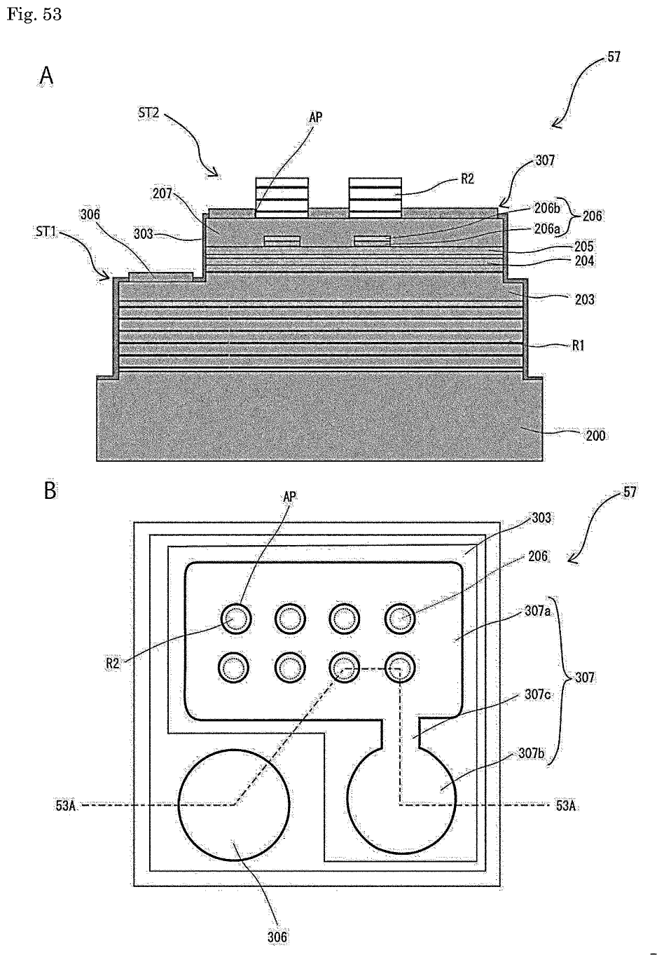

FIG. 53A is a sectional view of the surface emitting laser 57 according to the seventh example of the second embodiment of the present technology. FIG. 53B is a plan view of the surface emitting laser 57 according to the seventh example of the second embodiment of the present technology. FIG. 53A is a sectional view along the line 53A-53A in FIG. 53B.

The surface emitting laser 57 has a configuration that is similar to that of the surface emitting laser 51 according to the first example other than that a dielectric multilayer reflector as the second reflector R2 has only a part (a part corresponding to each TJ mesa) corresponding to each opening portion AP of the anode electrode 307 as illustrated in FIGS. 53A and 53B.

Here, the second reflector R2 does not include a stepped portion in the surroundings of each opening portion AP of the anode electrode 307.

The surface emitting laser 57 can be applied to both a front surface emitting type and a rear surface emitting type.

According to the surface emitting laser 57, effects that are substantially similar to those of the surface emitting laser 51 according to the first example are achieved, cracking is unlikely to occur since the second reflector R2 does not include the stepped portion in the surroundings of each opening portion AP of the electrode portion 307a, and it is possible to expect an improvement in a yield.

### 18. Surface Emitting Laser According to Eighth Example of Second Embodiment of Present Technology

Hereinafter, a surface emitting laser 58 according to an eighth example of the second embodiment of the present technology will be described.

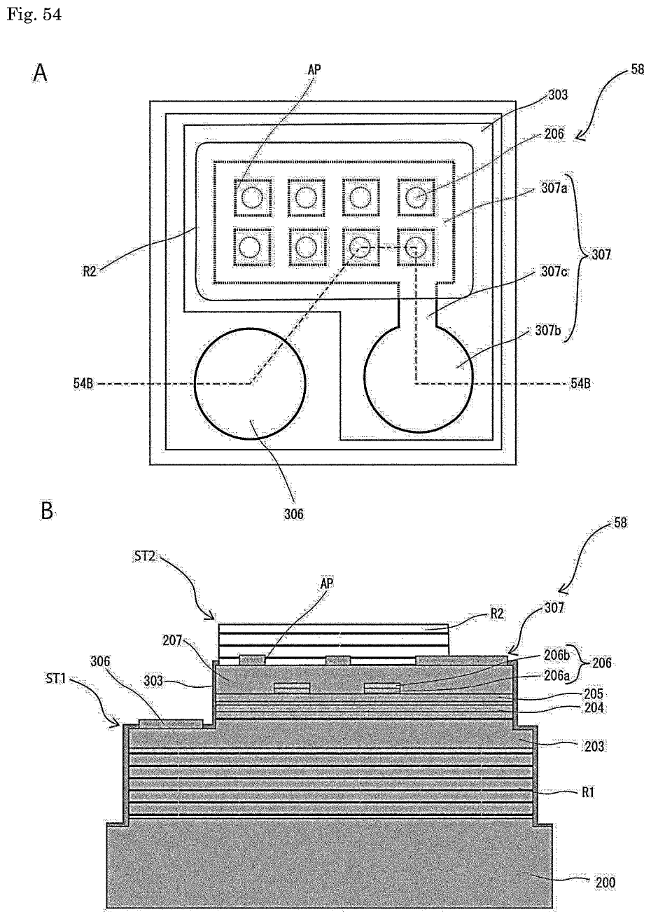

FIG. 54A is a plan view of the surface emitting laser 58 according to the eighth example of the second embodiment of the present technology. FIG. 54B is a sectional view of the surface emitting laser 58 according to the eighth example of the second embodiment of the present technology. FIG. 54B is a sectional view along the line 54B-54B in FIG. 54A.

The surface emitting laser 58 has a configuration that is substantially similar to that of the surface emitting laser 51 according to the first example other than that the shape of each opening portion AP of the electrode portion 307a is different as illustrated in FIGS. 54A and 54B.

Although each opening portion AP has a rectangular shape that is larger than the corresponding tunnel junction layer 206 in a plan view in the surface emitting laser 58, each opening portion AP may have another shape.

The surface emitting laser 58 can be applied to both a front surface emitting type and a rear surface emitting type.

According to the surface emitting laser 58, effects that are substantially similar to those of the surface emitting laser 51 according to the first embodiment are achieved.

### 19. Surface Emitting Laser According to Ninth Example of Second Embodiment of Present Technology

Hereinafter, a surface emitting laser 59 according to a ninth example of the second embodiment of the present technology will be described.

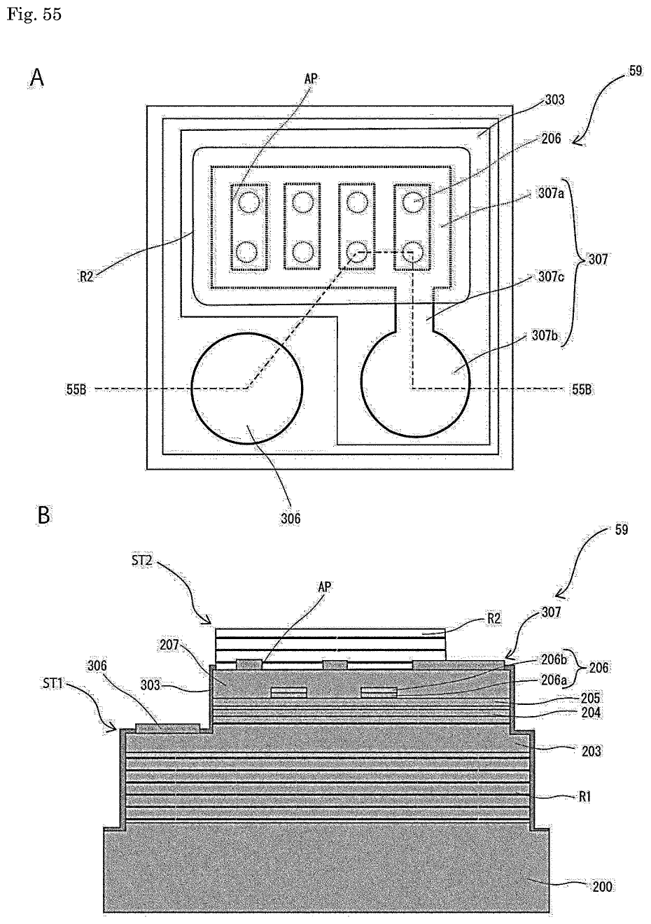

FIG. 55A is a plan view of the surface emitting laser 59 according to the ninth example of the second embodiment of the present technology. FIG. 55B is a sectional view of the surface emitting laser 59 according to the ninth example of the second embodiment of the present technology. FIG. 55B is a sectional view along the line 55B-55B in FIG. 55A.

The surface emitting laser 59 has a configuration that is similar to that of the surface emitting laser 51 according to the first example other than that the electrode portion 307a has a plurality of (four, for example) opening portions AP aligned in one direction in a plan view as illustrated in FIGS. 55A and 55B.

In the surface emitting laser 59, each opening portion AP corresponds to a plurality of (two, for example) tunnel junction layers 206 aligned in another direction that intersects (for example, perpendicularly intersects) the one direction. Although each opening portion AP has a rectangular shape surrounding the plurality of corresponding tunnel junction layers 206 together in a plan view here, each opening portion AP may have another shape.

The surface emitting laser 59 can be applied to both a front surface emitting type and a rear surface emitting type.

According to the surface emitting laser 59, effects that are substantially similar to those of the surface emitting laser 51 according to the first embodiment are achieved.

### 20. Surface Emitting Laser According to Tenth Example of Second Embodiment of Present Technology

Hereinafter, a surface emitting laser 60 according to a tenth example of the second embodiment of the present technology will be described.

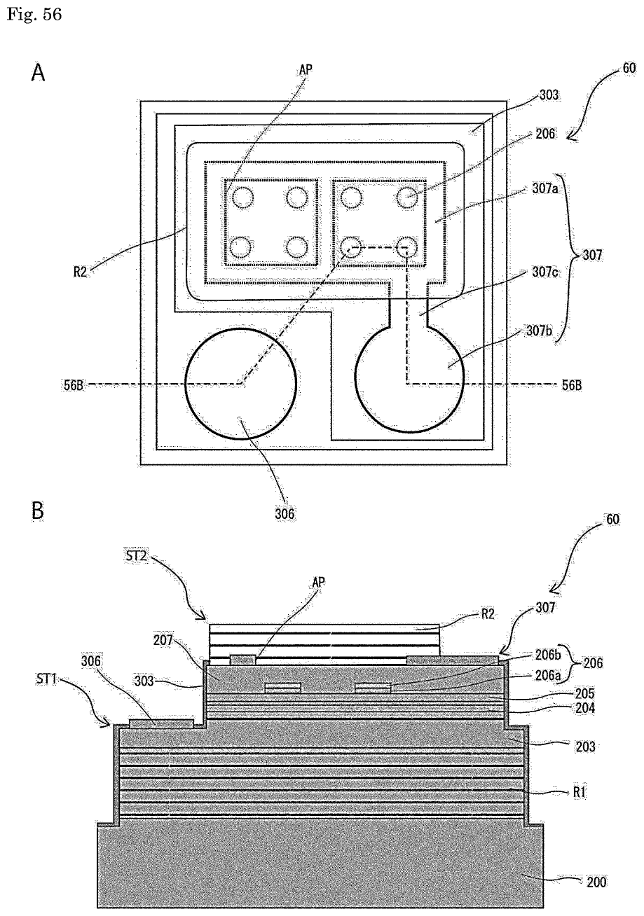

FIG. 56A is a plan view of a surface emitting laser 60 according to a tenth example of the second embodiment of the present technology. FIG. 56B is a sectional view of the surface emitting laser 60 according to the tenth example of the second embodiment of the present technology. FIG. 56B is a sectional view along the line 56B-56B in FIG. 56A.

The surface emitting laser 60 has a configuration that is similar to that of the surface emitting laser 51 according to the first example other than that the electrode portion 307a includes a plurality of (two, for example) opening portions AP aligned in one direction in a plan view as illustrated in FIGS. 56A and 56B.

In the surface emitting laser 60, each opening portion AP corresponds to a plurality of (four, for example) tunnel junction layers 206 aligned in a matrix shape. Although each opening portion AP has a rectangular shape surrounding the plurality of corresponding tunnel junction layers 206 together in a plan view here, each opening portion AP may have another shape.

The surface emitting laser 60 can be applied to both a front surface emitting type and a rear surface emitting type.

According to the surface emitting laser 60, effects that are substantially similar to those of the surface emitting laser 51 according to the first embodiment are achieved.

### 21. Surface Emitting Laser According to Eleventh Example of Second Embodiment of Present Technology

Hereinafter, a surface emitting laser 61 according to an eleventh example of the second embodiment of the present technology will be described.

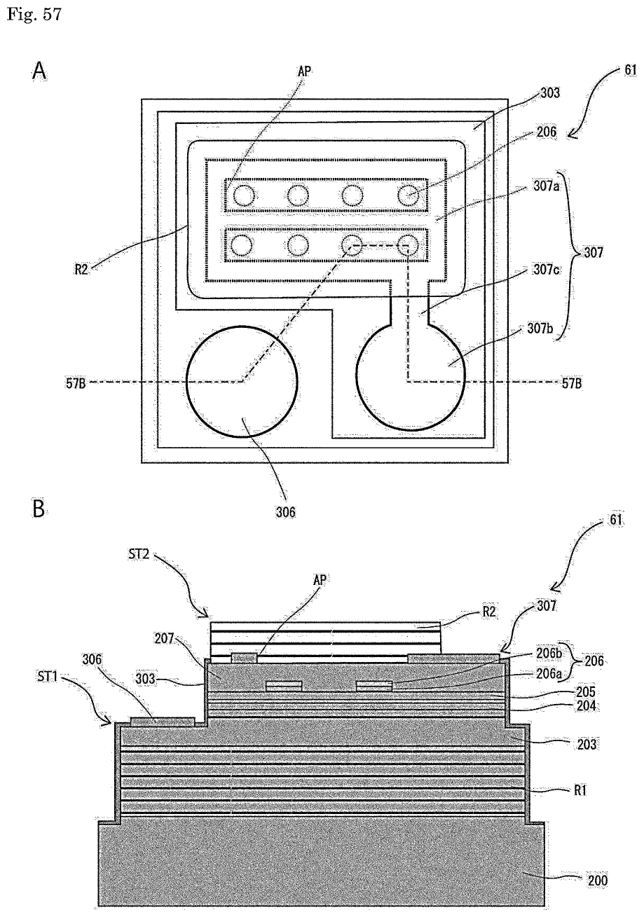

FIG. 57A is a plan view of the surface emitting laser 61 according to the eleventh example of the second embodiment of the present technology. FIG. 57B is a sectional view of the surface emitting laser 61 according to the eleventh example of the second embodiment of the present technology. FIG. 57B is a sectional view along the line 57B-57B in FIG. 57A.

The surface emitting laser 61 has a configuration that is similar to that of the surface emitting laser 51 according to the first example other than that the electrode portion 307a includes a plurality of (two, for example) opening portions AP aligned in one direction in a plan view as illustrated in FIGS. 57A and 57B.

In the surface emitting laser 61, each opening portion AP corresponds to a plurality of (four, for example) tunnel junction layers 206 aligned in another direction that intersects (for example, perpendicularly intersects) the one direction. Although each opening portion AP has a rectangular shape surrounding the plurality of corresponding tunnel junction layers 206 together in a plan view here, each opening portion AP may have another shape.

The surface emitting laser 61 can be applied to both a front surface emitting type and a rear surface emitting type.

According to the surface emitting laser 61, effects that are substantially similar to those of the surface emitting laser 51 according to the first embodiment are achieved.

### 22. Surface Emitting Laser According to Twelfth Example of Second Embodiment of Present Technology

Hereinafter, a surface emitting laser 62 according to a twelfth example of the second embodiment of the present technology will be described.

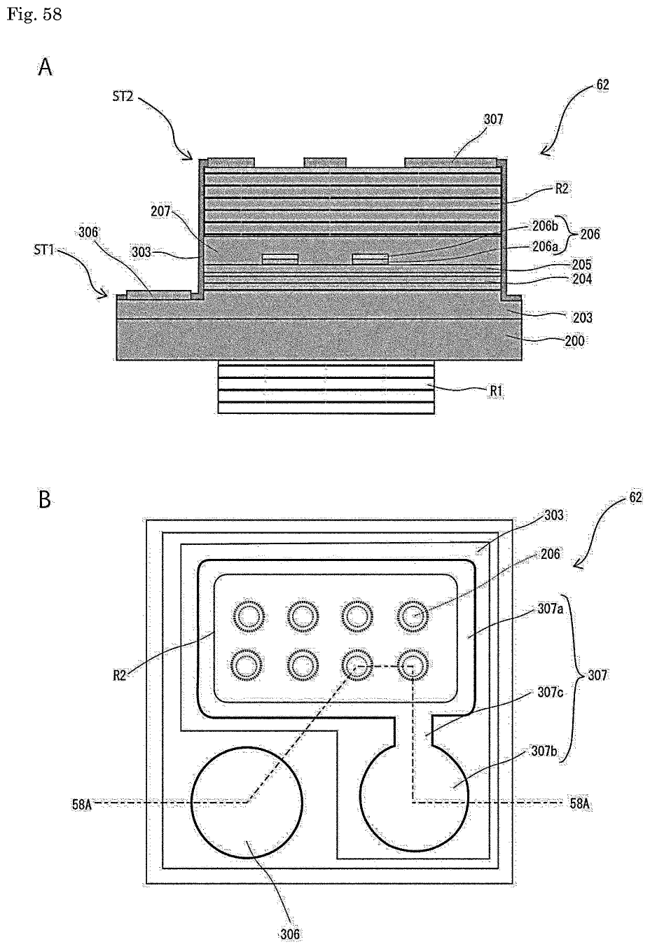

FIG. 58A is a sectional view of the surface emitting laser 62 according to the twelfth example of the second embodiment of the present technology. FIG. 58B is a plan view of the surface emitting laser 62 according to the twelfth example of the second embodiment of the present technology. FIG. 58A is a sectional view along the line 58A-58A in FIG. 58B.

The surface emitting laser 62 has a configuration that is substantially similar to that of the surface emitting laser 51 according to the first example other than that the first reflector R1 is a dielectric multilayer reflector and the second reflector R2 is a semiconductor multilayer reflector as illustrated in FIGS. 58A and 58B.

Here, the dielectric multilayer reflector as the first reflector R1 is made of a material that is similar to that of the dielectric multilayer reflector as the second reflector R2 in the surface emitting laser 51 according to the first example. The semiconductor multilayer reflector as the second reflector R2 is made of a material that is similar to that of the semiconductor multilayer reflector as the second reflector R2 in the surface emitting laser 54 according to the fourth example.

The thickness of the substrate 200 is reduced in the surface emitting laser 62, and it is possible to expect an improvement in heat dissipation.

The surface emitting laser 62 can be applied to both a front surface emitting type and a rear surface emitting type.

According to the surface emitting laser 62, effects that are substantially similar to those of the surface emitting laser 51 according to the first embodiment are achieved.

### 23. Surface Emitting Laser According to Thirteenth Example of Second Embodiment of Present Technology

Hereinafter, a surface emitting laser 63 according to a thirteenth example of the second embodiment of the present technology will be described.

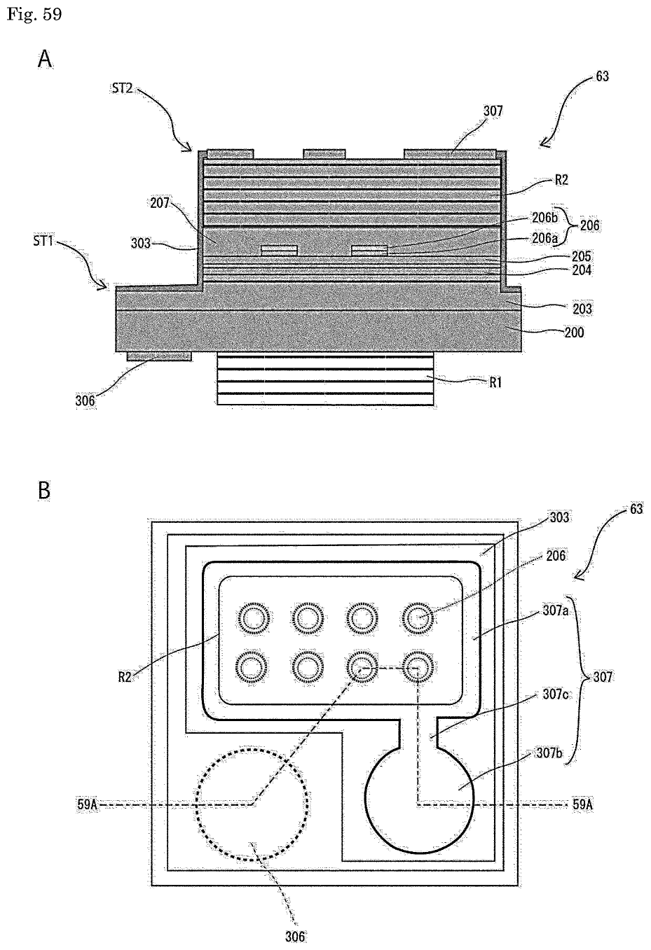

FIG. 59A is a sectional view of the surface emitting laser 63 according to the thirteenth example of the second embodiment of the present technology. FIG. 59B is a plan view of the surface emitting laser 63 according to the thirteenth example of the second embodiment of the present technology. FIG. 59A is a sectional view along the line 59A-59A in FIG. 59B.

The surface emitting laser 63 has a configuration that is substantially similar to that of the surface emitting laser 62 according to the twelfth example other than that the cathode electrode 306 is provided on the rear surface (lower surface) of the substrate 200 as illustrated in FIGS. 59A and 59B. In the surface emitting laser 63, the substrate 200 is doped into an n type, for example.

The surface emitting laser 63 can be applied to both a front surface emitting type and a rear surface emitting type.

According to the surface emitting laser 63, effects that are substantially similar to those of the surface emitting laser 61 according to the first embodiment are achieved.

### 24. Surface Emitting Laser According to Fourteenth Example of Second Embodiment of Present Technology

Hereinafter, a surface emitting laser 64 according to a fourteenth example of the second embodiment of the present technology will be described.

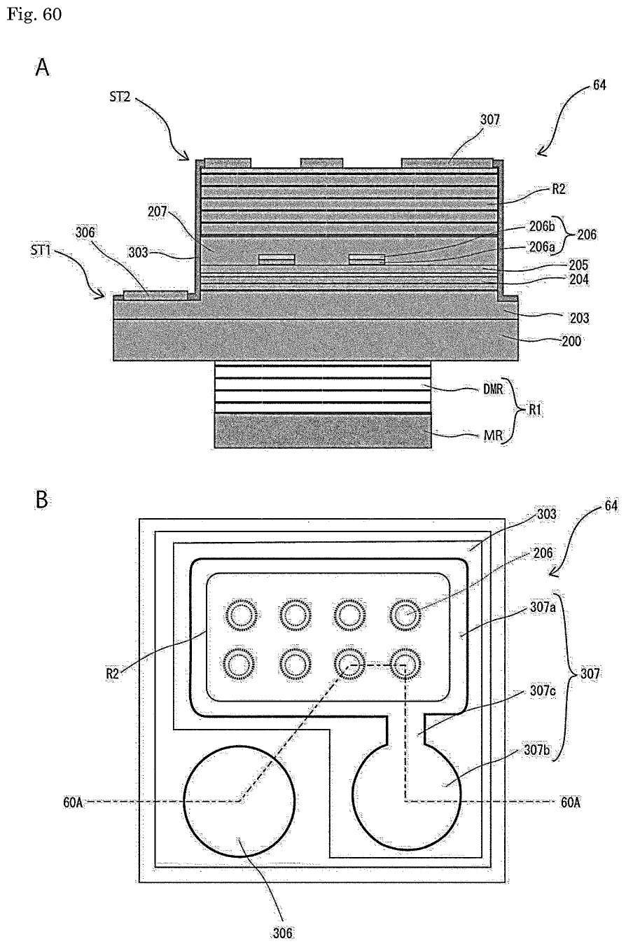

FIG. 60A is a sectional view of the surface emitting laser 64 according to the fourteenth example of the second embodiment of the present technology. FIG. 60B is a plan view of the surface emitting laser 64 according to the fourteenth example of the second embodiment of the present technology. FIG. 60A is a sectional view along the line 60A-60A in FIG. 60B.

The surface emitting laser 64 has a configuration that is similar to that of the surface emitting laser 62 according to the twelfth example other than that the first reflector R1 is a hybrid mirror including a dielectric multilayer reflector DMR and a metal reflector MR as illustrated in FIGS. 60A and 60B. The surface emitting laser 64 is a surface emitting laser of a front surface emitting type.

The first reflector R1 is provided on the rear surface (lower surface) of the substrate 200. In the first reflector R1, the dielectric multilayer reflector DMR and the metal reflector MR are stacked in this order from the side of the substrate 200 (upper side). The metal reflector MR is made of a single layer or a multilayer made of at least one kind from Au, Ag, Cu, and Al, for example.

In the surface emitting laser 64, the reflectance of the first reflector R1 is set to be slightly higher than the reflectance of the second reflector R2, and light is emitted to the side of the front surface (upper side) of the substrate 200.

According to the surface emitting laser 64, effects that are similar to those of the surface emitting laser 62 according to the twelfth example are achieved, and it is possible to expect an improvement in heat dissipation led by the metal reflector MR.

### 25. Surface Emitting Laser According to Fifteenth Example of Second Embodiment of Present Technology

Hereinafter, a surface emitting laser 65 according to a fifteenth example of the second embodiment of the present technology will be described.

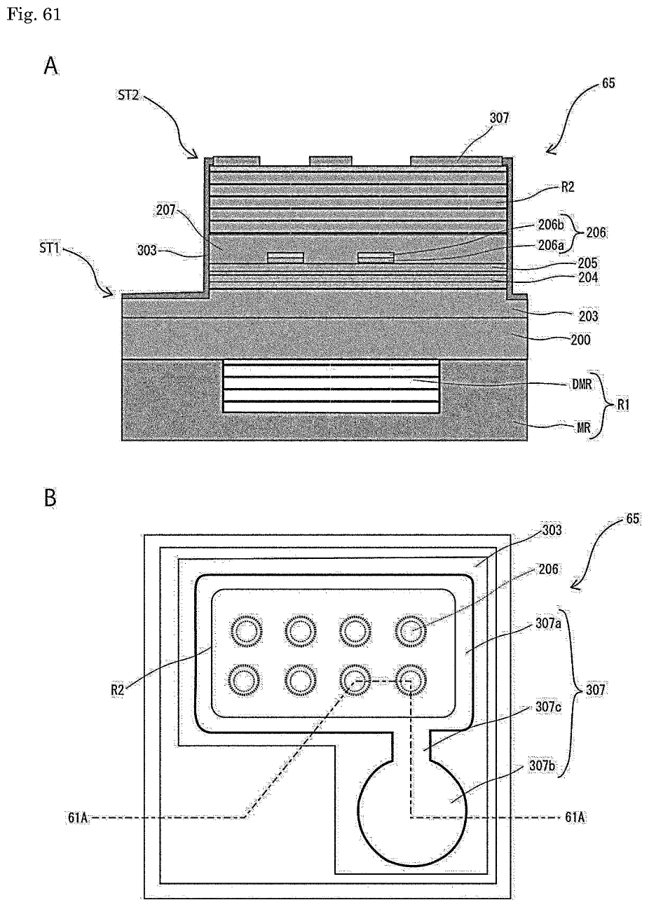

FIG. 61A is a sectional view of the surface emitting laser 65 according to the fifteenth example of the second embodiment of the present technology. FIG. 61B is a plan view of the surface emitting laser 65 according to the fifteenth example of the second embodiment of the present technology. FIG. 61A is a sectional view along the line 61A-61A in FIG. 61B.

The surface emitting laser 65 has a configuration that is similar to that of the surface emitting laser 62 according to the twelfth example other than that the first reflector R1 is a hybrid mirror including a dielectric multilayer reflector DMR and a metal reflector MR and the metal reflector MR also functions as a cathode electrode as illustrated in FIGS. 61A and 61B. The surface emitting laser 65 is a surface emitting laser of a front surface emitting type.

Here, the first reflector R1 is provided on the rear surface (lower surface) of the substrate 200. In the first reflector R1, the dielectric multilayer reflector DMR is provided at a center portion of the rear surface of the substrate 200, and the metal reflector MR is provided in the surrounding portion of the rear surface of the substrate 200 to cover the dielectric multilayer reflector DMR from the lower side and the lateral side. The metal reflector MR is made of a single layer or a multilayer made of at least one kind from Au, Ag, Cu, and Al, for example. The substrate 200 is doped into an n-type, for example.

In the surface emitting laser 65, the reflectance of the first reflector R1 is set to be slightly higher than the reflectance of the second reflector R2, and light is emitted to the side of the front surface (upper side) of the substrate 200.

According to the surface emitting laser 65, effects that are similar to those of the surface emitting laser 62 according to the twelfth example are achieved, and it is possible to expect a further improvement in heat dissipation led by the metal reflector MR.

### 26. Surface Emitting Laser According to Sixteenth Example of Second Embodiment of Present Technology

Hereinafter, a surface emitting laser 66 according to a sixteenth example of the second embodiment of the present technology will be described.

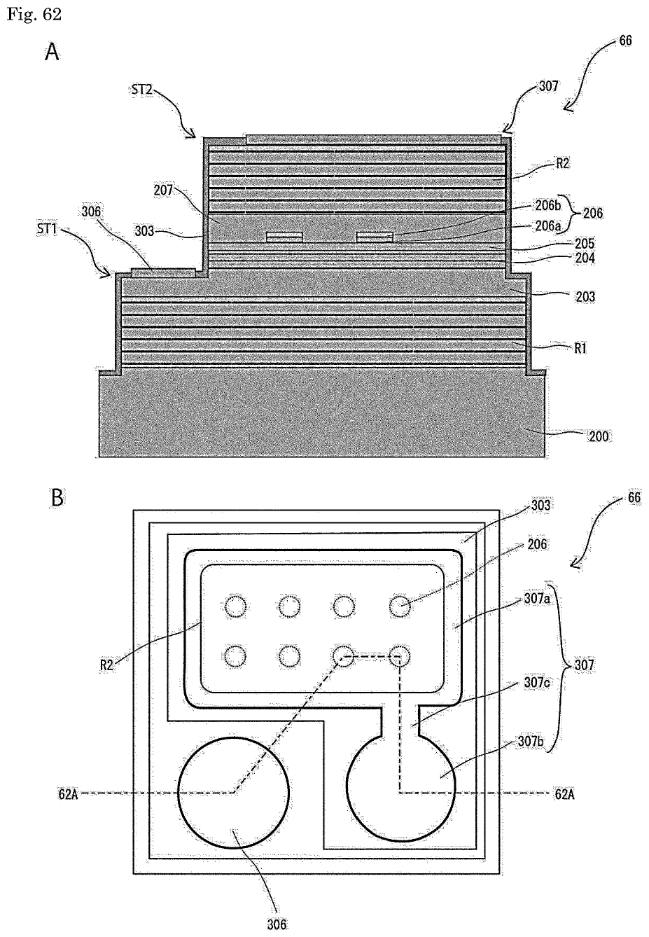

FIG. 62A is a sectional view of the surface emitting laser 66 according to the sixteenth example of the second embodiment of the present technology. FIG. 62B is a plan view of the surface emitting laser 66 according to the sixteenth example of the second embodiment of the present technology. FIG. 62A is a sectional view along the line 62A-62A in FIG. 62B.

The surface emitting laser 66 has a configuration that is similar to that of the surface emitting laser 54 according to the fourth example other than that the anode electrode 307 is provided in a solid shape (with no opening portions) on the second reflector R2 as illustrated in FIGS. 62A and 62B. The surface emitting laser 66 is a surface emitting laser of a rear surface emitting type.

Here, the electrode portion 307a is provided in a solid shape on the second reflector R2 to cover all of the plurality of tunnel junction layers 206.

In the surface emitting laser 66, the reflectance of the second reflector R2 is set to be slightly higher than the reflectance of the first reflector R1, and light is emitted to the side of the rear surface (lower side) of the substrate 200.

According to the surface emitting laser 66, effects that are similar to those of the surface emitting laser 54 according to the fourth example are achieved, and it is possible to expect an improvement in heat dissipation in accordance with the anode electrode 307 not including any opening portion.

### 27. Surface Emitting Laser According to Seventeenth Example of Second Embodiment of Present Technology

Hereinafter, a surface emitting laser 67 according to a seventeenth example of the second embodiment of the present technology will be described.

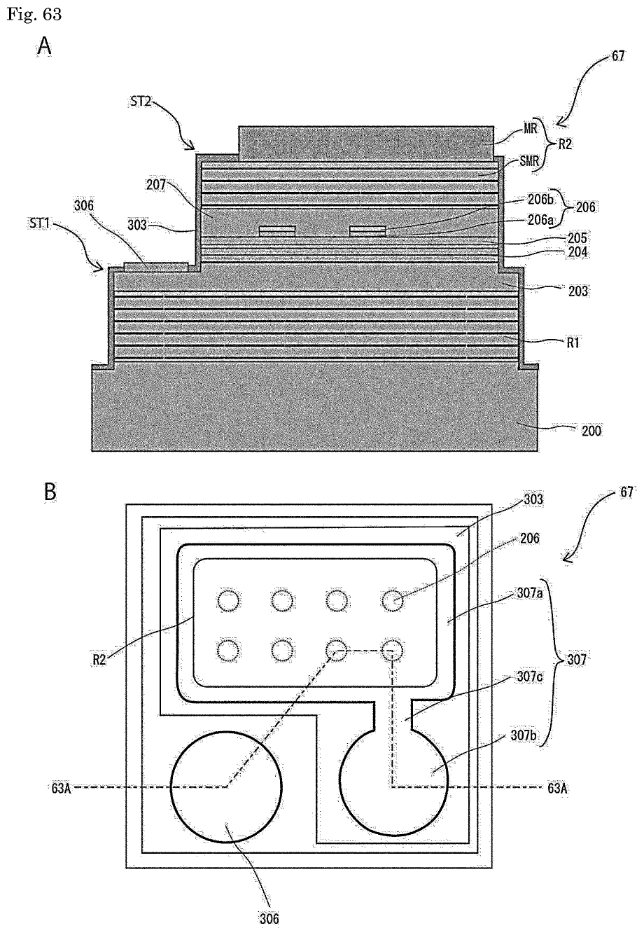

FIG. 63A is a sectional view of the surface emitting laser 67 according to the seventeenth example of the second embodiment of the present technology. FIG. 63B is a plan view of the surface emitting laser 67 according to the seventeenth example of the second embodiment of the present technology. FIG. 63A is a sectional view along the line 63A-63A in FIG. 63B.

The surface emitting laser 67 has a configuration that is substantially similar to that of the surface emitting laser 51 according to the first example other than that the second reflector R2 is a hybrid mirror including a semiconductor multilayer reflector SMR (an InP-based semiconductor DBR, for example) and a metal reflector MR and a part of the second reflector R2 also functions as an electrode portion of the anode electrode as illustrated in FIGS. 63A and 63B. The surface emitting laser 67 is a surface emitting laser of a rear surface emitting type.

Here, the metal reflector MR is stacked on the semiconductor multilayer reflector SMR. The metal reflector MR also functions as an anode electrode. The surface emitting laser 67 can reduce the number of pairs in the semiconductor multilayer reflector SMR in accordance with the metal reflector MR being provided and is advantageous in terms of heat dissipation.

The metal reflector MR is provided in a solid shape on the semiconductor multilayer reflector SMR to overlap with all of the plurality of tunnel junction layers 206.

In the surface emitting laser 67, the reflectance of the second reflector R2 is set to be slightly higher than the reflectance of the first reflector R1, and light is emitted to the side of the rear surface (lower side) of the substrate 200.

According to the surface emitting laser 67, effects that are similar to those of the surface emitting laser 54 according to the fourth example are achieved, the metal reflector MR is provided on the semiconductor multilayer reflector SMR, and it is thus possible to expect a sufficient improvement in heat dissipation.

### 28. Surface Emitting Laser According to Eighteenth Example of Second Embodiment of Present Technology

Hereinafter, a surface emitting laser 68 according to an eighteenth example of the second embodiment of the present technology will be described.

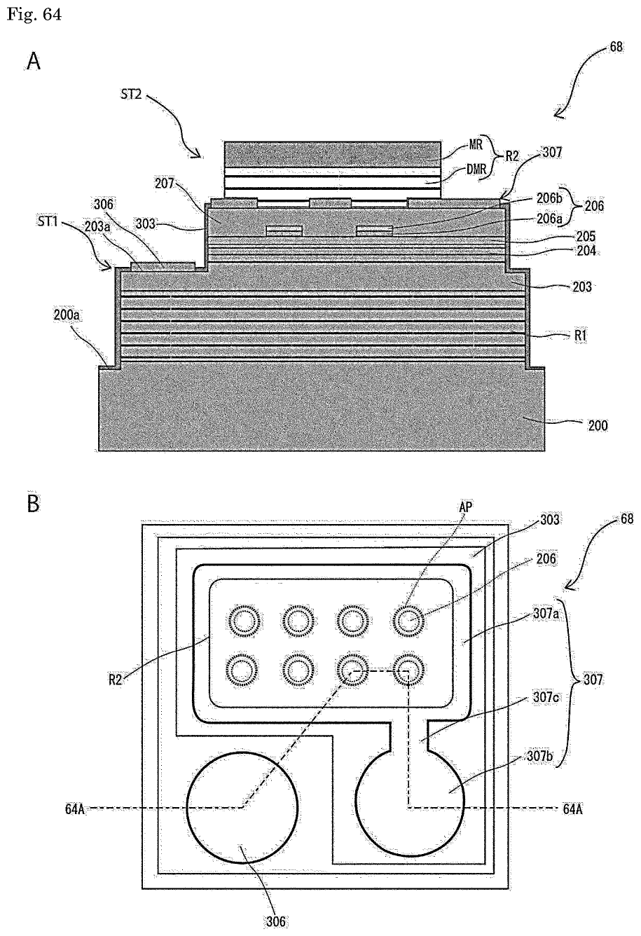

FIG. 64A is a sectional view of the surface emitting laser 68 according to the eighteenth example of the second embodiment of the present technology. FIG. 64B is a plan view of the surface emitting laser 68 according to the eighteenth example of the second embodiment of the present technology. FIG. 64A is a sectional view along the line 64A-64A in FIG. 64B.

The surface emitting laser 68 has a configuration that is substantially similar to that of the surface emitting laser 51 according to the first example other than that the second reflector R2 is a hybrid mirror including a dielectric multilayer reflector DMR and a metal reflector MR. The surface emitting laser 68 is a surface emitting laser of a rear surface emitting type.

Here, the metal reflector MR is stacked on the dielectric multilayer reflector DMR. The surface emitting laser 68 can reduce the number of pairs in the dielectric multilayer reflector DMR in accordance with the metal reflector MR being provided and is advantageous in terms of heat dissipation.

The metal reflector MR is provided in a solid shape on the dielectric multilayer reflector DMR to overlap with all of the plurality of tunnel junction layers 206.

In the surface emitting laser 68, the reflectance of the second reflector R2 is set to be slightly higher than the reflectance of the first reflector R1, and light is emitted to the side of the rear surface (lower side) of the substrate 200.

According to the surface emitting laser 68, effects that are similar to those of the surface emitting laser 51 according to the first example, the metal reflector MR is provided on the dielectric multilayer reflector DMR, and it is thus possible to expect an improvement in heat dissipation.

### 29. Other Modifications of Present Technology

The present technology is not limited to each example and each modification of the above first and second embodiments and can be modified in various manners.

For example, it is only necessary for the material systems (first and second material systems) configuring the first and second multilayer reflectors 102 and 202 to be different material systems, and the material systems are not limited to those in each example and each modification of the above first embodiment.

For example, the first and second multilayer reflectors 102 and 202 may be dielectric multilayer reflectors made of different material systems.

For example, one of the first and second multilayer reflectors 102 and 202 may be a semiconductor multilayer reflector, and the other may be a dielectric multilayer reflector.

Although each example and each modification of the above first embodiment have been described by exemplifying surface emitting lasers of the front surface emitting type, for example, the surface emitting lasers according to the present technology can configure surface emitting lasers of a rear surface emitting type.

The contact layers 208 and 108 that are in contact with the anode wiring 305 are not essential, for example.

For example, a contact layer that is in contact with the cathode electrode 306 may be included.

For example, the second reflector R2 is not limited to a dielectric multilayer reflector and may be a semiconductor multilayer reflector.

In a case where the surface emitting laser includes the plurality of tunnel junction layers 206 (TJ mesas), for example, alignment of the plurality of tunnel junction layers 206 is not limited to the matrix alignment, and in short, the alignment may be any one-dimensional alignment and/or two-dimensional alignment. Regardless of the alignment, it is preferable to lay out the electrode portion 307a of the anode electrode 307 in an appropriate layout in accordance with the alignment. The number of the tunnel junction layers 206 can also appropriately be changed.

The conductivity types (the p type and the n type) of the first and second structures ST1 and ST2 may be switched in the surface emitting lasers in each of the above examples and modifications.

Portions of the configurations of the surface emitting lasers in each of the above examples and modifications may be combined without causing any conflict therebetween.

In each of the above examples and modifications, a material, a conductivity type, a thickness, a width, a length, a shape, a size, arrangement, and the like of each component configuring the surface emitting lasers can be appropriately changed within a range in which the functions as the surface emitting lasers are achieved.

### 30. Examples of Application to Electronic Devices

The technology according to the present disclosure (present technology) can be applied to a variety of products (electronic devices). For example, the technology according to the present disclosure may be realized as a mobile object of any of types such as an automobile, an electric vehicle, a hybrid electric vehicle, a motorcycle, a bicycle, a personal mobility, an aircraft, a drone, a ship, a robot and the like or a device mounted on a low-power-consumption device (such as a smartphone, a smart watch, a tablet, or a mouse, for example).

The surface emitting lasers according to the present technology can also be applied as light sources for devices that form or display images with laser light (a laser printer, a laser copy machine, a projector, a head-mount display, or a head-up display, for example).

### 31. Examples in which Surface Emitting Lasers are Applied to Distance Measurement Device

Hereinafter, examples of applications of the surface emitting lasers according to each of the above examples and modifications will be described.

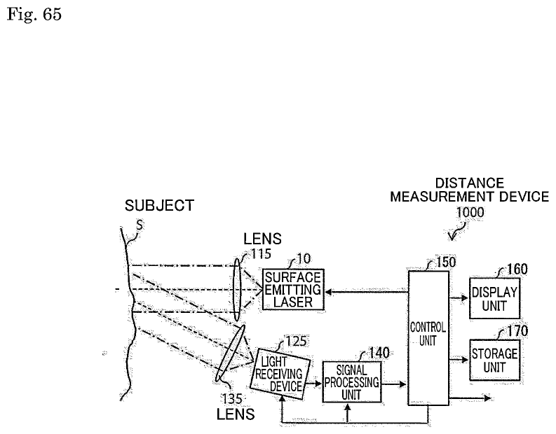

FIG. 65 represents an example of a schematic configuration of a distance measurement device 1000 including the surface emitting laser 10 as an example of an electronic device. The distance measurement device 1000 is adapted to measure a distance to a subject S by a time of flight (TOF) scheme. The distance measurement device 1000 includes the surface emitting laser 10 as a light source. The distance measurement device 1000 includes, for example, the surface emitting laser 10, a light receiving device 125, lenses 115 and 135, a signal processing unit 140, a control unit 150, a display unit 160, and a storage unit 170.

The light receiving device 125 detects light reflected by the subject S. The lens 115 is a lens for parallelizing light emitted from the surface emitting laser 10 and is a collimate lens. The lens 135 is a lens for collecting light reflected by the subject S and guiding the light to the light receiving device 125 and is a collecting lens.

The signal processing unit 140 is a circuit for generating a signal corresponding to a difference between a signal input from the light receiving device 125 and a reference signal input from the control unit 150. The control unit 150 is configured to include a time to digital converter (TDC), for example. The reference signal may be a signal input from the control unit 150 or may be an output signal of a detection unit that directly detects an output of the surface emitting laser 10. The control unit 150 is, for example, a processor that controls the surface emitting laser 10, the light receiving device 125, the signal processing unit 140, the display unit 160, and the storage unit 170. The control unit 150 is a circuit that measures the distance to the subject S on the basis of the signal generated by the signal processing unit 140. The control unit 150 generates a video signal for displaying information regarding the distance to the subject S and outputs the video signal to the display unit 160. The display unit 160 displays the information regarding the distance to the subject S on the basis of the video signal input from the control unit 150. The control unit 150 stores the information regarding the distance to the subject S in the storage unit 170.

In the present application example, it is also possible to apply any of the above surface emitting lasers 10-1, 10-2, 20, 20-1, 30-1, 40, 40-1, 50, 51, 52, 53, 54, 55, 56, 57, 58, 59, 60, 61, 62, 63, 68 and 68 to the distance measurement device 1000 instead of the surface emitting laser 10.

### 32. Examples in which Distance Measurement Device is Mounted in Mobile Object

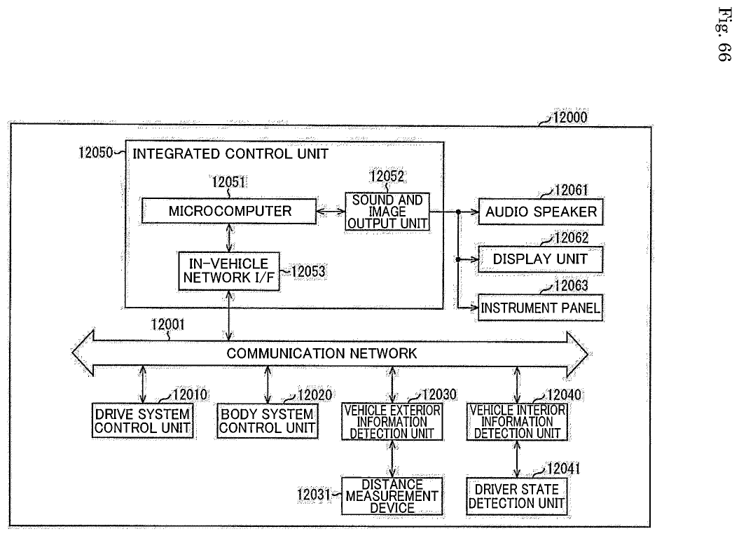

FIG. 66 is a block diagram illustrating a schematic configuration example of a vehicle control system, which is an example of a moving body control system to which the technique according to the present disclosure can be applied.

A vehicle control system 12000 includes a plurality of electronic control units connected thereto via a communication network 12001. In the example illustrated in FIG. 66, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls an operation of a device related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information regarding outside of the vehicle with the vehicle control system 12000 mounted therein. For example, a distance measurement device 12031 is connected to the vehicle exterior information detection unit 12030. The distance measurement device 12031 includes the aforementioned distance measurement device 1000. The vehicle exterior information detection unit 12030 causes the distance measurement device 12031 to measure the distance to an object (subject S) outside of the vehicle and acquires the thus obtained distance data. The vehicle exterior information detection unit 12030 may perform object detection processing for persons, cars, obstacles, signs, and the like on the basis of the acquired distance data.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information inside and outside of the vehicle acquired by the vehicle exterior information detection unit 12030 or the vehicle interior information detection unit 12040, and output a control command to the drive system control unit 12010. For example, the microcomputer 12051 can perform cooperative control for the purpose of realizing functions of an advanced driver assistance system (ADAS) including vehicle collision avoidance, impact mitigation, following traveling based on an inter-vehicle distance, vehicle speed maintenance driving, vehicle collision warning, vehicle lane deviation warning, and the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside of the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In the example of FIG. 66, an audio speaker 12061, a display unit 12062, and an instrument panel 12063 are illustrated as examples of the output device. The display unit 12062 may include at least one of an on-board display and a head-up display, for example.

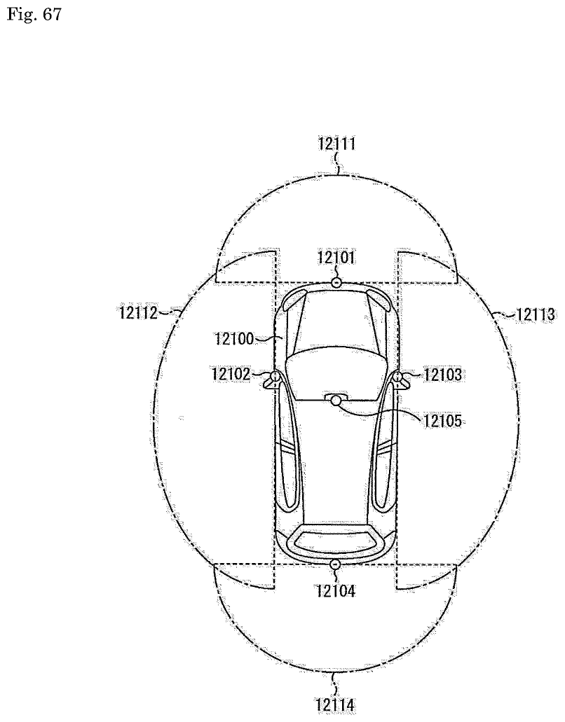

FIG. 67 is a diagram illustrating an example of an installation position of the distance measurement device 12031.

In FIG. 67, the vehicle 12100 includes, as the distance measurement device 12031, distance measurement devices 12101, 12102, 12103, 12104, and 12105.

The distance measurement devices 12101, 12102, 12103, 12104, and 12105 are provided at positions such as a front nose, side view mirrors, a rear bumper, rear doors, and an upper portion of a front glass in the vehicle interior of the vehicle 12100, for example. The distance measurement device 12101 provided at the front nose and the distance measurement device 12105 provided at the upper portion of the front glass in the vehicle interior mainly acquire data regarding an area in front of the vehicle 12100. The distance measurement devices 12102 and 12103 provided at the side view mirrors mainly acquire data regarding areas on the lateral sides of the vehicle 12100. The distance measurement device 12104 provided at the rear bumper or the rear door mainly acquires data regarding an area behind the vehicle 12100. The data regarding the front area acquired by the distance measurement devices 12101 and 12105 is used mainly to detect preceding vehicles, pedestrians, obstacles, traffic lights, traffic signs, and the like.

Note that FIG. 67 illustrates an example of a detection range of the distance measurement devices 12101 to 12104. A detection range 12111 denotes a detection range of the distance measurement device 12101 provided at the front nose, detection ranges 12112 and 12113 denote detection ranges of the distance measurement devices 12102 and 12103 provided on the side view mirrors, respectively, and a detection range 12114 denotes a detection range of the distance measurement device 12104 provided at the rear bumper or the rear door.

For example, the microcomputer 12051 can extract, as a preceding vehicle, a three-dimensional object that is closest to the vehicle 12100 and is on a traveling road of the vehicle 12100, in particular, which is also a three-dimensional object traveling at a predetermined speed (equal to or greater than 0 km/h, for example) in a direction that is substantially the same as that of the vehicle 12100 by obtaining the distance to each three-dimensional object inside of the detection ranges 12111 to 12114 and a temporal change in the distance (a relative speed with respect to the vehicle 12100) on the basis of the distance data obtained from the distance measurement devices 12101 to 12104. Furthermore, the microcomputer 12051 can set an inter-vehicle distance to be secured in advance before a preceding vehicle and can perform automatic brake control (including following stop control), automatic acceleration control (including following start control), and the like. Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles on the basis of distance data obtained from the distance measurement devices 12101 to 12104 and can use the three-dimensional data to perform automatic avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

An example of the moving body control system to which the technology according to the present disclosure can be applied has been described above. The technology according to the present disclosure can be applied to the distance measurement device 12031 among the configurations described above.

In addition, the present technology can also have the following configurations.

(1) A surface emitting laser including:
a first structure that includes a first reflector;
a second structure that includes a second reflector; and
an active layer that is disposed between the first structure and the second structure,
in which
the first reflector includes stacked a first multilayer reflector and a second multilayer reflector,
the first multilayer reflector is made of a first material system, and
the second multilayer reflector is made of a second material system that is different from the first material system.
   (2) The surface emitting laser according to (1), in which both the first multilayer reflector and the second multilayer reflector are semiconductor multilayer reflectors.
   (3) The surface emitting laser according to (1) or (2), in which the first material system is a compound semiconductor that lattice-matches GaAs, and the second material system is a compound semiconductor that lattice-matches InP.
   (4) The surface emitting laser according to any one of (1) to (3), in which a lattice constant of the first material system falls within a range of ±0.2% of a lattice constant of GaAs, and a lattice constant of the second material system falls within a range of ±0.2% of a lattice constant of InP.
   (5) The surface emitting laser according to any one of (1) to (4), in which the second multilayer reflector is disposed between the first multilayer reflector and the active layer.
   (6) The surface emitting laser according to any one of (1) to (5), in which the active layer is made of a GaAs-based compound semiconductor or a GaAsP-based compound semiconductor.
   (7) The surface emitting laser according to any one of (1) to (6), in which the active layer has a quantum well structure made of AlGaInAs or GaInAsP.
   (8) The surface emitting laser according to any one of (1) to (7), in which a light emitting wavelength of the active layer is equal to or greater than 1.2 μm and equal to or less than 2 μm.
   (9) The surface emitting laser according to any one of (1) to (8), in which the first structure further includes an intermediate layer disposed between the first multilayer reflector and the second multilayer reflector, and the intermediate layer includes a first layer that is disposed on a side of the first multilayer reflector and is made of a compound semiconductor that lattice-matches GaAs and a second layer that is disposed on a side of the second multilayer reflector and is made of a compound semiconductor that lattice-matches InP.
   (10) The surface emitting laser according to (9), in which the first layer and the second layer are bonded to each other.
   (11) The surface emitting laser according to any one of (1) to (10), in which the first structure further includes a substrate that is disposed on the first reflector on a side opposite to a side of the active layer.
   (12) The surface emitting laser according to any one of (1) to (11), in which the first material system is GaAs/AlₓGa_{1-X}As (0<X≤1).
   (13) The surface emitting laser according to any one of (1) to (12), in which the second material system includes AlGaInAs.
   (14) The surface emitting laser according to any one of (1) to (13), in which the second material system is InP/AlGaInAs or AlInAs/AlGaInAs.
   (15) The surface emitting laser according to any one of (9) to (14), in which a thickness of the intermediate layer is equal to or less than 300 nm.
   (16) The surface emitting laser according to any one of (1) to (15), in which the number of pairs in the second multilayer reflector is equal to or greater than one and equal to or less than twenty.
   (17) The surface emitting laser according to any one of (1) to (16), in which the second reflector is a dielectric multilayer reflector.
   (18) The surface emitting laser according to any one of (1) to (17), in which the second reflector is made of a material containing at least one kind from SiO₂, TiO₂, Ta₂O₅, SiN, amorphous Si, MgF₂, and CaF₂.
   (19) A method for manufacturing a surface emitting laser including:
stacking a first semiconductor structure including a first multilayer reflector that is a part of a first reflector on a first substrate;
bonding the first semiconductor structure to a second substrate;
forming a second semiconductor structure including a second multilayer reflector that is another portion of the first reflector and an active layer on the second substrate in this order from a side of the second substrate;
forming a second reflector on the second semiconductor structure; and
reducing a thickness of the second substrate.
   (20) The method for manufacturing the surface emitting laser according to (19), in which the reducing of the thickness is performed between the bonding of the first semiconductor structure to the second substrate and the forming of the second semiconductor structure.
   (21) A method for manufacturing a surface emitting laser including:
generating a first laminate including a first multilayer reflector that is a part of a first reflector and a first layer on a first substrate;
generating a second laminate including a second multilayer reflector that is another portion of the first reflector, an active layer, and a second reflector in this order on a second substrate;
bonding the first and second laminates; and
reducing a thickness of the second substrate.
   (22) The method for manufacturing a surface emitting laser according to (21), in which the reducing of the thickness is performed between the generating of the second laminate and the bonding of the first and second laminates.
   (23) A surface emitting laser including:
a first structure that includes a first reflector;
a second structure that includes a second reflector; and
an active layer that is disposed between the first structure and the second structure,
in which
the second structure includes
a plurality of mesa-shaped tunnel junction layers that are provided between the active layer and the second reflector, and
a semiconductor layer that covers the plurality of tunnel junction layers, and
the plurality of tunnel junction layers are disposed to be spaced apart from each other in an in-plane direction to be optically separated.
   (24) The surface emitting laser according to (23), in which the active layer includes a plurality of light emitting regions that individually correspond to the plurality of tunnel junction layers.
   (25) The surface emitting laser according to (23) or (24), in which an interval between two adjacent tunnel junction layers from among the plurality of tunnel junction layers is larger than a diameter of each of the plurality of tunnel junction layers.
   (26) The surface emitting laser according to (25), in which the interval is three times or more the diameter.
   (27) The surface emitting laser according to any one of (23) to (26), in which an alignment pitch of the plurality of tunnel junction layers is equal to or greater than 40 μm and equal to or less than 100 μm.
   (28) The surface emitting laser according to any one of (23) to (27), in which the second structure is provided with an electrode on the semiconductor layer on a side opposite to a side of the active layer.
   (29) The surface emitting laser according to (28), in which the electrode does not overlap with any of the plurality of tunnel junction layers.
   (30) The surface emitting laser according to (28), in which the electrode overlaps with at least one of the plurality of tunnel junction layers.
   (31) The surface emitting laser according to any one of (28) to (30), in which the electrode includes an electrode portion including a part that is present in surroundings of each of the plurality of tunnel junction layers in a plan view.
   (32) The surface emitting laser according to (31), in which at least a part of the part is present between each of the corresponding tunnel junction layer and each of the tunnel junction layer that is adjacent to the corresponding tunnel junction layer in a plan view.
   (33)
   The surface emitting laser according to (31) or (32), in which the part surrounds each of the corresponding tunnel junction layer in a plan view.
   (34) The surface emitting laser according to any one of (28) to (33), in which the electrode includes an electrode portion that surrounds at least two tunnel junction layers together from among the plurality of tunnel junction layers in a plan view.
   (35) The surface emitting laser according to any one of (28) to (34), in which at least a part of the electrode is disposed between the semiconductor layer and the second reflector.
   (36) The surface emitting laser according to any one of (28) to (35), in which the second reflector covers the electrode and the semiconductor layer.
   (37) The surface emitting laser according to any one of (28) to (36), in which the electrode is disposed on the second reflector on a side opposite to the active layer.
   (38) The surface emitting laser according to any one of (28) to (37), in which a part of the second reflector also functions as the electrode.
   (39) The surface emitting laser according to any one of (23) to (38), in which the semiconductor layer is made of InP.
   (40) The surface emitting laser according to any one of (23) to (39), in which a thickness of the semiconductor layer is equal to or greater than 200 nm.
   (41) The surface emitting laser according to any one of (23) to (40), in which the second reflector includes a dielectric multilayer reflector.
   (42) The surface emitting laser according to (41), in which the dielectric multilayer reflector is made of a material containing at least one kind from SiO₂, TiO₂, Ta₂O₅, SiN, amorphous Si, MgF₂, and CaF₂.
   (43) The surface emitting laser according to any one of (23) to (42), in which the first reflector includes a dielectric multilayer reflector.
   (44) The surface emitting laser according to (43), in which the dielectric multilayer reflector is made of a material containing at least one kind from SiO₂, TiO₂, Ta₂O₅, SiN, amorphous Si, MgF₂, and CaF₂.
   (45) The surface emitting laser according to any one of (23) to (44), in which the active layer has a quantum well structure made of AlGaInAs or GaInAsP.
   (46) The surface emitting laser according to any one of (23) to (45), in which a light emitting wavelength of the active layer is equal to or greater than 1.2 μm and equal to or less than 2 μm.
   (47) The surface emitting laser according to any one of (23) to (46), in which a part of the first reflector also functions as another electrode.

### REFERENCE SIGNS LIST

10, 10-1, 10-2, 20, 20-1, 30, 30-1, 40, 40-1, 50, 51, 52, 53, 54, 55, 56, 57, 58, 59, 60, 61, 62, 63, 68, 68 Surface emitting laser
101, 200 Substrate
102 First multilayer reflector
103 First layer
201 Second layer
202 Second multilayer reflector
204 Active layer
206 Tunnel junction layer
207 Buried layer (semiconductor layer)
307 Anode electrode (electrode)
307a Electrode portion
307a1 Part
ST1 First structure
ST2 Second structure
R1 First reflector
R2 Second reflector
ML Intermediate layer

1. A surface emitting laser comprising:
a first structure that includes a first reflector;
a second structure that includes a second reflector; and
an active layer that is disposed between the first structure and the second structure,
wherein
the first reflector includes stacked a first multilayer reflector and a second multilayer reflector,
the first multilayer reflector is made of a first material system, and
the second multilayer reflector is made of a second material system that is different from the first material system.

2. The surface emitting laser according to claim 1, wherein both the first multilayer reflector and the second multilayer reflector are semiconductor multilayer reflectors.

3. The surface emitting laser according to claim 1,
wherein the first material system is a compound semiconductor that lattice-matches GaAs, and
the second material system is a compound semiconductor that lattice-matches InP.

4. The surface emitting laser according to claim 1,
wherein a lattice constant of the first material system falls within a range of ±0.2% of a lattice constant of GaAs, and
a lattice constant of the second material system falls within a range of ±0.2% of a lattice constant of InP.

5. The surface emitting laser according to claim 3, wherein the second multilayer reflector is disposed between the first multilayer reflector and the active layer.

6. The surface emitting laser according to claim 5, wherein the active layer is made of a GaAs-based compound semiconductor or a GaAsP-based compound semiconductor.

7. The surface emitting laser according to claim 5, wherein the active layer has a quantum well structure made of AlGaInAs or GaInAsP.

8. The surface emitting laser according to claim 6, wherein a light emitting wavelength of the active layer is equal to or greater than 1.2 μm and equal to or less than 2 μm.

9. The surface emitting laser according to claim 3,
wherein the first structure further includes an intermediate layer disposed between the first multilayer reflector and the second multilayer reflector, and
the intermediate layer includes
a first layer that is disposed on a side of the first multilayer reflector and is made of a compound semiconductor that lattice-matches GaAs, and
a second layer that is disposed on a side of the second multilayer reflector and is made of a compound semiconductor that lattice-matches InP.

10. The surface emitting laser according to claim 9, wherein the first layer and the second layer are bonded to each other.

11. The surface emitting laser according to claim 3, wherein the first structure further includes a substrate that is disposed on the first reflector on a side opposite to a side of the active layer.

12. The surface emitting laser according to claim 1, wherein the first material system is GaAs/AlₓGa_{1-X}As (0<X≤1).

13. The surface emitting laser according to claim 1, wherein the second material system includes AlGaInAs.

14. The surface emitting laser according to claim 13, wherein the second material system is InP/AlGaInAs or AlInAs/AlGaInAs.

15. The surface emitting laser according to claim 9, wherein a thickness of the intermediate layer is equal to or less than 300 nm.

16. The surface emitting layer according to claim 1, wherein the number of pairs in the second multilayer reflector is equal to or greater than one and equal to or less than twenty.

17. The surface emitting laser according to claim 1, wherein the second reflector is a dielectric multilayer reflector.

18. The surface emitting laser according to claim 1, wherein the second reflector is made of a material containing at least one kind from SiO₂, TiO₂, Ta₂O₅, SiN, amorphous Si, MgF₂, and CaF₂.

19. A method for manufacturing a surface emitting laser comprising:
stacking a first semiconductor structure including a first multilayer reflector that is a part of a first reflector on a first substrate;
bonding the first semiconductor structure to a second substrate;
forming a second semiconductor structure including a second multilayer reflector that is another portion of the first reflector and an active layer on the second substrate in this order from a side of the second substrate;
reducing a thickness of the second substrate; and
forming a second reflector on the second semiconductor structure.

20. The method for manufacturing the surface emitting laser according to claim 19, wherein the reducing of the thickness is performed between the bonding of the first semiconductor structure to the second substrate and the forming of the second semiconductor structure.

21. A surface emitting laser comprising:
a first structure that includes a first reflector;
a second structure that includes a second reflector; and
an active layer that is disposed between the first structure and the second structure,
wherein
the second structure includes
a plurality of mesa-shaped tunnel junction layers that are provided between the active layer and the second reflector, and
a semiconductor layer that covers the plurality of tunnel junction layers, and
the plurality of tunnel junction layers are disposed to be spaced apart from each other in an in-plane direction to be optically separated.

22. The surface emitting laser according to claim 21, wherein the active layer includes a plurality of light emitting regions that individually correspond to the plurality of tunnel junction layers.

23. The surface emitting laser according to claim 21, wherein an interval between two adjacent tunnel junction layers from among the plurality of tunnel junction layers is larger than a diameter of each of the plurality of tunnel junction layers.

24. The surface emitting laser according to claim 23, wherein the interval is three times or more the diameter.

25. The surface emitting laser according to claim 23, wherein an alignment pitch of the plurality of tunnel junction layers is equal to or greater than 40 μm and equal to or less than 100 μm.

26. The surface emitting laser according to claim 21, wherein the second structure is provided with an electrode on the semiconductor layer on a side opposite to a side of the active layer.

27. The surface emitting laser according to claim 26, wherein the electrode does not overlap with any of the plurality of tunnel junction layers.

28. The surface emitting laser according to claim 26, wherein the electrode overlaps with at least one of the plurality of tunnel junction layers.

29. The surface emitting laser according to claim 26, wherein the electrode includes an electrode portion including a part that is present in surroundings of each of the plurality of tunnel junction layers in a plan view.

30. The surface emitting laser according to claim 29, wherein at least a part of the part is present between each of the corresponding tunnel junction layer and each of the tunnel junction layer that is adjacent to the corresponding tunnel junction layer in a plan view.

31. The surface emitting laser according to claim 29, wherein the part surrounds each of the corresponding tunnel junction layer in a plan view.

32. The surface emitting laser according to claim 26, wherein the electrode includes an electrode portion that surrounds at least two tunnel junction layers together from among the plurality of tunnel junction layers in a plan view.

33. The surface emitting laser according to claim 26, wherein at least a part of the electrode is disposed between the semiconductor layer and the second reflector.

34. The surface emitting laser according to claim 26, wherein the second reflector covers the electrode and the semiconductor layer.

35. The surface emitting laser according to claim 26, wherein the electrode is disposed on the second reflector on a side opposite to a side of the active layer.

36. The surface emitting laser according to claim 26, wherein a part of the second reflector also functions as the electrode.

37. The surface emitting laser according to claim 21, wherein the semiconductor layer is made of InP.

38. The surface emitting laser according to claim 21, wherein a thickness of the semiconductor layer is equal to or greater than 200 nm.

39. The surface emitting laser according to claim 21, wherein the second reflector includes a dielectric multilayer reflector.

40. The surface emitting laser according to claim 39, wherein the dielectric multilayer reflector is made of a material containing at least one kind from SiO₂, TiO₂, Ta₂O₅, SiN, amorphous Si, MgF₂, and CaF₂.

41. The surface emitting laser according to claim 21, wherein the first reflector includes a dielectric multilayer reflector.

42. The surface emitting laser according to claim 41, wherein the dielectric multilayer reflector is made of a material containing at least one kind from SiO₂, TiO₂, Ta₂O₅, SiN, amorphous Si, MgF₂, and CaF₂.

43. The surface emitting laser according to claim 21, wherein the active layer has a quantum well structure made of AlGaInAs or GaInAsP.

44. The surface emitting laser according to claim 21, wherein a light emitting wavelength of the active layer is equal to or greater than 1.2 μm and equal to or less than 2 μm.

45. The surface emitting laser according to claim 26, wherein a part of the first reflector also functions as another electrode.
